(19) United States
(12) Patent Application Publication
(10) Pub. No.: US 2024/0260272 A1
(43) Pub. Date: Aug. 1, 2024

(54) THREE-DIMENSIONAL FLASH MEMORY COMPRISING CONNECTION PART, AND MANUFACTURING METHOD THEREFOR

(71) Applicant: IUCF-HYU (Industry-University Cooperation Foundation Hanyang University), Seoul (KR)

(72) Inventor: Yun Heub SONG, Seoul (KR)

(21) Appl. No.: 18/560,682

(22) PCT Filed: Mar. 25, 2022
(86) PCT No.: PCT/KR2022/004194

§ 371 Date: Feb. 20, 2024

(30) Foreign Application Priority Data
May 14, 2021 (KR) 10-2021-0062346
May 14, 2021 (KR) 10-2021-0062347

(51) Int. Cl. H10B 43/27

(52) U.S. Cl. CPC H10B 43/27

(57) ABSTRACT

A three-dimensional flash memory comprising a connection part, and a manufacturing method therefor are disclosed.

### TECHNICAL FIELD

The following embodiments relate to a three-dimensional flash memory, and more particularly, to a technology for a three-dimensional flash memory manufactured through a stack laminating process.

### BACKGROUND ART

A flash memory device that is an electrically erasable programmable read only memory (EEPROM) controlling the data input/output through the F-N (Fowler-Nordheim) tunneling or the hot electron injection may be used in common in a computer, a digital camera, an MP3 player, a game system, a memory stick, etc.

In this flash memory device, it is required to increase the degree of integration to satisfy excellent performance and low price demanded by consumers, and thus a three-dimensional structure in which memory cell transistors are vertically arranged to constitute a cell string has been proposed.

In recent years, the three-dimensional flash memory has been more highly staged and more integrated, and a process in which a plurality of stack structures are vertically laminated and manufactured to implement a highly-staged and integrated structure has been used as a manufacturing process.

However, in the case of a stack laminating process, a vertical channel pattern VCP of each of the stack structures is misaligned, and thus channel current characteristics may be degraded.

Accordingly, the following embodiments are intended to provide a technology for solving the above issues.

### DETAILED DESCRIPTION OF THE INVENTION

### Techinical Problem

To solve a problem of degradation of channel current characteristics due to misalignment of a vertical channel pattern in a stack laminating process, embodiments propose a three-dimensional flash memory having a structure including connection parts that connect vertical channel patterns of stack structures to each other, a method of manufacturing the same, and an electronic system including the same.

In particular, embodiments propose a three-dimensional flash memory having a structure in which the connection parts have curved edges while protruding from the vertical channel patterns in a horizontal direction, a method of manufacturing the same, and an electronic system including the same.

Further, embodiments propose a three-dimensional flash memory having a structure in which the connection parts protrude from the vertical channel patterns in the horizontal direction, a method of manufacturing the same, and an electronic system including the same.

However, technical problems to be solved by the present disclosure are not limited to the above problems and may be variously expanded without departing from the technical spirit and scope of the present disclosure.

### Technical Solution

According to an embodiment, a three-dimensional flash memory includes stack structures each including interlayer insulating films and gate electrodes formed to extend in a horizontal direction and alternately laminated in a vertical direction and vertical channel structures passing through the interlayer insulating films and the gate electrodes and formed to extend in the vertical direction, each of the vertical channel structures including a data storage pattern formed to extend in the vertical direction and a vertical channel pattern that covers an inner side wall of the data storage pattern and is formed to extend in the vertical direction, and the stack structures being laminated in the vertical direction, and a buffer layer including connection parts that are arranged between the stack structures and connect the vertical channel patterns of the stack structures to each other, wherein the connection parts protrude from the vertical channel patterns in the horizontal direction and have curved edges, respectively.

According to an aspect, each of the connection parts may be formed on a side wall on which a portion of the buffer layer in the horizontal direction is wet-etched and thus may have a curved edge.

According to another aspect, the buffer layer may be formed of a material on which the wet etching is performed.

According to still another aspect, the material forming the buffer layer may include at least one material among a silicon oxide and a metal oxide.

According to yet another aspect, each of the connection parts may be formed on a side wall on which a portion of the buffer layer in the horizontal direction is etched as the buffer layer includes a plurality of layers, which have different etching ratios and are laminated in the vertical direction and may have a curved shape.

According to yet another aspect, a layer positioned in a center of the plurality of layers in the vertical direction may have a higher etching ratio than those of layers positioned at edges of the plurality of layers in the vertical direction.

According to an embodiment, a method of manufacturing a three-dimensional flash memory includes preparing a lower stack structure including interlayer insulating films and gate electrodes formed to extend in a horizontal direction and alternately laminated in a vertical direction and channel holes passing through the interlayer insulating films and the gate electrodes in the vertical direction, forming a buffer layer on the lower stack structure, forming, on the lower stack structure in which the buffer layer is formed, an upper stack structure including the interlayer insulating films and the gate electrodes formed to extend in the horizontal direction and alternately laminated in the vertical direction and the channel holes passing through the interlayer insulating films and the gate electrodes in the vertical direction, forming channel connection holes passing through the buffer layer in the vertical direction based on positions of the channel holes, wet etching a portion of the buffer layer in the horizontal direction such that a remaining portion has an undercut shape through the channel holes and the channel connection holes, and forming vertical channel structures each including a data storage pattern and a vertical channel pattern, on inner side walls of the channel holes and an etched side wall of the buffer layer, such that the vertical channel structures extend in the vertical direction, wherein the forming of the vertical channel structures such that the vertical channel structures extend in the vertical direction includes forming connection parts having curve edges while respectively protruding from the vertical channel patterns in the horizontal direction while connecting the vertical channel patterns formed in and extending from the upper stack structure and the vertical channel patterns formed in and extending from the lower stack structure to each other.

According to an embodiment, a method of manufacturing a three-dimensional flash memory includes preparing a lower stack structure including interlayer insulating films and gate electrodes formed to extend in a horizontal direction and alternately laminated in a vertical direction and channel holes passing through the interlayer insulating films and the gate electrodes in the vertical direction, forming a buffer layer, in which a plurality of layers having different etching ratios are laminated in the vertical direction, on the lower stack structure, forming, on the lower stack structure in which the buffer layer is formed, an upper stack structure including the interlayer insulating films and the gate electrodes formed to extend in the horizontal direction and alternately laminated in the vertical direction and the channel holes passing through the interlayer insulating films and the gate electrodes in the vertical direction, forming channel connection holes passing through the buffer layer in the vertical direction based on positions of the channel holes, etching a portion of the buffer layer in the horizontal direction such that a remaining portion has an undercut shape through the channel holes and the channel connection holes, and forming vertical channel structures each including a data storage pattern and a vertical channel pattern, on inner side walls of the channel holes and an etched side wall of the buffer layer, such that the vertical channel structures extend in the vertical direction, wherein the forming of the vertical channel structures such that the vertical channel structures extend in the vertical direction includes forming connection parts having curve edges while respectively protruding from the vertical channel patterns in the horizontal direction while connecting the vertical channel patterns formed in and extending from the upper stack structure and the vertical channel patterns formed in and extending from the lower stack structure to each other.

According to an embodiment, a three-dimensional flash memory includes stack structures each including interlayer insulating films and gate electrodes formed to extend in a horizontal direction and alternately laminated in a vertical direction and vertical channel structures passing through the interlayer insulating films and the gate electrodes and formed to extend in the vertical direction, each of the vertical channel structures including a data storage pattern formed to extend in the vertical direction and a vertical channel pattern configured to cover an inner side wall of the data storage pattern and formed to extend in the vertical direction, and the stack structures being laminated in the vertical direction, and connection parts arranged between the stack structures and protruding from the vertical channel patterns in the horizontal direction to connect the vertical channel patterns of the stack structures to each other.

According to an aspect, each of the connection parts may be formed in a pillar shape having a closed interior such that when each of the vertical channel patterns includes a back gate formed to extend in the vertical direction while at least a portion thereof is surrounded by the vertical channel pattern, the back gate is formed in a tube shape including an internal hole formed to extend in the vertical direction or when each of the vertical channel patterns includes a vertical semiconductor pattern, the vertical semiconductor pattern included in an upper stack structure and the vertical semiconductor pattern included in a lower stack structure among the stack structures are separated by the connection parts.

According to an embodiment, a method of manufacturing a three-dimensional flash memory includes preparing a lower stack structure including interlayer insulating films and gate electrodes formed to extend in a horizontal direction and alternately laminated in a vertical direction and vertical channel structures passing through the interlayer insulating films and the gate electrodes in the vertical direction, forming connection parts on the lower stack structure based on positions of the vertical channel structures in the lower stack structure, and forming, on the lower stack structure in which the connection parts are formed, an upper stack structure including the interlayer insulating films and the gate electrodes formed to extend in the horizontal direction and alternately laminated in the vertical direction and the vertical channel structures passing through the interlayer insulating films and the gate electrodes in the vertical direction.

According to an embodiment, a method of manufacturing a three-dimensional flash memory includes preparing a lower stack structure including interlayer insulating films and gate electrodes formed to extend in a horizontal direction and alternately laminated in a vertical direction and vertical channel structures passing through the interlayer insulating films and the gate electrodes in the vertical direction, forming connection parts on the lower stack structure based on positions of the vertical channel structures in the lower stack structure, forming, on the lower stack structure in which the connection parts are formed, an upper stack structure including the interlayer insulating films and the gate electrodes formed to extend in the horizontal direction and alternately laminated in the vertical direction and channel holes passing through the interlayer insulating films and the gate electrodes in the vertical direction, a data storage pattern and a vertical channel pattern among components of the vertical channel structures being formed on and extending from an inner side wall of each of the channel holes, forming channel connection holes passing through the connection parts in the vertical direction based on positions of the channel holes, and forming at least remaining component among the components of the vertical channel structures except for the data storage pattern and the vertical channel pattern on the inner side walls of the channel holes and inner side walls of the channel connection holes such that the at least remaining component extends in the vertical direction.

According to an aspect, the forming of the connection parts on the lower stack structure may include one of forming the connection parts in remaining spaces after an upper end portion of the lower stack structure is etched or forming the connection parts at an upper portion of the lower stack structure.

### Advantageous Effects of the Invention

Embodiments may propose a three-dimensional flash memory having a structure including connection parts that connect vertical channel patterns of stack structures to each other, a method of manufacturing the same, and an electronic system including the same.

In particular, embodiments may propose a three-dimensional flash memory having a structure in which the connection parts have curved edges while protruding from the vertical channel patterns in a horizontal direction, a method of manufacturing the same, and an electronic system including the same.

Further, embodiments may propose a three-dimensional flash memory having a structure in which the connection parts protrude from the vertical channel patterns in the horizontal direction, a method of manufacturing the same, and an electronic system including the same.

Thus, the three-dimensional flash memory according to embodiments may solve a problem of degradation of channel current characteristics due to misalignment of a vertical channel pattern in a stack laminating process.

However, effects of the present disclosure are not limited to the above effects and may be variously expanded without departing from the technical spirit and scope of the present disclosure.

### DESCRIPTION OF THE DRAWINGS

FIG. 1 is a schematic circuit diagram illustrating an array of a three-dimensional flash memory according to an embodiment.

FIG. 2 is a plan view illustrating a structure of the three-dimensional flash memory according to the embodiment.

FIG. 3 is a cross-sectional view illustrating the structure of the three-dimensional flash memory according to the embodiment and corresponds to a cross section along line A-A′ of FIG. 2.

FIG. 4 is a cross-sectional view for describing another implementation example of connection parts and a buffer layer included in the three-dimensional flash memory illustrated in FIG. 3 and corresponds to the cross section along line A-A′ of FIG. 2.

FIG. 5 is a cross-sectional view illustrating a structure of a three-dimensional flash memory according to another embodiment and corresponds to the cross section along line A-A′ of FIG. 2.

FIG. 6 is a cross-sectional view for describing another implementation example of connection parts and a buffer layer included in the three-dimensional flash memory illustrated in FIG. 5 and corresponds to the cross section along line A-A of FIG. 2.

FIG. 7 is a flowchart illustrating a method of manufacturing the three-dimensional flash memory illustrated in FIGS. 3 and 5.

FIGS. 8A to 8F are cross-sectional views illustrating the three-dimensional flash memory to describe the method illustrated in FIG. 7.

FIG. 9 is a flowchart illustrating a method of manufacturing a three-dimensional flash memory having the structure illustrated in FIGS. 4 and 6.

FIGS. 10A to 10F are cross-sectional views illustrating the three-dimensional flash memory to describe the method illustrated in FIG. 9.

FIG. 11 is a plan view illustrating the structure of the three-dimensional flash memory according to the embodiment.

FIG. 12 is a cross-sectional view illustrating the structure of the three-dimensional flash memory according to the embodiment and corresponds to the cross section along line A-A′ of FIG. 11.

FIG. 13 is a cross-sectional view for describing another implementation example of connection parts included in the three-dimensional flash memory illustrated in FIG. 12 and corresponds to a cross section along line A-A of FIG. 11.

FIG. 14 is a cross-sectional view illustrating the structure of the three-dimensional flash memory according to another embodiment and corresponds to the cross section along line A-A′ of FIG. 11.

FIG. 15 is a cross-sectional view for describing another implementation example of connection parts included in the three-dimensional flash memory illustrated in FIG. 14 and corresponds to the cross section along line A-A′ of FIG. 11.

FIG. 16 is a flowchart illustrating a method of manufacturing the three-dimensional flash memory illustrated in FIGS. 12 and 13.

FIGS. 17A to 17E are cross-sectional views illustrating the three-dimensional flash memory to describe the method illustrated in FIG. 16.

FIG. 18 is a flowchart illustrating a method of manufacturing the three-dimensional flash memory having a structure illustrated in FIGS. 14 and 15.

FIGS. 19A to 19G are cross-sectional views illustrating the three-dimensional flash memory to describe the method illustrated in FIG. 18.

FIG. 20 is a schematic perspective view illustrating an electronic system including the three-dimensional flash memory according to embodiments.

### BEST MODE

Hereinafter, embodiments of the present disclosure will be described in detail with reference to the accompanying drawing. However, the present disclosure is not restricted or limited by the embodiments. Further, the same reference numerals in each drawing indicate the same components.

Further, terms used in the specification are used to properly express the embodiments of the present disclosure, and the terms may change depending on the intention of a viewer or an operator or customs in the field to which the present disclosure belongs. Therefore, definitions of these terms should be made based on the content throughout the specification. For example, in the specification, a singular form also includes a plural form unless specifically mentioned in a phrase. Further, the term “comprise” and/or “comprising” used herein does not exclude the presence or addition of one or more other components, steps, operations, and/or elements in or to components, steps, operations, and/or elements mentioned above. Further, even though the terms such as first and second are used in the specification to describe various areas, directions, and shapes, the areas, directions, and shapes should not be limited by these terms. These terms are merely used to distinguish one area, direction or shape from another area, direction or shape. Thus, a portion/part referred to as a “first part/portion” in an embodiment may be referred to as a “second part/portion” in another embodiment.

Further, it should be understood that various embodiments of the present disclosure are different from each other but are not necessarily mutually exclusive. For example, specific shapes, specific structures, and specific characteristics described herein may be implemented in another embodiment without departing from the technical spirit and scope of the present disclosure in relation to the embodiment. Further, it should be understood that positions, arrangements, or configurations of individual components in the range of each presented embodiment may be changed without departing from the technical spirit and scope of the present disclosure.

Hereinafter, a three-dimensional flash memory, an operating method therefor, and an electronic system including the same according to embodiments will be described in detail with reference to the accompanying drawings.

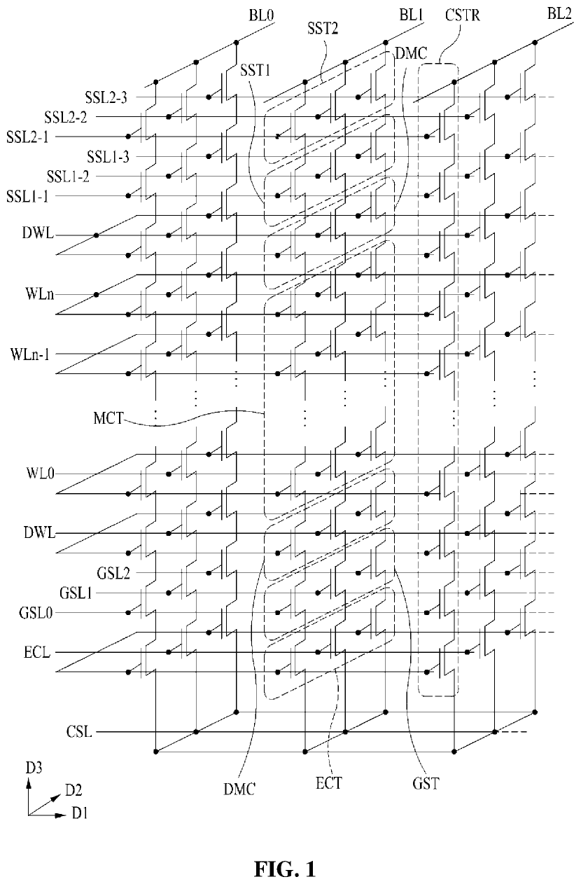

FIG. 1 is a schematic circuit diagram illustrating an array of a three-dimensional flash memory according to an embodiment.

Referring to FIG. 1, an array of the three-dimensional flash memory according to the embodiment may include a common source line CSL, a plurality of bit lines BL0, BL1, and BL2, and a plurality of cell strings CSTR arranged between the common source line CSL and the bit lines BL0, BL1, and BL2.

The bit lines BL0, BL1, and BL2 may be two-dimensionally arranged while being spaced apart from each other in a first direction D1 while extending in a second direction D2. Here, the first direction D1, the second direction D2, and a third direction D3 may be orthogonal to each other and may form a rectangular coordinate system defined by X, Y, and Z axes.

The plurality of cell strings CSTR may be connected in parallel to the bit lines BL0, BL1, and BL2, respectively. The cell strings CSTR may be commonly connected to the common source line CSL while being provided between the bit lines BL0, BL1, and BL2 and the one common source line CSL. In this case, a plurality of common source lines CSL may be provided, and the plurality of common source lines CSL may be two-dimensionally arranged while being spaced apart from each other in the second direction D2 while extending in the first direction D1. The same voltage may be electrically applied to the plurality of common source lines CSL, but the present disclosure is not restricted or limited thereto, and different voltages may be applied to the plurality of common source lines CSL as the plurality of common source lines CSL are electrically independently controlled.

The cell strings CSTR may be arranged spaced apart from each other in the second direction D2 for each bit line while extending in the third direction D3. According to an embodiment, each of the cell strings CSTR may include a ground selection transistor GST connected to the common source line CSL, first and second string selection transistors SST1 and SST2 connected to the bit lines BL0, BL1, and BL2 and connected in series to each other, memory cell transistors MCT arranged between the ground selection transistor GST and the first and second string selection transistors SST1 and SST2 and connected in series to each other, and an erasure control transistor ECT. Further, each of the memory cell transistors MCT may include a data storage element.

As an example, each of the cell strings CSTR may include the first and second string selection transistors SST1 and SST2 connected in series to each other, and the second string selection transistor SST2 may be connected to one of the bit lines BL0, BL1, and BL2. However, the present disclosure is not restricted or limited thereto, and each of the cell strings CSTR may include one string selection transistor. As another example, the ground selection transistor GST in each of the cell strings CSTR may include a plurality of metal oxide semiconductor (MOS) transistors connected in series to each other, which is similar to the first and second string selection transistors SST1 and SST2.

The one cell string CSTR may include the plurality of memory cell transistors MCT having different distances from the common source lines CSL. That is, the memory cell transistors MCT may be connected in series to each other while being arranged between the first string selection transistor SST1 and the ground selection transistor GST in the third direction D3. The erasure control transistor ECT may be connected between the ground selection transistor GST and the common source lines CSL. Each of the cell strings CSTR may further include dummy cell transistors DMC connected between the first string selection transistor SST1 and an uppermost one of the memory cell transistors MCT and between the ground selection transistor GST and a lowermost one of the memory cell transistors MCT.

According to the embodiment, the first string selection transistor SST1 may be controlled by first string selection lines SSL1-1, SSL1-2, and SSL1-3, and the second string selection transistor SST2 may be controlled by second string selection lines SSL2-1, SSL2-2, and SSL2-3. The memory cell transistors MCT may be respectively controlled by a plurality of word lines WL0 to WLn, and the dummy cell transistors DMC may be respectively controlled by dummy word lines DWL. The ground selection transistor GST may be controlled by ground selection lines GSL0, GSL1, and GSL2, and the erasure control transistor ECT may be controlled by an erasure control line ECL. A plurality of erasure control transistors ECT may be provided. The common source lines CSL may be commonly connected to sources of the erasure control transistors ECT.

Gate electrodes of the memory cell transistors MCT, which are provided at substantially the same distance from the common source lines CSL, may be commonly connected to one of the word lines WL0 to WLn and DWL and thus may be in an equipotential state. However, the present disclosure is not restricted or limited thereto, and even when the gate electrodes of the memory cell transistors MCT are provided at substantially the same level from the common source lines CSL, the gate electrodes provided in different rows or columns may be independently controlled.

The ground selection lines GSL0, GSL1, and GSL2, the first string selection lines SSL1-1, SSL1-2, and SSL1-3, and the second string selection lines SSL2-1, SSL2-2, and SSL2-3 may be two-dimensionally arranged while extending in the first direction D1 and being spaced apart from each other in the second direction D2. The ground selection lines GSL0, GSL1, and GSL2, the first string selection lines SSL1-1, SSL1-2, and SSL1-3, and the second string selection lines SSL2-1, SSL2-2, and SSL2-3, which are provided at substantially the same level from the common source lines CSL, may be electrically separated from each other. Further, the erasure control transistors ECT of different cell strings CSTR may be controlled by the common erasure control line ECL. The erasure control transistors ECT may generate gate induced drain leakage GIDL during an operation of erasing a memory cell array. In some embodiments, during the operation of erasing the memory cell array, an erasure voltage may be applied to the bit lines BL0, BL1, and BL2 and/or the common source lines CSL, and a gate induced leakage current may be generated in the string selection transistor SST and/or the erasure control transistors ECT.

The string selection line SSL may be expressed as an upper selection line USL, and the ground selection line GSL may be expressed as a lower selection line.

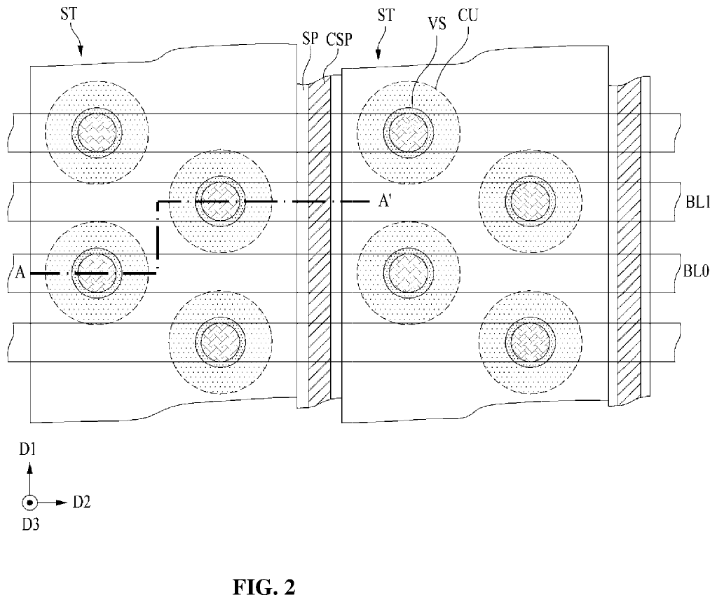

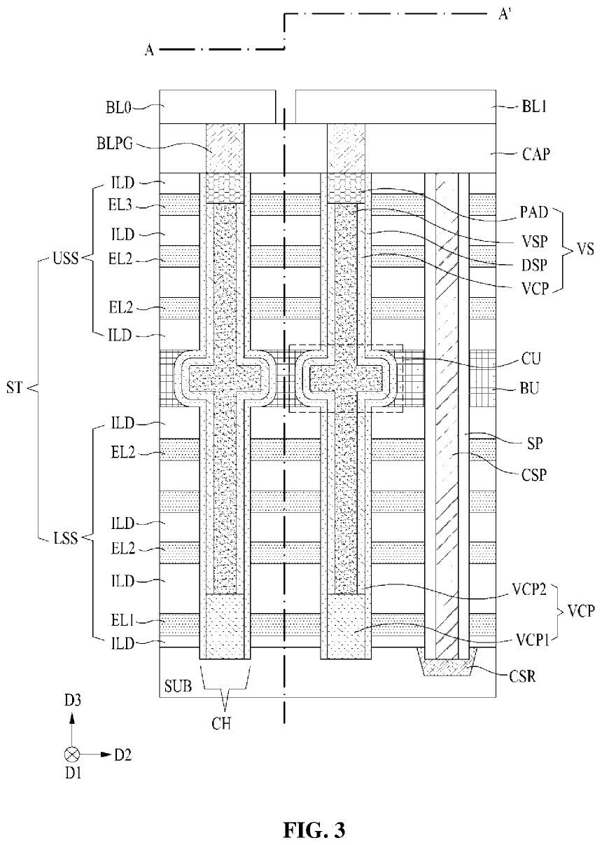

FIG. 2 is a plan view illustrating a structure of the three-dimensional flash memory according to the embodiment. FIG. 3 is a cross-sectional view illustrating the structure of the three-dimensional flash memory according to the embodiment and corresponds to a cross section along line A-A′ of FIG. 2.

Referring to FIGS. 2 and 3, a substrate SUB may be a semiconductor substrate such as a silicon substrate, a silicon-germanium substrate, a germanium substrate, or a single crystal epitaxial layer grown on a monocrystalline silicon substrate. The substrate SUB may be doped with first conductivity-type impurities (e.g., P-type impurities).

Laminated structures ST may be arranged on the substrate SUB. The laminated structures ST may be two-dimensionally arranged in the second direction D2 while extending in the first direction D1. Further, the laminated structures ST may be spaced apart from each other in the second direction D2.

Each of the laminated structures ST may include gate electrodes EL1, EL2, and EL3 alternately laminated in a vertical direction perpendicular to an upper surface of the substrate SUB (e.g., in the third direction D3), and interlayer insulating films ILD. The laminated structures ST may have substantially flat upper surfaces. That is, the upper surfaces of the laminated structures ST may be parallel to the upper surface of the substrate SUB. Hereinafter, the vertical direction means the third direction D3 or a direction opposite to the third direction D3.

Returning to FIG. 1, each of the gate electrodes EL1, EL2, and EL3 may be one of the erasure control line ECL, the ground selection lines GSL0, GSL1, and GSL2, the word lines WL0 to WLn and DWL, the first string selection lines SSL1-1, SSL1-2, and SSL1-3, and the second string selection lines SSL2-1, SSL2-2, and SSL2-3 that are sequentially laminated on the substrate SUB.

Each of the gate electrodes EL1, EL2, and EL3 may have substantially the same thickness in the third direction D3 while extending in the first direction D1. Hereinafter, the thickness means a thickness in the third direction D3. Each of the gate electrodes EL1, EL2, and EL3 may be formed of a conductive material. For example, each of the gate electrodes EL1, EL2, and EL3 may include at least one selected from a doped semiconductor (e.g., a doped silicon or the like), a metal (e.g., W (tungsten), Cu (copper), Al (aluminum), Ti (titanium), Ta (tantalum), Mo (molybdenum), Ru (ruthenium), Au (gold), or the like), a conductive metal nitride (e.g., a titanium nitride, a tantalum nitride, or the like) or the like. Each of the gate electrodes EL1, EL2, and EL3 may include at least one of all metal materials that may be formed by ALD in addition to the metal material described above.

In more detail, the gate electrodes EL1, EL2, and EL3 may include the lowermost first gate electrode EL1, the uppermost third gate electrode EL3, and a plurality of second gate electrodes EL2 between the first gate electrode EL1 and the third gate electrode EL3. Although each of the first gate electrode EL1 and the third gate electrode EL3 is illustrated and described in a singular number, this is exemplary, and the present disclosure is not limited thereto. As needed, a plurality of first gate electrodes EL1 and a plurality of third gate electrodes EL3 may also be provided. The first gate electrode EL1 may correspond to one of the ground selection lines GSL0, GSL1, and GSL2 illustrated in FIG. 1. The second gate electrode EL2 may correspond to any one of the word lines WL0 to WLn and DWL illustrated in FIG. 1. The third gate electrode EL3 may correspond to any one of the first string selection lines SSL1-1, SSL1-2, and SSL1-3 or any one of the second string selection lines SSL2-1, SSL2-2, and SSL2-3 illustrated in FIG. 1.

Although not illustrated, an end of each of the laminated structures ST may have a stepwise structure in the first direction D1. In more detail, lengths of the gate electrodes EL1, EL2, and EL3 of the laminated structures ST in the first direction D1 may decrease as a distance from the substrate SUB increases. The third gate electrode EL3 may have the smallest length in the first direction D1 and the largest distance from the substrate SUB in the third direction D3. The first gate electrode EL1 may have the largest length in the first direction D1 and the smallest distance from the substrate SUB in the third direction D3. Due to the stepwise structure, a thickness of each of the laminated structures ST may decrease as a distance from an outermost one of vertical channel structures VS, which will be described below, increases, and side walls of the gate electrodes EL1, EL2, and EL3 may be spaced apart from each other at regular intervals in the first direction D1 when viewed from a plane.

The interlayer insulating films ILD may have different thicknesses. As an example, a lowermost one and an uppermost one of the interlayer insulating films ILD may have a thickness that is smaller than those of the other interlayer insulating films ILD. However, this is exemplary, and the present disclosure is not limited thereto. The interlayer insulating films ILD may be set to have different thickness or the same thickness according to characteristics of a semiconductor device. The interlayer insulating films ILD may be formed of an insulating material to insulate the gate electrodes EL1, EL2, and EL3 from each other. As an example, the interlayer insulating films ILD may be formed of a silicon oxide.

A plurality of channel holes CH passing through portions of the laminated structures ST and the substrate SUB may be provided. The vertical channel structures VS may be provided in the channel holes CH. The vertical channel structures VS, which are the plurality of cell strings CSTR illustrated in FIG. 1, may extend in the third direction D3 while being connected to the substrate SUB. A state in which the vertical channel structures VS are connected to the substrate SUB may mean that a portion of each of the vertical channel structures VS is buried inside the substrate SUB, but the present disclosure is not restricted or limited thereto. For example, the vertical channel structures VS may be formed such that lower surfaces of the vertical channel structures VS are in contact with the upper surface of the substrate SUB. When the portion of each of the vertical channel structures VS is buried inside the substrate SUB, the lower surfaces of the vertical channel structures VS may be positioned to be lower in level than the upper surface of the substrate SUB.

A plurality of columns of the vertical channel structures VS passing through any one of the laminated structures ST may be provided. For example, as illustrated in FIG. 2, columns of two vertical channel structures VS may penetrate one of the laminated structures ST. However, the present disclosure is not restricted or limited thereto. For example, columns of three or more vertical channel structures VS may penetrate one of the laminated structures ST. In a pair of adjacent columns, the vertical channel structures VS corresponding to one column may be shifted in the first direction D1 from the vertical channel structures VS corresponding to the other column adjacent thereto. When viewed from a plane, the vertical channel structures VS may be arranged in a zigzag shape in the first direction D1. However, the present disclosure is not restricted or limited thereto, and the vertical channel structures VS may form an array in which the vertical channel structures VS are arranged side by side in rows and columns.

Each of the vertical channel structures VS may extend from the substrate SUB in the third direction D3. In the drawing, each of the vertical channel structures VS is illustrated as having a column shape having the same width at an upper end and a lower end thereof, but the present disclosure is not restricted or limited thereto, and each of the vertical channel structures VS may have a shape of which widths in the first direction D1 and the second direction D2 increase toward the third direction D3. This is caused due to the limitation that when the channel holes CH are etched, the widths in the first direction D1 and the second direction D2 decrease as it goes in an opposite direction to the third direction D3. The upper surface of each of the vertical channel structures VS may have a circular shape, an oval shape, a quadrangular shape, or a bar shape.

Each of the vertical channel structures VS may include a data storage pattern DSP, a vertical channel pattern VCP, a vertical semiconductor pattern VSP, and a conductive pad PAD. In each of the vertical channel structures VS, the lower end of the data storage pattern DSP may have the shape of an opened pipe or a macaroni, and the lower end of the vertical channel pattern VCP may have the shape of a closed pipe or a macaroni. The vertical semiconductor pattern VSP may fill a space surrounded by the vertical channel pattern VCP and the conductive pad PAD.

While covering an inner side wall of each of the channel holes CH, the data storage pattern DSP may be in contact with the vertical channel pattern VCP inwardly and may be in contact with the side walls of the gate electrodes EL1, EL2, and EL3 outwardly. As such, areas of the data storage pattern DSP, which correspond to the second gate electrodes EL2, may constitute memory cells, in which a memory operation (e.g., a program operation, a read operation, or an erase operation) is performed by voltages applied through the second gate electrodes EL2, together with areas of the vertical channel pattern VCP, which correspond to the second gate electrodes EL2. The memory cells correspond to the memory cell transistors MCT illustrated in FIG. 1. That is, the data storage pattern DSP may trap charges or holes by the voltages applied through the second gate electrodes EL2 or may maintain a state of charges (e.g., a polarization state of charges) by the voltages applied through the second gate electrodes EL2, and thus, the data storage pattern DSP may serve as data storage in the three-dimensional flash memory. For example, an (Tunneling Oxide-Charge trap Nitride-Blocking Oxide) ONO layer or a ferroelectric layer may be used as the data storage pattern DSP. The data storage pattern DSP may indicate a binary data value or a multi-bit (multi-level) data value through a change in the amount of trapped charges or holes or may indicate a binary data value or a multi-bit (multi-level) data value through a state change of charges.

The vertical channel pattern VCP may cover an inner side wall of the data storage pattern DSP. The vertical channel pattern VCP may include a first part VCP1 and a second part VCP2 on the first part VCP1.

The first part VCP1 of the vertical channel pattern VCP may be provided under each of the channel holes CH and may be in contact with the substrate SUB. The first part VCP1 of the vertical channel pattern VCP may be used to block, suppress, or minimize a leakage current in each of the vertical channel structures VS and/or to form an epitaxial pattern. A thickness of the first part VCP1 of the vertical channel pattern VCP may be greater than, for example, a thickness of the first gate electrode EL1. A side wall of the first part VCP1 of the vertical channel pattern VCP may be surrounded by the data storage pattern DSP. An upper surface of the first part VCP1 of the vertical channel pattern VCP may be positioned at a higher level than that of an upper surface of the first gate electrode EL1. In more detail, the upper surface of the first part VCP1 of the vertical channel pattern VCP may be positioned between the upper surface of the first gate electrode EL1 and a lower surface of a lowermost one of the second gate electrodes EL2. A lower surface of the first part VCP1 of the vertical channel pattern VCP may be positioned at a lower level than an uppermost surface of the substrate SUB (i.e., a lower surface of a lowermost one of the interlayer insulating films ILD). A portion of the first part VCP1 of the vertical channel pattern VCP may overlap the first gate electrode EL1 in the horizontal direction. Hereinafter, the horizontal direction refers to a predetermined direction extending on a plane parallel to the first direction D1 and the second direction D2.

The second part VCP2 of the vertical channel pattern VCP may extend from the upper surface of the first part VCP1 in the third direction D3. The second part VCP2 of the vertical channel pattern VCP may be provided between the data storage pattern DSP and the vertical semiconductor pattern VSP and may correspond to the second gate electrodes EL2. Accordingly, as described above, the second part VCP2 of the vertical channel pattern VCP may constitute the memory cells together with the areas of the data storage pattern DSP, which correspond to the second gate electrodes EL2.

An upper surface of the second part VCP2 of the vertical channel pattern VCP may be substantially coplanar with an upper surface of the vertical semiconductor pattern VSP. The upper surface of the second part VCP2 of the vertical channel pattern VCP may be positioned at a level higher than an upper surface of an uppermost one of the second gate electrodes EL2. In more detail, the upper surface of the second part VCP2 of the vertical channel pattern VCP may be positioned between an upper surface and a lower surface of the third gate electrode EL3.

The vertical channel pattern VCP, which is a component transferring charges or holes to the data storage pattern DSP, may be formed of monocrystalline silicon or polysilicon such that a channel is formed or boosted by a voltage applied thereto. However, the present disclosure is not restricted or limited thereto. For example, the vertical channel pattern VCP may be formed of an oxide semiconductor material capable of blocking, suppressing, or minimizing a leakage current. For example, the vertical channel pattern VCP may be formed of an oxide semiconductor material including at least one of In, Zn, and Ga having excellent leakage current characteristics, or a group 4 semiconductor material. The vertical channel pattern VCP may be formed of, for example, a ZnOx-based material including AZO, ZTO, IZO, ITO, IGZO, or Ag—ZnO. Thus, the vertical channel pattern VCP may block, suppress, or minimize a leakage current to the gate electrodes EL1, EL2, and EL3 or the substrate SUB, may improve transistor characteristics (e.g., a threshold voltage distribution and a program/read operation speed) of at least one of the gate electrodes EL1, EL2, and EL3, and as a result, may improve electrical characteristics of the three-dimensional flash memory.

The vertical semiconductor pattern VSP may be surrounded by the second part VCP2 of the vertical channel pattern VCP. The upper surface of the vertical semiconductor pattern VSP may be in contact with the conductive pad PAD, and a lower surface of the vertical semiconductor pattern VSP may be in contact with the first part VCP1 of the vertical channel pattern VCP. The vertical semiconductor pattern VSP may be spaced apart from the substrate SUB in the third direction D3. In other words, the vertical semiconductor pattern VSP may be electrically floated from the substrate SUB.

The vertical semiconductor pattern VSP may be formed of a material that helps diffusion of charges or holes in the vertical channel pattern VCP. In more detail, the vertical semiconductor pattern VSP may be formed of a material having excellent charge and hole mobility. For example, the vertical semiconductor pattern VSP may be formed of a semiconductor material doped with impurities, an intrinsic semiconductor material not doped with impurities, or a polycrystalline semiconductor material. For a more detailed example, the vertical semiconductor pattern VSP may be formed of a polysilicon doped with first conductivity-type impurities, which is like the impurities of the substrate SUB (e.g., P-type impurities). That is, the vertical semiconductor pattern VSP may improve the electrical characteristics of the three-dimensional flash memory to increase a memory operation speed.

Returning to FIG. 1, the vertical channel structures VS may correspond to channels of the erasure control transistor ECT, the first and second string selection transistors SST1 and SST2, the ground selection transistor GST, and the memory cell transistors MCT.

The conductive pad PAD may be provided on the upper surface of the second part VCP2 of the vertical channel pattern VCP and on the upper surface of the vertical semiconductor pattern VSP. The conductive pad PAD may be connected to an upper portion of the vertical channel pattern VCP and an upper portion of the vertical semiconductor pattern VSP. A side wall of the conductive pad PAD may be surrounded by the data storage pattern DSP. An upper surface of the conductive pad PAD may be substantially coplanar with the upper surface of each of the laminated structures ST (i.e., an upper surface of the uppermost one of the interlayer insulating films ILD). A lower surface of the conductive pad PAD may be positioned at a lower level than that of an upper surface of the third gate electrode EL3. In more detail, the lower surface of the conductive pad PAD may be positioned between the upper surface and the lower surface of the third gate electrode EL3. That is, at least a portion of the conductive pad PAD may overlap the third gate electrode EL3 in the horizontal direction.

The conductive pad PAD may be formed of a semiconductor doped with impurities or a conductive material. For example, the conductive pad PAD may be formed of a semiconductor material doped with impurities different from those of the vertical semiconductor pattern VSP (in more detail, second conductivity-type (e.g., N-type) impurities different from the first conductivity-type (e.g., P-type) impurities).

The conductive pad PAD may reduce contact resistance between a bit line BL, which will be described below, and the vertical channel pattern VCP (or the vertical semiconductor pattern VSP).

Hereinafter, it has been described that the vertical channel structures VS have a structure including the conductive pad PAD, but the present disclosure is not restricted or limited thereto, and the vertical channel structures VS may have a structure in which the conductive pad PAD is omitted. In this case, as the conductive pad PAD is omitted from the vertical channel structures VS, each of the vertical channel pattern VCP and the vertical semiconductor pattern VSP may extend in the third direction D3 so that an upper surface of each of the vertical channel pattern VCP and the vertical semiconductor pattern VSP are substantially coplanar with the upper surface of each of the laminated structures ST (i.e., the upper surface of the uppermost one of the interlayer insulating films ILD). Further, in this case, a bit line contact plug BLPG, which will be described below, may be in direct contact with and electrically connected to the vertical channel pattern VCP instead of being indirectly electrically connected to the vertical channel pattern VCP through the conductive pad PAD.

Further, it has been described that the vertical channel structures VS include the vertical semiconductor pattern VSP, but the present disclosure is not restricted or limited thereto, and the vertical semiconductor pattern VSP may be omitted.

Further, it has been described that the vertical channel pattern VCP has a structure including the first part VCP1 and the second part VCP2, but the present disclosure is not restricted or limited thereto, and the vertical channel pattern VCP may have a structure in which the first part VCP1 is excluded. For example, the vertical channel pattern VCP may be provided between the vertical semiconductor pattern VSP that extends to the substrate SUB and the data storage pattern DSP and may extend to the substrate SUB to be in contact with the substrate SUB. In this case, a lower surface of the vertical channel pattern VCP may be positioned at a lower level than that of the uppermost surface of the substrate SUB (the lower surface of the lowermost one of the interlayer insulating films ILD), and an upper surface of the vertical channel pattern VCP may be substantially coplanar with the upper surface of the vertical semiconductor pattern VSP.

A separation trench TR extending in the first direction D1 may be provided between the adjacent laminated structures ST. A common source area CSR may be provided inside the substrate SUB exposed by the separation trench TR. The common source area CSR may extend in the first direction D1 within the substrate SUB. The common source area CSR may be formed of a semiconductor material doped with second conductivity-type impurities (e.g., N-type impurities). The common source area CSR may correspond to the common source line CSL of FIG. 1.

A common source plug CSP may be provided inside the separation trench TR. The common source plug CSP may be connected to the common source area CSR. An upper surface of the common source plug CSP may be substantially coplanar with the upper surface of each of the laminated structures ST (i.e., the upper surface of the uppermost one of the interlayer insulating films ILD). The common source plug CSP may have a plate shape extending in the first direction D1 and the third direction D3. In this case, the common source plug CSP may have a shape of which a width in the second direction D2 increases toward the third direction D3.

Insulation spacers SP may be interposed between the common source plug CSP and the laminated structures ST. The insulation spacers SP may be provided between the adjacent laminated structures ST to face each other. For example, the insulation spacers SP may be formed of a silicon oxide, a silicon nitride, a silicon oxy nitride, or a low-k material having a low dielectric constant.

A capping insulating film CAP may be provided on the laminated structures ST, the vertical channel structures VS, and the common source plug CSP. The capping insulating film CAP may cover the upper surface of the uppermost one of the interlayer insulating films ILD, the upper surface of the conductive pad PAD, and the upper surface of the common source plug CSP. The capping insulating film CAP may be formed of an insulating material different from that of the interlayer insulating films ILD. The bit line contact plug BLPG electrically connected to the conductive pad PAD may be provided inside the capping insulating film CAP. The bit line contact plug BLPG may have a shape of which widths in the first direction D1 and the second direction D2 increase in the third direction D3.

The bit line BL may be provided on the capping insulating film CAP and the bit line contact plug BLPG. The bit line BL corresponds to any one of the plurality of bit lines BL0, BL1, and BL2 illustrated in FIG. 1, and may be formed of a conductive material to extend in the second direction D2. The conductive material constituting the bit line BL may be the same material as the conductive material forming each of the gate electrodes EL1, EL2, and EL3.

The bit line BL may be electrically connected to the vertical channel structures VS through the bit line contact plug BLPG. Here, the fact that the bit line BL is connected to the vertical channel structures VS may mean that the bit line BL is connected to the vertical channel patterns VCP included in the vertical channel structures VS.

The three-dimensional flash memory having such a structure may perform the program operation, the read operation, and the erasure operation based on a voltage applied to each of the cell strings CSTR, a voltage applied to the string selection line SSL, a voltage applied to each of the word lines WL0 to WLn, a voltage applied to the ground selection line GSL, and a voltage applied to the common source line CSL. For example, the three-dimensional flash memory may perform the program operation by forming a channel in the vertical channel pattern VCP and transferring charges or holes to the data storage pattern DSP of a target memory cell, based on the voltage applied to each of the cell strings CSTR, the voltage applied to the string selection line SSL, the voltage applied to each of the word lines WL0 to WLn, the voltage applied to the ground selection line GSL, and the voltage applied to the common source line CSL.

Further, the three-dimensional flash memory according to an embodiment is not restricted or limited to the above structure, and according to an implementation example, the three-dimensional flash memory may be implemented in various structures under a condition that the vertical channel pattern VCP, the data storage pattern DSP, the gate electrodes EL1, EL2, and EL3, the bit line BL, and the common source line CSL are included.

As the three-dimensional flash memory having such a structure is manufactured through a stack laminating process, each of the laminated structures ST may include an upper stack structure USS and a lower stack structure LSS. The lower stack structure LSS may be disposed on the substrate SUB and include the gate electrodes (portions of EL1 and EL2) and the interlayer insulating films ILD that are vertically and alternately laminated. The upper stack structure USS may be laminated on the lower stack structure LSS and include the gate electrodes (a portion of EL2 and EL3) and the interlayer insulating films ILD that are vertically and alternately laminated.

When the lower stack structure LSS and the upper stack structure USS are laminated, the vertical channel structures VS included in the lower stack structure LSS and the vertical channel structures VS included in the upper stack structure USS may be misaligned. For example, when the vertical channel patterns VCP of the lower stack structure LSS and the vertical channel patterns VCP of the upper stack structure USS are misaligned, channel current characteristics may be degraded. Thus, each of the laminated structures ST of the three-dimensional flash memory may include connection parts CU that connect the vertical channel patterns VCP of the stack structures USS and LSS to each other while being arranged between the upper stack structure USS and the lower stack structure LSS. These connection parts CU are formed in spaces obtained by etching a portion of a buffer layer BU, which is positioned between the upper stack structure USS and the lower stack structure LSS, in the horizontal direction (the first direction D1 and the second direction D2), and thus may be accommodated by the buffer layer BU.

Further, the connection parts CU formed on inner walls of the spaces obtained by etching the portion of the buffer layer BU in the horizontal direction are collectively formed through the same process as that of the vertical channel structures VS formed in the channel holes CH of each of the upper stack structures USS and the lower stack structures LSS. Thus, each of the connection parts CU may include a first connection portion CU1 formed of the same material as that of the data storage pattern DSP, a second connection portion CU2 formed of the same material as that of the vertical channel pattern VCP, and a third connection portion CU3 formed of the same material as that of the vertical semiconductor pattern VSP.

In particular, the connection parts CU may have curved edges while protruding from the vertical channel patterns VCP in the horizontal direction, respectively. In more detail, the connection parts CU may have sizes in which the vertical channel patterns VCP are accommodated on a plane and thus may have shapes protruding from the vertical channel patterns VCP in the horizontal direction, respectively. Further, the connection parts CU may be formed at positions, in which the vertical channel patterns VCP are accommodated, to connect the vertical channel patterns VCP of the upper and lower stack structures USS and LSS to each other.

In this way, the reason why the connection parts CU have curved edges while protruding is that the connection parts CU are formed on side walls of remaining portions having an undercut shape after the portion of the buffer layer BU is etched. That is, the side walls in which the portion of the buffer layer BU in the horizontal direction is wet-etched (the side walls of remaining portions after the wet etching is performed) may have an undercut shape. The connection parts CU are formed on the side walls of the remaining portions after the wet etching and thus may have curved edges while protruding in the horizontal direction.

To this end, the buffer layer BU may be formed of a material capable of performing wet etching. Here, the material on which the wet etching may be performed may include at least one material among a silicon oxide or a metal oxide (e.g., a silicon nitride, a silicon oxide, a silicon carbide, or a silicon oxy nitride).

As described above, the three-dimensional flash memory includes the connection parts CU, to connect the vertical channel patterns VCP of the stack structures USS and LSS to each other so as to solve a problem of degrading the channel current characteristics.

It has been described above that the three-dimensional flash memory is manufactured through the stack laminating process, and thus includes the upper stack structure USS and the lower stack structure LSS. However, the number of stack structures laminated in the stack laminating process is adjusted, and thus the three-dimensional flash memory may include three or more stack structures (e.g., the upper stack structure USS, a middle stack structure MSS, and the lower stack structure LSS). In this case, groups of the connection parts CU, which are arranged in the horizontal direction (the first direction D1 and the second direction D2), are spaced apart from each other in the third direction D3, and the connection parts CU may be arranged at connection portions of the stack structures. A plurality of buffer layers BU may be provided to surround the groups of the connection parts CU spaced apart from each other in the third direction D3, and may be spaced apart from each other in the third direction D3.

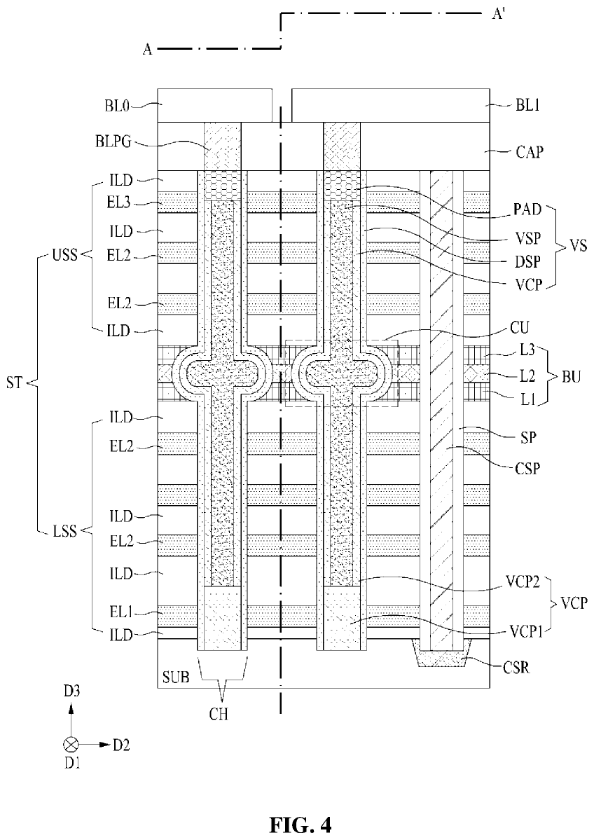

FIG. 4 is a cross-sectional view for describing another implementation example of connection parts and a buffer layer included in the three-dimensional flash memory illustrated in FIG. 3 and corresponds to the cross section along line A-A′ of FIG. 2.

Hereinafter, the three-dimensional flash memory described with reference to FIG. 4 has all the same components as those of the three-dimensional flash memory described above with reference to FIG. 3 but only a structure of the buffer layer BU is different therebetween. Accordingly, only the buffer layer BU having a different structure will be described below.

The connection parts CU illustrated in FIG. 4 may also have curved edges while protruding from the vertical channel patterns VCP in the horizontal direction. In this way, the reason why the connection parts CU have curved edges while protruding is that the connection parts CU are formed on the side walls of the remaining portions having an undercut shape after the portion of the buffer layer BU is etched, which is like the description with reference to FIG. 3.

However, the buffer layer BU illustrated in FIG. 4 is different from the buffer layer BU illustrated in FIG. 3 in that, as a plurality of layers L1, L2, and L3 having different etching ratios are laminated in the vertical direction, the etched side walls have an undercut shape even through dry etching as well as the wet etching. That is, as the buffer layer BU is configured such that the plurality of layers L1, L2, and L3 having different etching ratios are laminated in the vertical direction, the side walls on which the etching is performed on a portion of the buffer layer BU in the horizontal direction (the side walls of the remaining portions after the etching) have an undercut shape, and the connection parts CU are formed on the side walls of the remaining portions after the etching and thus may have curved edges while protruding in the horizontal direction.

In relation to the fact that the buffer layer BU is configured as the plurality of layers L1, L2, and L3 having different etching ratios are laminated in the vertical direction, the layer L2 positioned in a center of the plurality of layers L1, L2, and L3 in the vertical direction has a higher etching ratio than that of the layers L1 and L3 positioned at edges so that the side walls on which the etching is performed have an undercut shape.

It has been described that the buffer layer BU includes the three layers L1, L2, and L3, but the present disclosure is not restricted or limited thereto, and the buffer layer BU may include four or more layers. In this case, the four layers may have a high etching ratio as they are closer to the center in the vertical direction and has a low etching ratio as they are closer to the edges.

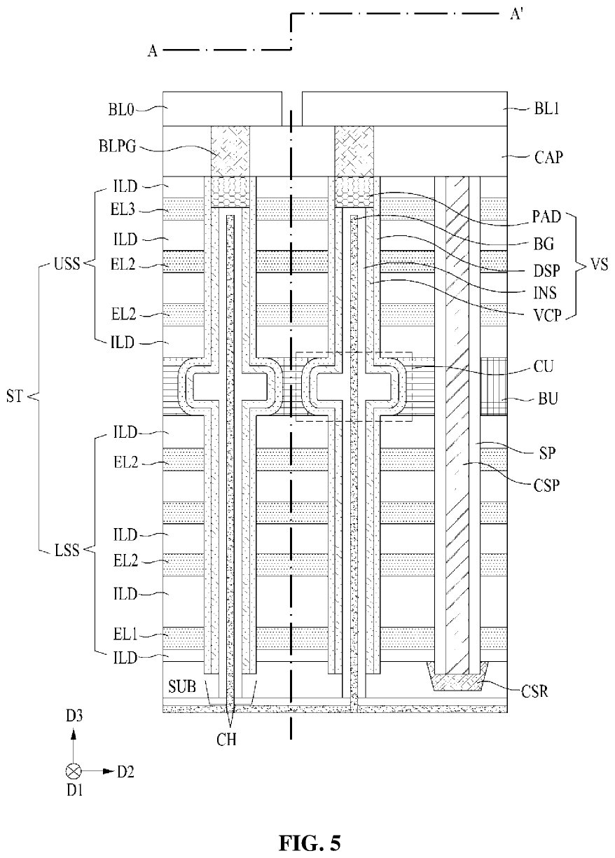

FIG. 5 is a cross-sectional view illustrating a structure of a three-dimensional flash memory according to another embodiment and corresponds to the cross section along line A-A′ of FIG. 2.

Referring to FIG. 5, the substrate SUB may be a semiconductor substrate such as a silicon substrate, a silicon-germanium substrate, a germanium substrate, or a monocrystalline silicon substrate on which a monocrystalline epitaxial layer is grown. The substrate SUB may be doped with first conductivity-type impurities (e.g., P-type impurities).

Laminated structures ST may be arranged on the substrate SUB. The laminated structures ST may be two-dimensionally arranged in the second direction D2 while extending in the first direction D1. Further, the laminated structures ST may be spaced apart from each other in the second direction D2.

Each of the laminated structures ST may include the gate electrodes EL1, EL2, and EL3 alternately laminated in the vertical direction perpendicular to the upper surface of the substrate SUB (e.g., in the third direction D3), and the interlayer insulating films ILD. The laminated structures ST may have substantially flat upper surfaces. That is, the upper surfaces of the laminated structures ST may be parallel to the upper surface of the substrate SUB. Hereinafter, the vertical direction means the third direction D3 or a direction opposite to the third direction D3.

Returning to FIG. 1, each of the gate electrodes EL1, EL2, and EL3 may be one of the erasure control line ECL, the ground selection lines GSL0, GSL1, and GSL2, the word lines WL0 to WLn and DWL, the first string selection lines SSL1-1, SSL1-2, and SSL1-3, and the second string selection lines SSL2-1, SSL2-2, and SSL2-3 that are sequentially laminated on the substrate SUB.

Each of the gate electrodes EL1, EL2, and EL3 may have substantially the same thickness in the third direction D3 while extending in the first direction D1. Hereinafter, the thickness means a thickness in the third direction D3. Each of the gate electrodes EL1, EL2, and EL3 may be formed of a conductive material. For example, each of the gate electrodes EL1, EL2, and EL3 may include at least one selected from a doped semiconductor (e.g., a doped silicon or the like), a metal (e.g., W (tungsten), Cu (copper), Al (aluminum), Ti (titanium), Ta (tantalum), Mo (molybdenum), Ru (ruthenium), Au (gold), or the like), a conductive metal nitride (e.g., a titanium nitride, a tantalum nitride, or the like) or the like. Each of the gate electrodes EL1, EL2, and EL3 may include at least one of all metal materials that may be formed by ALD in addition to the metal material described above.

In more detail, the gate electrodes EL1, EL2, and EL3 may include the lowermost first gate electrode EL1, the uppermost third gate electrode EL3, and the plurality of second gate electrodes EL2 between the first gate electrode EL1 and the third gate electrode EL3. Although each of the first gate electrode EL1 and the third gate electrode EL3 is illustrated and described in a singular number, this is exemplary, and the present disclosure is not limited thereto. As needed, the plurality of first gate electrodes EL1 and the plurality of third gate electrodes EL3 may also be provided. The first gate electrode EL1 may correspond to one of the ground selection lines GSL0, GSL1, and GLS2 illustrated in FIG. 1. The second gate electrode EL2 may correspond to any one of the word lines WL0 to WLn and DWL illustrated in FIG. 1. The third gate electrode EL3 may correspond to any one of the first string selection lines SSL1-1, SSL1-2, and SSL1-3 or any one of the second string selection lines SSL2-1, SSL2-2, and SSL2-3 illustrated in FIG. 1.

Although not illustrated, an end of each of the laminated structures ST may have a stepwise structure in the first direction D1. In more detail, the lengths of the gate electrodes EL1, EL2, and EL3 of the laminated structures ST in the first direction D1 may decrease as a distance from the substrate SUB increases. The third gate electrode EL3 may have the smallest length in the first direction D1 and the largest distance from the substrate SUB in the third direction D3. The first gate electrode EL1 may have the largest length in the first direction D1 and the smallest distance from the substrate SUB in the third direction D3. Due to the stepwise structure, the thickness of each of the laminated structures ST may decrease as the distance from the outermost one of the vertical channel structures VS, which will be described below, increases, and the side walls of the gate electrodes EL1, EL2, and EL3 may be spaced apart from each other at regular intervals in the first direction D1 when viewed from a plane.

The interlayer insulating films ILD may have different thicknesses. As an example, the lowermost one and the uppermost one of the interlayer insulating films ILD may have a thickness that is smaller than those of the other interlayer insulating films ILD. However, this is exemplary, and the present disclosure is not limited thereto. The interlayer insulating films ILD may be set to have different thickness or the same thickness according to characteristics of a semiconductor device. The interlayer insulating films ILD may be formed of an insulating material to insulate the gate electrodes EL1, EL2, and EL3 from each other. As an example, the interlayer insulating films ILD may be formed of a silicon oxide.

A plurality of channel holes CH passing through portions of the laminated structures ST and the substrate SUB may be provided. The vertical channel structures VS may be provided in the channel holes CH. The vertical channel structures VS, which are the plurality of cell strings CSTR illustrated in FIG. 1, may extend in the third direction D3 while being connected to the substrate SUB. A state in which the vertical channel structures VS are connected to the substrate SUB may mean that the portion of each of the vertical channel structures VS is buried inside the substrate SUB, but the present disclosure is not restricted or limited thereto. For example, the vertical channel structures VS may be formed such that the lower surfaces of the vertical channel structures VS are in contact with the upper surface of the substrate SUB. When the portion of each of the vertical channel structures VS is buried inside the substrate SUB, the lower surfaces of the vertical channel structures VS may be positioned to be lower in level than the upper surface of the substrate SUB.

A plurality of columns of the vertical channel structures VS passing through any one of the laminated structures ST may be provided. For example, as illustrated in FIG. 2, the columns of two vertical channel structures VS may penetrate one of the laminated structures ST. However, the present disclosure is not restricted or limited thereto. For example, columns of three or more vertical channel structures VS may penetrate one of the laminated structures ST. In a pair of adjacent columns, the vertical channel structures VS corresponding to one column may be shifted in the first direction D1 from the vertical channel structures VS corresponding to the other column adjacent thereto. When viewed from a plane, the vertical channel structures VS may be arranged in a zigzag shape in the first direction D1. However, the present disclosure is not restricted or limited thereto, and the vertical channel structures VS may form an array in which the vertical channel structures VS are arranged side by side in rows and columns.

Each of the vertical channel structures VS may extend from the substrate SUB in the third direction D3. In the drawing, each of the vertical channel structures VS is illustrated as having a column shape having the same width at an upper end and a lower end thereof, but the present disclosure is not restricted or limited thereto, and each of the vertical channel structures VS may have a shape of which widths in the first direction D1 and the second direction D2 increase toward the third direction D3. This is caused due to the limitation that when the channel holes CH are etched, the widths in the first direction D1 and the second direction D2 decrease as it goes in an opposite direction to the third direction D3. The upper surface of each of the vertical channel structures VS may have a circular shape, an oval shape, a quadrangular shape, or a bar shape.

Each of the vertical channel structures VS may include the data storage pattern DSP, the vertical channel pattern VCP, a back gate BG, and the conductive pad PAD. In each of the vertical channel structures VS, the lower end of the data storage pattern DSP may have the shape of an opened pipe or a macaroni, and the lower end of the vertical channel pattern VCP may have the shape of a closed pipe or a macaroni. The back gate BG may be formed to apply a voltage to the vertical channel pattern VCP, with at least a portion thereof surrounded by the vertical channel pattern VCP. Hereinafter, the fact that the back gate BG is included in the vertical channel pattern VCP may mean a state in which at least a portion of the back gate BG is surrounded by the vertical channel pattern VCP as described above.

While covering the inner side wall of each of the channel holes CH, the data storage pattern DSP may be in contact with the vertical channel pattern VCP inwardly and may be in contact with the side walls of the gate electrodes EL1, EL2, and EL3 outwardly. As such, the areas of the data storage pattern DSP, which correspond to the second gate electrodes EL2, may constitute the memory cells, in which the memory operation (e.g., the program operation, the read operation, or the erase operation) is performed by voltages applied through the second gate electrodes EL2, together with the areas of the vertical channel pattern VCP, which correspond to the second gate electrodes EL2. The memory cells correspond to the memory cell transistors MCT illustrated in FIG. 1. That is, the data storage pattern DSP may trap the charges or holes by the voltages applied through the second gate electrodes EL2 or may maintain the state of the charges (e.g., the polarization state of the charges) by the voltages applied through the second gate electrodes EL2, and thus, the data storage pattern DSP may serve as data storage in the three-dimensional flash memory. For example, the ONO layer or the ferroelectric layer may be used as the data storage pattern DSP. The data storage pattern DSP may indicate the binary data value or the multi-bit (multi-level) data value through the change in the amount of trapped charges or holes or may indicate the binary data value or the multi-bit (multi-level) data value through the state change of the charges.

The vertical channel pattern VCP may cover the inner side wall of the data storage pattern DSP and may extend in the third direction D3. The vertical channel pattern VCP may be provided between the data storage pattern DSP and the back gate BG and may correspond to the second gate electrodes EL2. As such, as described above, the vertical channel pattern VCP may constitute memory cells together with the areas of the data storage pattern DSP, which correspond to the second gate electrodes EL2.

The upper surface of the vertical channel pattern VCP may be positioned to be higher in level than an upper surface of the uppermost one of the second gate electrodes EL2. In more detail, the upper surface of the vertical channel pattern VCP may be positioned between the upper surface and the lower surface of the third gate electrode EL3.

The vertical channel pattern VCP, which is a component transferring charges or holes to the data storage pattern DSP, may be formed of monocrystalline silicon or polysilicon such that a channel is formed or boosted by a voltage applied thereto. However, the present disclosure is not restricted or limited thereto. For example, the vertical channel pattern VCP may be formed of an oxide semiconductor material capable of blocking, suppressing, or minimizing a leakage current. For example, the vertical channel pattern VCP may be formed of an oxide semiconductor material including at least one of In, Zn, and Ga having excellent leakage current characteristics, or a group 4 semiconductor material. The vertical channel pattern VCP may be formed of, for example, a ZnOx-based material including AZO, ZTO, IZO, ITO, IGZO, or Ag—ZnO. Thus, the vertical channel pattern VCP may block, suppress, or minimize a leakage current to the gate electrodes EL1, EL2, and EL3 or the substrate SUB, may improve transistor characteristics (e.g., the threshold voltage distribution and the program/read operation speed) of at least one of the gate electrodes EL1, EL2, and EL3, and as a result, may improve electrical characteristics of the three-dimensional flash memory.

The back gate BG may be in contact with the vertical channel pattern VCP, with at least a portion thereof surrounded by the vertical channel pattern VCP, and may be formed to apply a voltage to the vertical channel pattern VCP for the memory operation. To this end, the back gate BG may be formed of a conductive material including at least one selected from the group of a doped semiconductor (e.g., doped silicon, etc.), metal (e.g., tungsten (W), copper (Cu), aluminum (Al), titanium (Ti), tantalum (Ta), molybdenum (Mo), ruthenium (Ru), gold (Au), etc.), or a conductive metal nitride (e.g., a titanium nitride, a tantalum nitride, etc.). The back gate BG may include at least one of all metal materials capable of being formed by ALD, in addition to the above metal materials.

In this case, the back gate BG may be formed to extend in the third direction D3 in the vertical channel pattern VCP from a level corresponding to the first gate electrode EL1 to a level corresponding to the second gate electrode EL2. That is, an upper surface of the back gate BG may be positioned to be higher in level than the upper surface of the uppermost one of the second gate electrodes EL2. However, the present disclosure is not restricted or limited thereto. For example, the back gate BG may be formed to extend in the third direction D3 in the vertical channel pattern VCP to a level corresponding to the third gate electrode EL3.

A lower substrate in contact with a lower portion of the back gate BG is omitted in the drawing, but depending on an implementation example, the lower substrate in contact with a lower surface of the back gate BG may be included. Further, depending on an implementation example, the back gate BG may be formed from an interior of the substrate SUB or may be formed from an upper portion of the substrate SUB.

The back gate BG may be included in the vertical channel pattern VCP of each of the cell strings CSTR, and all the back gates BG respectively included in the vertical channel patterns VCP of the cell strings CSTR may be electrically connected on a plane that the first direction D1 and the second direction D2 form. That is, the back gate BG may be connected in common to the cell strings CSTR. In this case, the back gates BG of the cell strings CSTR may be collectively controlled such that the same voltage is applied to all the back gates BG.

However, the present disclosure is not restricted or limited thereto. For example, the back gates BG respectively included in the vertical channel patterns VCP of the cell strings CSTR may be electrically connected to each other in the first direction D1 of FIG. 1. In this case, the back gates BG of the cell strings CSTR arranged in the second direction D2 may be electrically controlled independently of each other such that different voltages are applied to the back gates BG, and the back gates BG of the cell strings CSTR arranged in the first direction D1 of FIG. 1 may be collectively controlled such that the same voltage is applied to the back gates BG.

Further, the back gates BG respectively included in the vertical channel patterns VCP of the cell strings CSTR may be electrically connected to each other in the second direction D2 of FIG. 1. In this case, the back gates BG of the cell strings CSTR arranged in the first direction D1 may be electrically controlled independently of each other such that different voltages are applied to the back gates BG, and the back gates BG of the cell strings CSTR arranged in the second direction D2 of FIG. 1 may be collectively controlled such that the same voltage is applied to the back gates BG.

An insulating film INS may be disposed between the back gate BG and the vertical channel pattern VCP, and thus, the back gate BG may be prevented from being in direct contact with the vertical channel pattern VCP. Like the interlayer insulating films ILD, the insulating film ILD may be formed of an insulating material such as a silicon oxide.

A structure in which the back gate BG is formed in an internal hole of the vertical channel pattern VCP and is formed in a state of being closely surrounded by the vertical channel pattern VCP is described above, but the present disclosure is not restricted or limited thereto. For example, a structure in which only at least a portion of the back gate BG may be surrounded by the vertical channel pattern VCP may be formed. For example, a structure in which the back gate BG and the insulating film INS are included in at least a portion of the vertical channel pattern VCP or a structure in which the back gate BG and the insulating film INS penetrate the vertical channel pattern VCP may be implemented.

Returning to FIG. 1, the vertical channel structures VS may correspond to the channels of the erasure control transistor ECT, the first and second string selection transistors SST1 and SST2, the ground selection transistor GST, and the memory cell transistors MCT.

The conductive pad PAD may be provided on the upper surface of the vertical channel pattern VCP. The conductive pad PAD may be connected to the upper portion of the vertical channel pattern VCP. The side wall of the conductive pad PAD may be surrounded by the data storage pattern DSP. The upper surface of the conductive pad PAD may be substantially coplanar with the upper surface of each of the laminated structures ST (i.e., the upper surface of the uppermost one of the interlayer insulating films ILD). The lower surface of the conductive pad PAD may be positioned at a lower level than that of the upper surface of the third gate electrode EL3. In more detail, the lower surface of the conductive pad PAD may be positioned between the upper surface and the lower surface of the third gate electrode EL3. That is, at least a portion of the conductive pad PAD may overlap the third gate electrode EL3 in the horizontal direction.

The conductive pad PAD may be formed of a semiconductor doped with impurities or a conductive material. For example, the conductive pad PAD may be formed of a semiconductor material doped with impurities different from that of the substrate SUB (in detail, a semiconductor material doped with impurities of the second conductive type (e.g., N-type) different from the first conductive type (e.g., P-type)).

The conductive pad PAD may reduce a contact resistance between the bit line BL, which will be described below, and the vertical channel pattern VCP.

A separation trench TR extending in the first direction D1 may be provided between the adjacent laminated structures ST. The common source area CSR may be provided inside the substrate SUB exposed by the separation trench TR. The common source area CSR may extend in the first direction D1 within the substrate SUB. The common source area CSR may be formed of a semiconductor material doped with second conductivity-type impurities (e.g., N-type impurities). The common source area CSR may correspond to the common source line CSL of FIG. 1.

The common source plug CSP may be provided inside the separation trench TR. The common source plug CSP may be connected to the common source area CSR. The upper surface of the common source plug CSP may be substantially coplanar with the upper surface of each of the laminated structures ST (i.e., the upper surface of the uppermost one of the interlayer insulating films ILD). The common source plug CSP may have a plate shape extending in the first direction D1 and the third direction D3. In this case, the common source plug CSP may have a shape of which a width in the second direction D2 increases toward the third direction D3.

The insulation spacers SP may be interposed between the common source plug CSP and the laminated structures ST. The insulation spacers SP may be provided between the adjacent laminated structures ST to face each other. For example, the insulation spacers SP may be formed of a silicon oxide, a silicon nitride, a silicon oxy nitride, or a low-k material having a low dielectric constant.

The capping insulating film CAP may be provided on the laminated structures ST, the vertical channel structures VS, and the common source plug CSP. The capping insulating film CAP may cover the upper surface of the uppermost one of the interlayer insulating films ILD, the upper surface of the conductive pad PAD, and the upper surface of the common source plug CSP. The capping insulating film CAP may be formed of an insulating material different from that of the interlayer insulating films ILD. The bit line contact plug BLPG electrically connected to the conductive pad PAD may be provided inside the capping insulating film CAP. The bit line contact plug BLPG may have a shape of which widths in the first direction D1 and the second direction D2 increase toward the third direction D3.

The bit line BL may be provided on the capping insulating film CAP and the bit line contact plug BLPG. The bit line BL corresponds to any one of the plurality of bit lines BL0, BL1, and BL2 illustrated in FIG. 1, and may be formed of a conductive material to extend in the second direction D2. The conductive material constituting the bit line BL may be the same material as the conductive material forming each of the gate electrodes EL1, EL2, and EL3.

The bit line BL may be electrically connected to the vertical channel structures VS through the bit line contact plug BLPG. Here, the fact that the bit line BL is connected to the vertical channel structures VS may mean that the bit line BL is connected to the vertical channel patterns VCP included in the vertical channel structures VS.

The three-dimensional flash memory with the above structure may perform the program operation, the read operation, and the erase operation based on the voltage applied to each of the cell strings CSTR, the voltage applied to the string selection line SSL, the voltage applied to each of the word lines WL0 to WLn, the voltage applied to the ground selection line GSL, the voltage applied to the common source line CSL, and a voltage applied to the back gate BG. For example, based on the voltage applied to each of the cell strings CSTR, the voltage applied to the string selection line SSL, the voltage applied to each of the word lines WL0 to WLn, the voltage applied to the ground selection line GSL, the voltage applied to the common source line CSL, and the voltage applied to the back gate BG, the three-dimensional flash memory may form a channel in the vertical channel pattern VCP such that charges or holes are transferred to the data storage pattern DSP of a target memory cell. This may mean that the three-dimensional flash memory performs the program operation.

Further, the three-dimensional flash memory according to another embodiment is not restricted or limited to the above structure, and according to the implementation example, the three-dimensional flash memory may be implemented in various structures under the condition that the vertical channel pattern VCP, the data storage pattern DSP, the back gate BG, the gate electrodes EL1, EL2, and EL3, the bit line BL, and the common source line CSL are included.

As the three-dimensional flash memory having such a structure is manufactured through the stack laminating process, each of the laminated structures ST may include the upper stack structure USS and the lower stack structure LSS. The lower stack structure LSS may be disposed on the substrate SUB and include the gate electrodes (EL1 and a portion of EL2) and the interlayer insulating films ILD that are vertically and alternately laminated. The upper stack structure USS may be laminated on the lower stack structure LSS and include the gate electrodes (a portion of EL2 and EL3) and the interlayer insulating films ILD that are vertically and alternately laminated.

When the lower stack structure LSS and the upper stack structure USS are laminated, the vertical channel structures VS included in the lower stack structure LSS and the vertical channel structures VS included in the upper stack structure USS may be misaligned. For example, when the vertical channel patterns VCP of the lower stack structure LSS and the vertical channel patterns VCP of the upper stack structure USS are misaligned, channel current characteristics may be degraded. Thus, each of the laminated structures ST of the three-dimensional flash memory may include the connection parts CU that connect the vertical channel patterns VCP of the stack structures USS and LSS to each other while being arranged between the upper stack structure USS and the lower stack structure LSS. These connection parts CU are formed in spaces obtained by etching a portion of the buffer layer BU, which is positioned between the upper stack structure USS and the lower stack structure LSS, in the horizontal direction (the first direction D1 and the second direction D2), and thus may be accommodated by the buffer layer BU.

Further, the connection parts CU formed on the inner walls of the spaces obtained by etching the portion of the buffer layer BU in the horizontal direction are collectively formed through the same process as that of the vertical channel structures VS formed in the channel holes CH of each of the upper stack structures USS and the lower stack structures LSS. Thus, each of the connection parts CU may include the first connection portion CU1 formed of the same material as that of the data storage pattern DSP, the second connection portion CU2 formed of the same material as that of the vertical channel pattern VCP, and a third connection portion CU3 formed of the same material as that of the back gate BG. In this case, when it is understood that the back gate BG of the upper and lower stack structures USS and LSS are formed to extend in the vertical direction, the third connection portion CU3 may be interpreted as an internal hole through which one back gate BG extends. That is, each of the connection parts CU may include the internal hole through which the back gate BG extends in the vertical direction.

In particular, the connection parts CU may have curved edges while protruding from the vertical channel patterns VCP in the horizontal direction, respectively. In more detail, the connection parts CU may have sizes in which the vertical channel patterns VCP are accommodated on a plane and thus may have shapes protruding from the vertical channel patterns VCP in the horizontal direction, respectively. Further, the connection parts CU may be formed at positions, in which the vertical channel patterns VCP are accommodated, to connect the vertical channel patterns VCP of the upper and lower stack structures USS and LSS to each other.

In this way, the reason why the connection parts CU have curved edges while protruding is that the connection parts CU are formed on the side walls of remaining portions having an undercut shape after the portion of the buffer layer BU is etched. That is, the side walls in which the portion of the buffer layer BU in the horizontal direction is wet-etched (the side walls of the remaining portions after the wet etching is performed) may have an undercut shape. The connection parts CU are formed on the side walls of the remaining portions after the wet etching and thus may have curved edges while protruding in the horizontal direction.

To this end, the buffer layer BU may be formed of a material capable of performing wet etching. Here, the material on which the wet etching may be performed may include at least one material among a silicon oxide or a metal oxide (e.g., a silicon nitride, a silicon oxide, a silicon carbide, or a silicon oxy nitride).

As described above, the three-dimensional flash memory includes the connection parts CU, to connect the vertical channel patterns VCP of the stack structures USS and LSS to each other so as to solve a problem of degrading the channel current characteristics.

It has been described above that the three-dimensional flash memory is manufactured through the stack laminating process, and thus includes the upper stack structure USS and the lower stack structure LSS. However, the number of stack structures laminated in the stack laminating process is adjusted, and thus the three-dimensional flash memory may include three or more stack structures (e.g., the upper stack structure USS, the middle stack structure MSS, and the lower stack structure LSS). In this case, the groups of the connection parts CU, which are arranged in the horizontal direction (the first direction D1 and the second direction D2), are spaced apart from each other in the third direction D3, and the connection parts CU may be arranged at connection portions of the stack structures. A plurality of buffer layers BU may be provided to surround the groups of the connection parts CU spaced apart from each other in the third direction D3, and may be spaced apart from each other in the third direction D3.

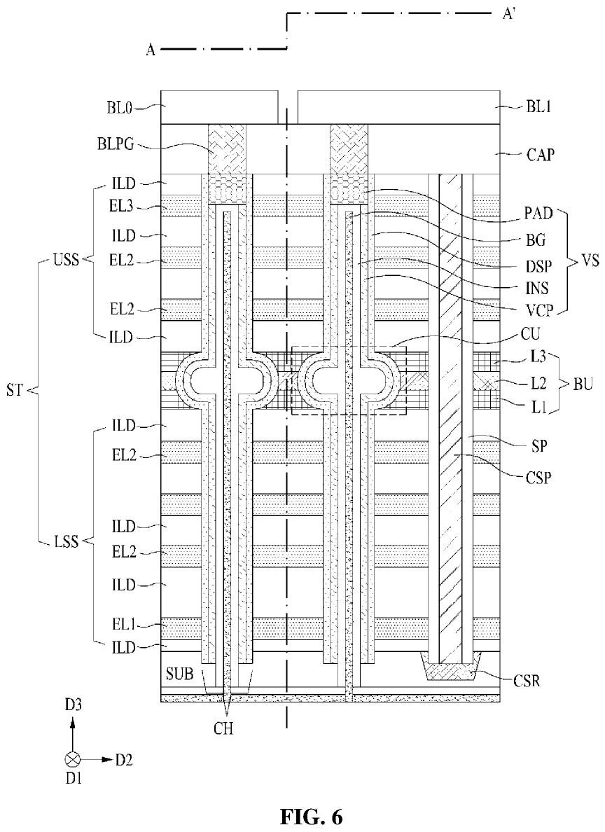

FIG. 6 is a cross-sectional view for describing another implementation example of connection parts and a buffer layer included in the three-dimensional flash memory illustrated in FIG. 5 and corresponds to the cross section along line A-A of FIG. 2.

Hereinafter, the three-dimensional flash memory described with reference to FIG. 6 has all the same components as those of the three-dimensional flash memory described above with reference to FIG. 5 but only a structure of the buffer layer BU is different therebetween. Accordingly, only the buffer layer BU having a different structure will be described below.

The connection parts CU illustrated in FIG. 6 may also have curved edges while protruding from the vertical channel patterns VCP in the horizontal direction. In this way, the reason why the connection parts CU have curved edges while protruding is that the connection parts CU are formed on the side walls of the remaining portions having an undercut shape after the portion of the buffer layer BU is etched, which is like the description with reference to FIG. 5.

However, the buffer layer BU illustrated in FIG. 6 is different from the buffer layer BU illustrated in FIG. 5 in that, as the plurality of layers L1, L2, and L3 having different etching ratios are laminated in the vertical direction, the etched side walls have an undercut shape even through the dry etching as well as the wet etching. That is, as the buffer layer BU is configured such that the plurality of layers L1, L2, and L3 having different etching ratios are laminated in the vertical direction, the side walls on which the etching is performed on a portion of the buffer layer BU in the horizontal direction (the side walls of the remaining portions after the etching) have an undercut shape, and the connection parts CU are formed on the side walls of the remaining portions after the etching and thus may have curved edges while protruding in the horizontal direction.

In relation to the fact that the buffer layer BU is configured as the plurality of layers L1, L2, and L3 having different etching ratios are laminated in the vertical direction, the layer L2 positioned in a center of the plurality of layers L1, L2, and L3 in the vertical direction has a higher etching ratio than that of the layers L1 and L3 positioned at edges so that the side walls on which the etching is performed have an undercut shape.

It has been described that the buffer layer BU includes the three layers L1, L2, and L3, but the present disclosure is not restricted or limited thereto, and the buffer layer BU may include four or more layers. In this case, the four layers may have a high etching ratio as they are closer to the center in the vertical direction and has a low etching ratio as they are closer to the edges.

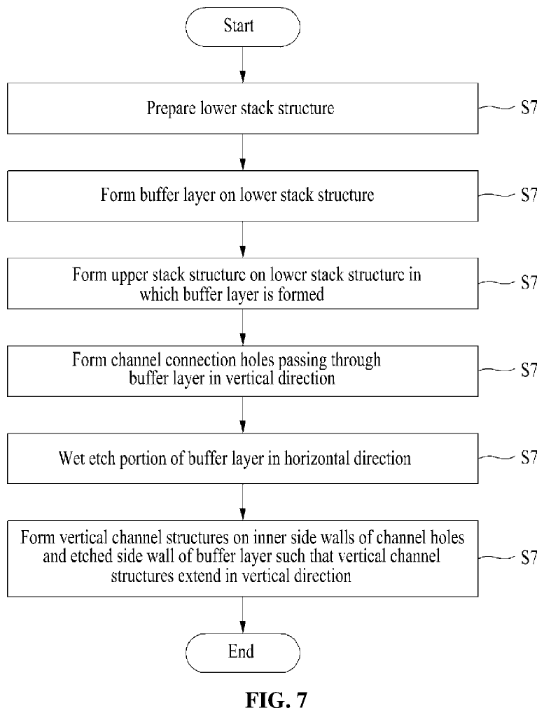

FIG. 7 is a flowchart illustrating a method of manufacturing the three-dimensional flash memory illustrated in FIGS. 3 and 5, and FIGS. 8A to 8F are cross-sectional views illustrating the three-dimensional flash memory to describe the method illustrated in FIG. 7.

Referring to FIG. 7, the method of manufacturing a three-dimensional flash memory according to the embodiment, which is intended to manufacture the three-dimensional flash memory described with reference to FIGS. 3 and 5 and is based on the assumption that the method is performed by an automated and mechanized manufacturing system, may include operation S710 of preparing the lower stack structure LSS including the interlayer insulating films ILD and the gate electrodes (EL1 and a portion of EL2) formed to extend in the horizontal direction and alternately laminated in the vertical direction and the channel holes CH passing through the interlayer insulating films ILD and the gate electrodes (EL1 and a portion of EL2) in the vertical direction, operation S720 of forming the buffer layer BU on the lower stack structure LSS, operation S730 of forming the upper stack structure USS including the interlayer insulating films ILD and the gate electrodes (a portion of EL2 and EL3) formed to extend in the horizontal direction and alternately laminated in the vertical direction and the channel holes CH passing through the interlayer insulating films ILD and the gate electrodes (a portion of EL2 and EL3) in the vertical direction, on the lower stack structure LSS in which the buffer layer BU is formed, operation S740 of forming channel connection holes CCH passing through the buffer layer BU in the vertical direction based on positions of the channel holes CH, operation S750 of wet etching a portion of the buffer layer BU in the horizontal direction so that the remaining portion has an undercut shape through the channel holes CH and the channel connection holes CCH, and operation S760 of forming the vertical channel structures VS including the data storage pattern DSP and the vertical channel pattern VCP on inner side walls of the channel holes CH and the etched side wall of the buffer layer BU such that the vertical channel structures VS extend in the vertical direction. In particular, operation S760 may include an operation of connecting the vertical channel patterns VCP formed in and extending from the upper stack structure USS and the vertical channel patterns VCP formed in and extending from the lower stack structure LSS to each other and forming the connection parts CU having curved edges while protruding from the vertical channel patterns VCP in the horizontal direction.

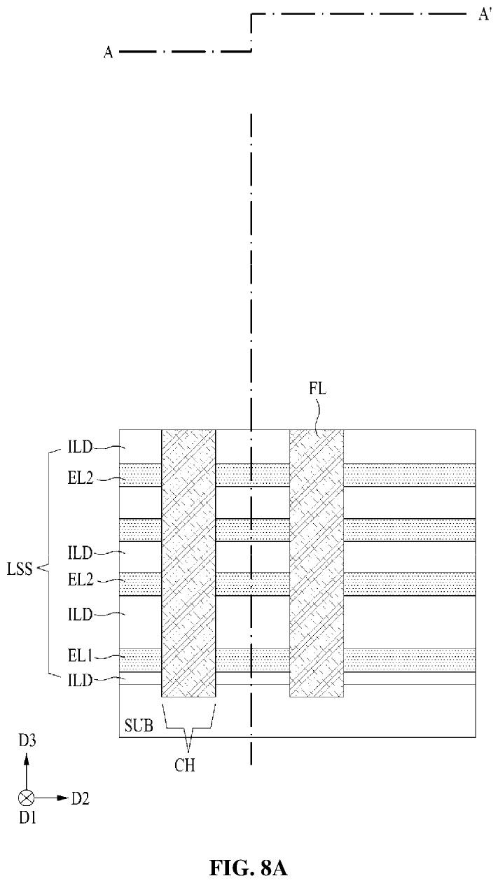

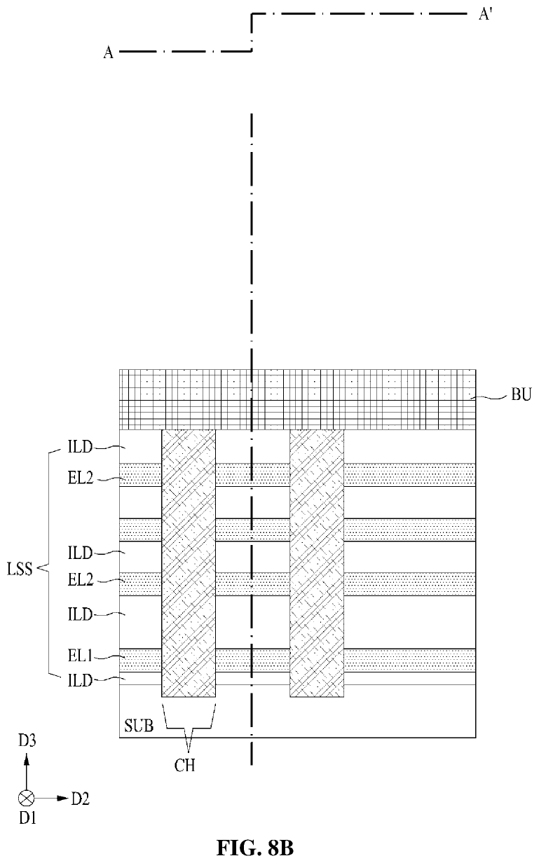

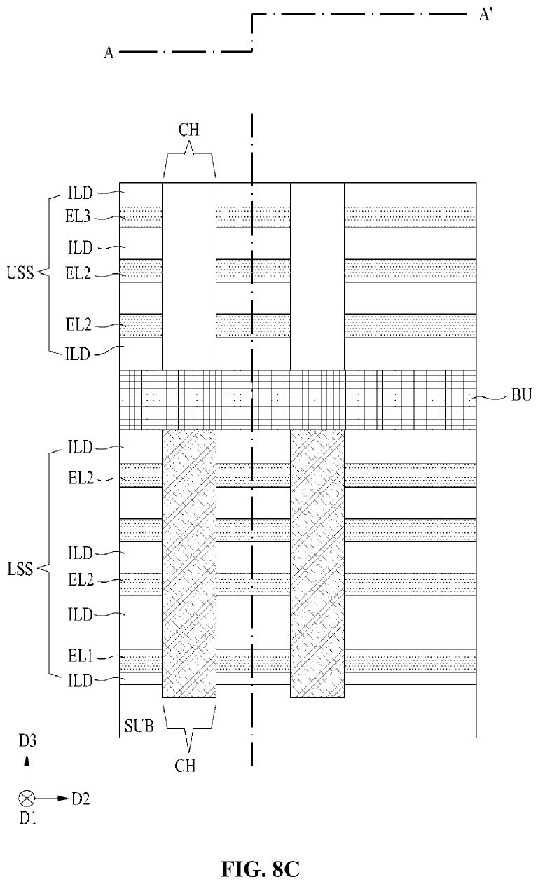

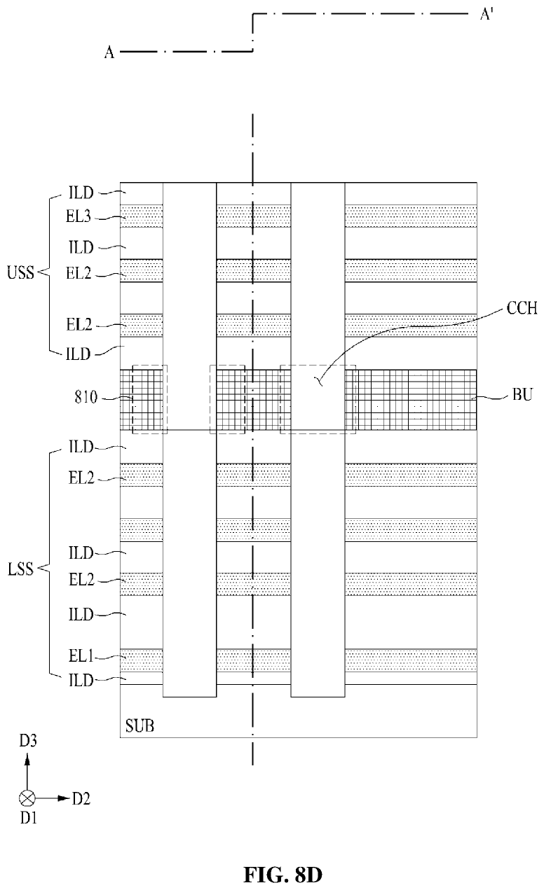

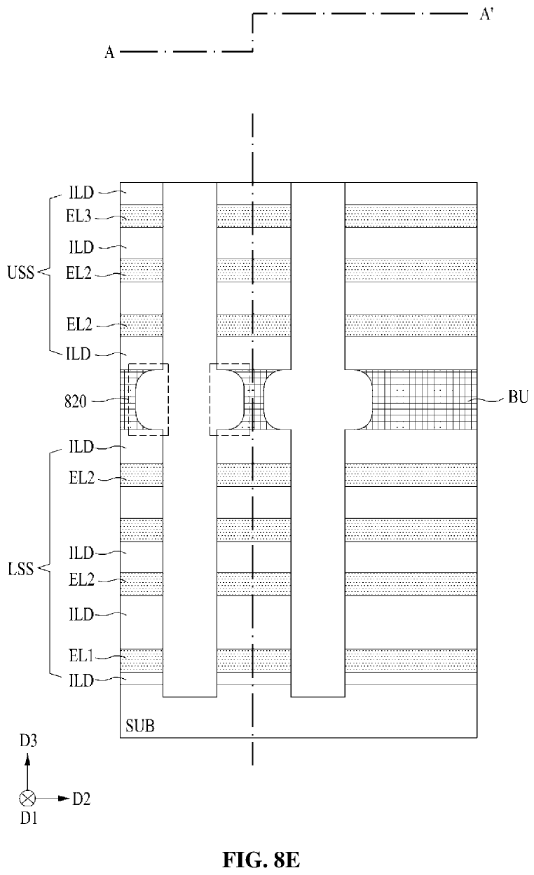

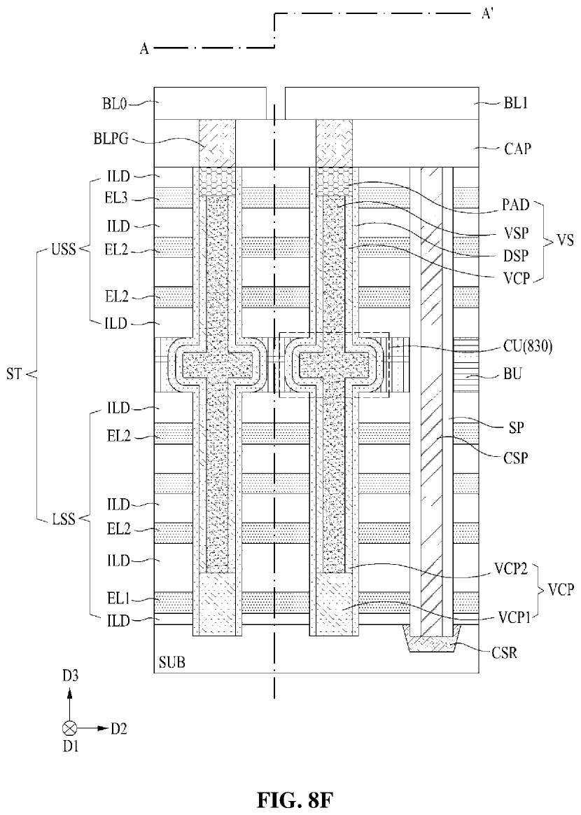

Hereinafter, operations S710 to S760 of FIG. 7 will be described in detail with reference to FIGS. 8A and 8F.

Referring to FIG. 8A, in operation S710, the manufacturing system may prepare the lower stack structure LSS including the interlayer insulating films ILD and the gate electrodes (EL1 and a portion of EL2) formed in and extending from the substrate SUB in the horizontal direction (e.g., the first direction D1 and the second direction D2) and alternately laminated in the vertical direction (e.g., the third direction D3) and the channel holes CH passing through the interlayer insulating films ILD and the gate electrodes (EL1 and a portion of EL2) in the vertical direction.

Although not described and illustrated in separate operations and drawings, before operation S710 of preparing the lower stack structure LSS, the manufacturing system may perform an operation of forming the channel holes CH in a structure in which the interlayer insulating films ILD and sacrificial layers SAC are alternately laminated in the vertical direction, selectively removing the sacrificial layers SAC through the channel holes CH, and forming the gate electrodes (EL1 and a portion of EL2) on gate areas GR that are spaces from which the sacrificial layers SAC are removed. That is, the manufacturing system performs a WL Replacement process before operation S710, and thus may prepare the lower stack structure LSS including the interlayer insulating films ILD, the gate electrodes (EL1 and a portion of EL2), and the channel holes CH in operation S710. Here, the sacrificial layers SAC may be selectively removed through the separation trench TR as well as the channel holes CH. In this case, an operation of forming the separation trench TR may be previously performed before operation S710.

Further, it has been described above that the WL Replacement process is performed before operation S710, and thus the lower stack structure LSS in which the gate electrodes (EL1 and a portion of EL2) are formed is prepared. However, the present disclosure is not restricted or limited thereto, and the lower stack structure LSS in which the gate electrodes (EL1 and a portion of EL2) are formed may be prepared through a gate first process.

In operation S720, which will be described below, since the buffer layer BU should be formed on the lower stack structure LSS, the channel holes CH of the lower stack structure LSS may be filled with filling layers FL. The filling layers FL may be removed when the channel connection holes CCH are formed in operation S740, which will be described below.

Referring to FIG. 8B, in operation S720, the manufacturing system may form the buffer layer BU on the lower stack structure LSS. In more detail, since the buffer layer BU should be wet-etched through operation S750, in operation S720, the manufacturing system may form the buffer layer BU with the material on which the wet etching may be performed (e.g., at least one material among a silicon oxide or a metal oxide (e.g., a silicon nitride, a silicon oxide, a silicon carbide, or a silicon oxy nitride)).

Referring to FIG. 8C, in operation S730, the manufacturing system may form, on the lower stack structure LSS in which the buffer layer BU is formed, the upper stack structure USS including the interlayer insulating films ILD and the gate electrodes (a portion of EL2 and EL3) formed and extending in the horizontal direction (e.g., the first direction D1 and the second direction D2) and alternately laminated in the vertical direction (e.g., the third direction D3) and the channel holes CH passing through the interlayer insulating films ILD and the gate electrodes (a portion of EL2 and EL3) in the vertical direction

Although not described and illustrated in separate operations and drawings, before operation S730 of preparing the upper stack structure USS, the manufacturing system may perform an operation of forming the channel holes CH in a structure in which the interlayer insulating films ILD and the sacrificial layers SAC are alternately laminated in the vertical direction, selectively removing the sacrificial layers SAC through the channel holes CH, and forming the gate electrodes (a portion of EL2 and EL3) on the gate areas GR that are the spaces from which the sacrificial layers SAC are removed. That is, the manufacturing system may perform the WL Replacement process between operation S720 and operation S730 and thus form the upper stack structure USS including the interlayer insulating films ILD and the gate electrodes (a portion of EL2 and EL3) and the channel holes CH in operation S730. Here, the sacrificial layers SAC may be selectively removed through the separation trench TR as well as the channel holes CH. In this case, an operation of forming the separation trench TR may be previously performed between operation S720 and operation S730.

Further, it has been described above that the WL Replacement process is performed before operation S730, and thus the upper stack structure USS in which the gate electrodes (a portion of EL2 and EL3) are formed is prepared. However, the present disclosure is not restricted or limited thereto, and the upper stack structure USS in which the gate electrodes (a portion of EL2 and EL3) are formed may be formed through the gate first process.

Referring to FIG. 8D, in operation S740, the manufacturing system may form the channel connection holes CCH passing through the buffer layer BU in the vertical direction based on the positions of the channel holes CH. In more detail, the manufacturing system may form the channel connection holes CCH based on the positions of the channel holes CH of the upper and lower stack structures USS and LSS so that the channel holes CH included in the lower stack structure LSS and the channel holes CH included in the upper stack structure USS are connected to each other through the channel connection holes CCH.

In operation S740 of forming the channel connection holes CCH, an anisotropic etching method using a mask pattern as an etch mask may be used. However, this is merely an example, and various etching processes may be used in operation S740.

Referring to FIG. 8E, in operation S750, the manufacturing system may wet etch a portion 810 of the buffer layer BU in the horizontal direction through the channel holes CH and the channel connection holes CCH. Due to the wet etching, a remaining portion after the etching may have an undercut shape 820.

Referring to FIG. 8F, in operation S760, the manufacturing system may form the vertical channel structures VS including the data storage pattern DSP and the vertical channel pattern VCP on the inner side walls of the channel holes CH and the etched side wall of the buffer layer BU such that the vertical channel structures VS extend in the vertical direction. In this case, the etched side wall of the buffer layer BU is present in a position in which the etched side wall is expanded from the inner side walls of the channel holes CH in the horizontal direction. Thus, both the data storage pattern DSP and the vertical channel pattern VCP formed on the etched side wall of the buffer layer BU may have a structure that is expanded and protrudes from the data storage pattern DSP and the vertical channel pattern VCP formed in the inner side walls of the channel holes CH in the horizontal direction.

Further, since the remaining portion of the buffer layer BU after the etching has the undercut shape 802, both the data storage pattern DSP and the vertical channel pattern VCP formed on the etched side wall of the buffer layer BU may have curved edges.

Thus, operation S760 may include an operation of connecting the vertical channel patterns VCP formed in and extending from the upper stack structure USS and the vertical channel patterns VCP formed in and extending from the lower stack structure LSS to each other and forming the connection parts CU 830 having curved edges while protruding from the vertical channel patterns VCP in the horizontal direction.

It has been described in the drawing that each of the vertical channel structures VS has a structure including the vertical semiconductor pattern VSP illustrated in FIG. 3, but the present disclosure is not restricted or limited thereto, and each of the vertical channel structures VS may have a structure including the back gate BG illustrated in FIG. 5.

First, detailed operations of operation S760 will be described on the assumption that each of the vertical channel structures VS includes the vertical semiconductor pattern VSP.

In operation S760, the description is focused on forming the connection parts CU 830 in extending and forming of the vertical channel structures VS. However, operation S760 may include a first operation of forming the data storage pattern DSP such that the data storage pattern DSP extends in the vertical direction (e.g., the third direction D3), to cover the inner side walls of the channel holes CH and the etched side wall of the buffer layer BU, a second operation of forming the vertical channel pattern VCP that covers a portion of a side wall of the data storage pattern DSP such that the vertical channel pattern VCP extends in the vertical direction (e.g., the third direction D3), a third operation of forming the vertical semiconductor pattern VSP that fills a space surrounded by the vertical channel pattern VCP, and a fourth operation of forming the conductive pad PAD that fills a space surrounded by the portion of the side wall of the data storage pattern DSP, the upper surface of the vertical channel pattern VCP, and the upper surface of the vertical semiconductor pattern VSP.

In more detail, the second operation of forming the vertical channel pattern VCP such that the vertical channel pattern VCP extends may include a (2-1)th operation of the first part VCP1 that covers a lower side wall of the data storage pattern DSP and is in contact with the substrate SUB, and a (2-2)th operation of forming the second part VCP2 that covers an upper side wall of the data storage pattern DSP on the first part VCP1.

The materials forming the data storage pattern DSP, the vertical channel pattern VCP, the vertical semiconductor pattern VSP, and the conductive pad PAD have been described with reference to FIGS. 3 and 5, and thus a detailed description thereof will be omitted.

In the first operation of forming the data storage pattern DSP such that the data storage pattern DSP extends, the second operation of forming the vertical channel pattern VCP such that the vertical channel pattern VCP extends, and the third operation of forming the vertical semiconductor pattern VSP, the data storage pattern DSP, the vertical channel pattern VCP, and the vertical semiconductor pattern VSP may be formed by a chemical vapor deposition method or an atomic layer deposition method.

The manufacturing system may perform the fourth operation of forming the conductive pad PAD, which is subdivided into a (4-1)th operation of recessing the upper portion of the vertical channel pattern VCP and the upper portion of the vertical semiconductor pattern VSP and a (4-2)th operation of filling the recessed area with a doped semiconductor material or conductive material.

When each of the vertical channel structures VS has a structure including the back gate BG instead of the vertical semiconductor pattern VSP, operation S760 may include a first operation of forming the data storage pattern DSP such that the data storage pattern DSP extends in the vertical direction (e.g., the third direction D3), to cover the inner side walls of the channel holes CH and the etched side wall of the buffer layer BU, a second operation of forming the vertical channel pattern VCP that covers the portion of the side wall of the data storage pattern DSP such that the vertical channel pattern VCP extends in the vertical direction (e.g., the third direction D3), a third operation of forming the insulating film INS in the internal hole of the vertical channel pattern VCP such that the insulating film INS extends in the vertical direction (e.g., the third direction D3), a fourth operation of forming the back gate BG in an internal hole of the insulating film INS such that the back gate BG extends in the vertical direction (e.g., the third direction D3), and a fifth operation of forming the conductive pad PAD that fills a space surrounded by the portion of the side wall of the data storage pattern DSP and the upper surface of the vertical channel pattern VCP.

The materials forming the data storage pattern DSP, the vertical channel pattern VCP, the back gate BG, and the conductive pad PAD have been described with reference to FIGS. 3 and 5, and thus a detailed description thereof will be omitted.

In the first operation of forming the data storage pattern DSP such that the data storage pattern DSP extends, the second operation of forming the vertical channel pattern VCP such that the vertical channel pattern VCP extends, and the third operation of forming the insulating film INS, the data storage pattern DSP, the vertical channel pattern VCP, and the insulating film INS may be formed by a chemical vapor deposition method or an atomic layer deposition method.

The manufacturing system may perform the fifth operation of forming the conductive pad PAD, which is subdivided into a (5-1)^{th} operation of recessing an upper portion of the vertical channel pattern VCP and a (5-2)th operation of filling the recessed area with a doped semiconductor material or conductive material.

Further, although not described as a separate operation, in addition to operations S710 to S760, the manufacturing system may further perform an operation of forming the separation trench TR, an operation of performing the WL Replacement process through the separation trench TR (which may be omitted when the WL Replacement process is performed through the channel holes CH), an operation of forming the common source area CSR inside the substrate SUB exposed through the separation trench TR, an operation of forming an insulating spacer SP that covers a side wall of the separation trench TR and the common source plug CSP that fills an interior space of the separation trench TR surrounded by the insulating spacer SP, an operation of forming the capping insulating film CAP on the vertical channel structures VS and the common source plug CSP, an operation of forming the bit line contact plug BLPG electrically connected to the conductive pad PAD through the capping insulating film CAP, and an operation of forming the bit line BL electrically connected to the bit line contact plug BLPG on the capping insulating film CAP such that the bit line BL extends in the second direction D2.

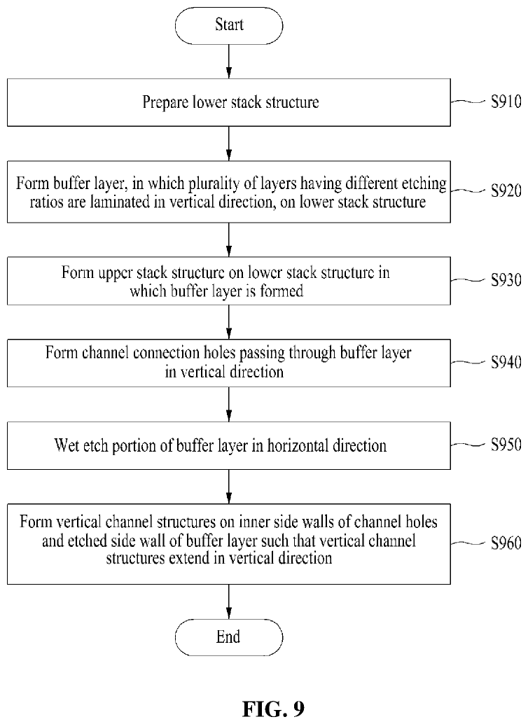

FIG. 9 is a flowchart illustrating a method of manufacturing a three-dimensional flash memory having the structure illustrated in FIGS. 4 and 6, and FIGS. 10A to 10F are cross-sectional views illustrating the three-dimensional flash memory to describe the method illustrated in FIG. 9.

Referring to FIG. 9, the method of manufacturing a three-dimensional flash memory according to another embodiment, which is intended to manufacture the three-dimensional flash memory described with reference to FIGS. 4 and 6 and is based on the assumption that the method is performed by an automated and mechanized manufacturing system, may include operation S910 of preparing the lower stack structure LSS including the interlayer insulating films ILD and the gate electrodes (EL1 and a portion of EL2) formed to extend in the horizontal direction and alternately laminated in the vertical direction and the channel holes CH passing through the interlayer insulating films ILD and the gate electrodes (EL1 and a portion of EL2) in the vertical direction, operation S920 of forming the buffer layer BU, in which the plurality of layers L1, L2, and L3 having different etching ratios are laminated, on the lower stack structure LSS, operation S930 of forming the upper stack structure USS including the interlayer insulating films ILD and the gate electrodes (a portion of EL2 and EL3) formed to extend in the horizontal direction and alternately laminated in the vertical direction and the channel holes CH passing through the interlayer insulating films ILD and the gate electrodes (a portion of EL2 and EL3) in the vertical direction, on the lower stack structure LSS in which the buffer layer BU is formed, operation S940 of forming the channel connection holes CCH passing through the buffer layer BU in the vertical direction based on positions of the channel holes CH, operation S950 of etching the portion of the buffer layer BU in the horizontal direction so that the remaining portion has an undercut shape through the channel holes CH and the channel connection holes CCH, and operation S960 of forming the vertical channel structures VS including the data storage pattern DSP and the vertical channel pattern VCP on inner side walls of the channel holes CH and the etched side wall of the buffer layer BU such that the vertical channel structures VS extend in the vertical direction. In particular, operation S960 may include an operation of connecting the vertical channel patterns VCP formed in and extending from the upper stack structure USS and the vertical channel patterns VCP formed in and extending from the lower stack structure LSS to each other and forming the connection parts CU having curved edges while protruding from the vertical channel patterns VCP in the horizontal direction.

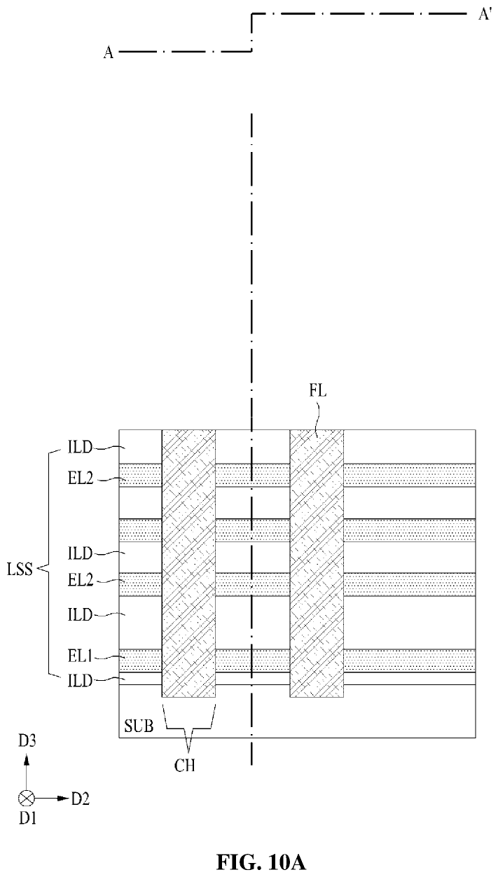

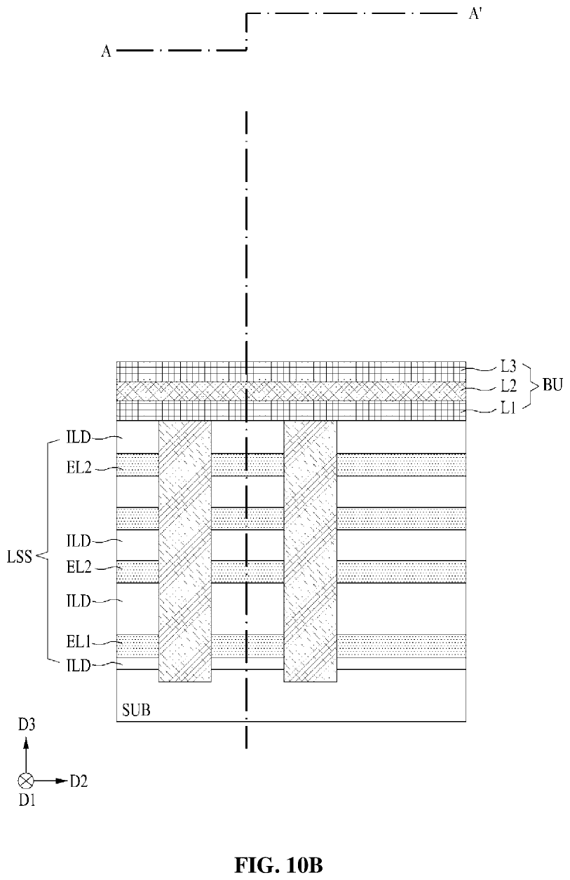

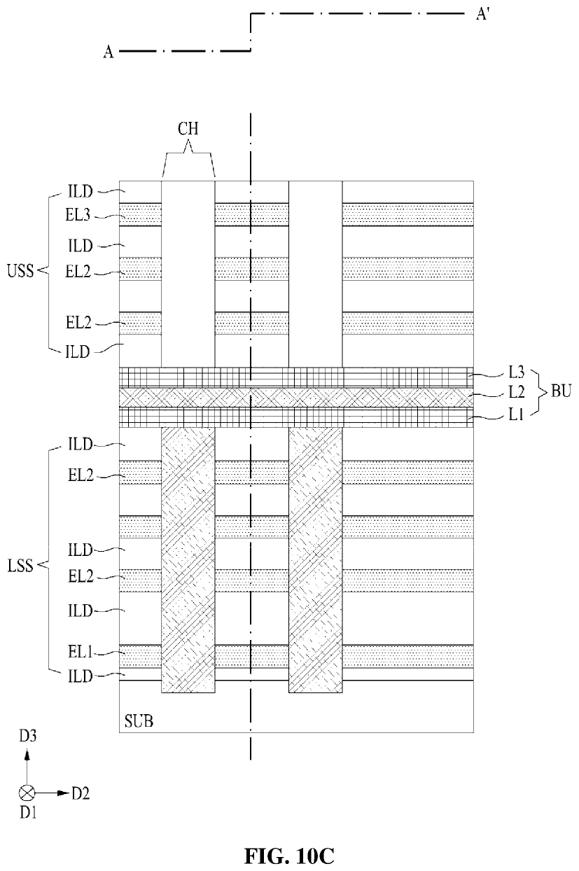

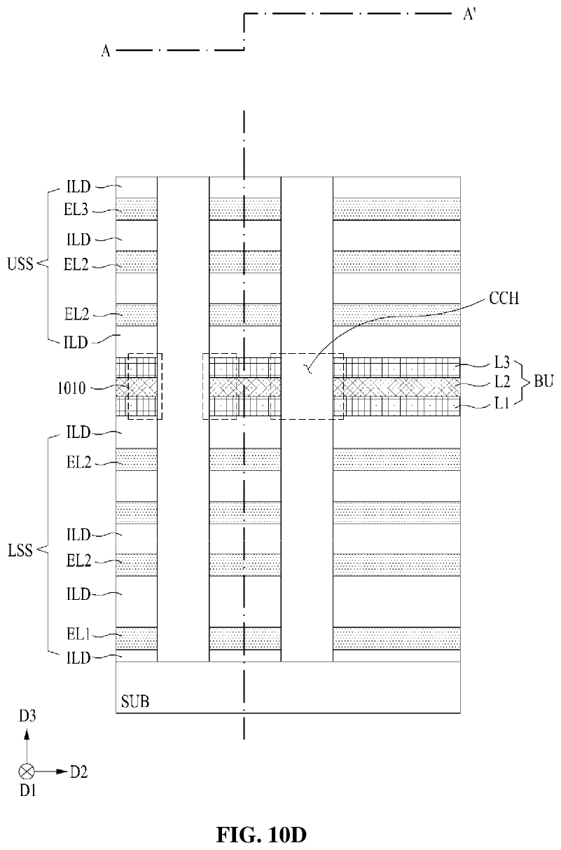

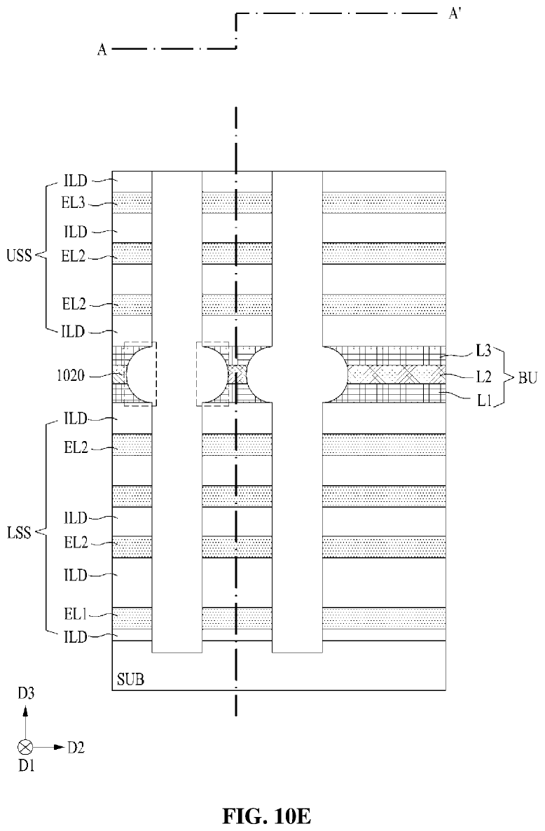

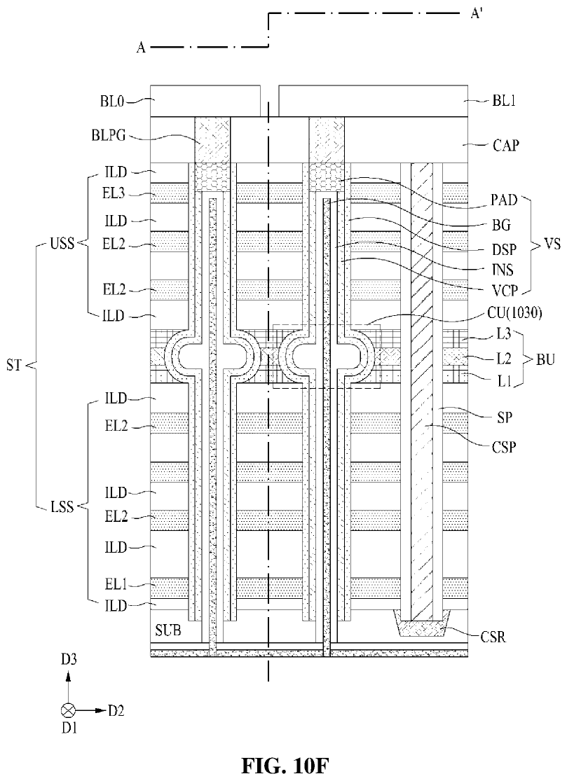

Hereinafter, operations S910 to S960 of FIG. 9 will be described in detail with reference to FIGS. 10A to 10F.

Referring to FIG. 10A, in operation S910, the manufacturing system may prepare the lower stack structure LSS including the interlayer insulating films ILD and the gate electrodes (EL1 and a portion of EL2) formed in and extending from the substrate SUB in the horizontal direction (e.g., the first direction D1 and the second direction D2) and alternately laminated in the vertical direction (e.g., the third direction D3) and the channel holes CH passing through the interlayer insulating films ILD and the gate electrodes (EL1 and a portion of EL2) in the vertical direction.

Although not described and illustrated in separate operations and drawings, before operation S910 of preparing the lower stack structure LSS, the manufacturing system may perform an operation of forming the channel holes CH in the structure in which the interlayer insulating films ILD and the sacrificial layers SAC are alternately laminated in the vertical direction, selectively removing the sacrificial layers SAC through the channel holes CH, and forming the gate electrodes (EL1 and a portion of EL2) on the gate areas GR that are the spaces from which the sacrificial layers SAC are removed. That is, the manufacturing system performs the WL Replacement process before operation S910, and thus may prepare the lower stack structure LSS including the interlayer insulating films ILD, the gate electrodes (EL1 and a portion of EL2), and the channel holes CH in operation S910. Here, the sacrificial layers SAC may be selectively removed through the separation trench TR as well as the channel holes CH. In this case, an operation of forming the separation trench TR may be previously performed before operation S910.

Further, it has been described above that the WL Replacement process is performed before operation S910, and thus the lower stack structure LSS in which the gate electrodes (EL1 and a portion of EL2) are formed is prepared. However, the present disclosure is not restricted or limited thereto, and the lower stack structure LSS in which the gate electrodes (EL1 and a portion of EL2) are formed may be prepared through the gate first process.

In operation S920, which will be described below, since the buffer layer BU should be formed on the lower stack structure LSS, the channel holes CH of the lower stack structure LSS may be filled with the filling layers FL. The filling layers FL may be removed when the channel connection holes CCH are formed in operation S940, which will be described below.

Referring to FIG. 10B, in operation S920, the manufacturing system may form the buffer layer BU, in which the plurality of layers L1, L2, and L3 having different etching ratios are laminated in the vertical direction, on the lower stack structure LSS. In more detail, as a result of etching the buffer layer BU in operation S950, the side wall of the remaining portion should have an undercut shape. Thus, in operation S920, the manufacturing system may form the layer L2 positioned at the center of the plurality of layers L1, L2, and L3 in the vertical direction using a material having a higher etching ratio than those of the layers L1 and L3 positioned at edges thereof.

When the buffer layer BU includes four or more layers, the manufacturing system may form the buffer layer BU such that the buffer layer BU has a high etching ratio as it is closer to the center in the vertical direction and has a low etching ratio as it is closer to the edges.

Referring to FIG. 10C, in operation S930, the manufacturing system may form, on the lower stack structure LSS in which the buffer layer BU is formed, the upper stack structure USS including the interlayer insulating films ILD and the gate electrodes (a portion of EL2 and EL3) formed and extending in the horizontal direction (e.g., the first direction D1 and the second direction D2) and alternately laminated in the vertical direction (e.g., the third direction D3) and the channel holes CH passing through the interlayer insulating films ILD and the gate electrodes (a portion of EL2 and EL3) in the vertical direction.

Although not described and illustrated in separate operations and drawings, before operation S930 of preparing the upper stack structure USS, the manufacturing system may perform an operation of forming the channel holes CH in the structure in which the interlayer insulating films ILD and the sacrificial layers SAC are alternately laminated in the vertical direction, selectively removing the sacrificial layers SAC through the channel holes CH, and forming the gate electrodes (a portion of EL2 and EL3) on the gate areas GR that are the spaces from which the sacrificial layers SAC are removed. That is, the manufacturing system may perform the WL Replacement process between operation S920 and operation S930 and thus form the upper stack structure USS including the interlayer insulating films ILD and the gate electrodes (a portion of EL2 and EL3) and the channel holes CH in operation S930. Here, the sacrificial layers SAC may be selectively removed through the separation trench TR as well as the channel holes CH. In this case, an operation of forming the separation trench TR may be previously performed between operation S920 and operation S930.

Further, it has been described above that the WL Replacement process is performed before operation S930, and thus the upper stack structure USS in which the gate electrodes (a portion of EL2 and EL3) are formed is prepared. However, the present disclosure is not restricted or limited thereto, and the upper stack structure USS in which the gate electrodes (a portion of EL2 and EL3) are formed may be formed through the gate first process.

Referring to FIG. 10D, in operation S940, the manufacturing system may form the channel connection holes CCH passing through the buffer layer BU in the vertical direction based on the positions of the channel holes CH. In more detail, the manufacturing system may form the channel connection holes CCH based on the positions of the channel holes CH of the upper and lower stack structures USS and LSS so that the channel holes CH included in the lower stack structure LSS and the channel holes CH included in the upper stack structure USS are connected to each other through the channel connection holes CCH.

In operation S940 of forming the channel connection holes CCH, an anisotropic etching method using a mask pattern as an etch mask may be used. However, this is merely an example, and various etching processes may be used in operation S940.

Referring to FIG. 10E, in operation S950, the manufacturing system may etch a portion 1010 of the buffer layer BU in the horizontal direction through the channel holes CH and the channel connection holes CCH. As described above, in the buffer layer BU, the plurality of layers L1, L2, and L3 having different etching ratios are laminated in the vertical direction. Thus, even when the dry etching as well as the wet etching is used as an etching method, the remaining portion after the etching may have an undercut shape 1020.

Referring to FIG. 10F, in operation S960, the manufacturing system may form the vertical channel structures VS including the data storage pattern DSP and the vertical channel pattern VCP on the inner side walls of the channel holes CH and the etched side wall of the buffer layer BU such that the vertical channel structures VS extend in the vertical direction. In this case, the etched side wall of the buffer layer BU is present in a position in which the etched side wall is expanded from the inner side walls of the channel holes CH in the horizontal direction. Thus, both the data storage pattern DSP and the vertical channel pattern VCP formed on the etched side wall of the buffer layer BU may have a structure that is expanded and protrudes from the data storage pattern DSP and the vertical channel pattern VCP formed in the inner side walls of the channel holes CH in the horizontal direction.

Further, since the remaining portion of the buffer layer BU after the etching has the undercut shape 1020, both the data storage pattern DSP and the vertical channel pattern VCP formed on the etched side wall of the buffer layer BU may have curved edges.

Thus, operation S960 may include an operation of connecting the vertical channel patterns VCP formed in and extending from the upper stack structure USS and the vertical channel patterns VCP formed in and extending from the lower stack structure LSS to each other and forming the connection parts CU 1030 having curved edges while protruding from the vertical channel patterns VCP in the horizontal direction.

It has been described in the drawing that each of the vertical channel structures VS has a structure including the back gate BG and illustrated in FIG. 5, but the present disclosure is not restricted or limited thereto, and each of the vertical channel structures VS may have a structure including the vertical semiconductor pattern VSP and illustrated in FIG. 3.

First, detailed operations of operation S960 will be described on the assumption that each of the vertical channel structures VS includes the back gate BG.

In operation S960, the description has been made while focused on forming of the connection parts CU 1030 in extending and forming of the vertical channel structures VS, operation S960 may include a first operation of forming the data storage pattern DSP such that the data storage pattern DSP extends in the vertical direction (e.g., the third direction D3), to cover the inner side walls of the channel holes CH and the etched side wall of the buffer layer BU, a second operation of forming the vertical channel pattern VCP that covers the portion of the side wall of the data storage pattern DSP such that the vertical channel pattern VCP extends in the vertical direction (e.g., the third direction D3), a third operation of forming the insulating film INS in the internal hole of the vertical channel pattern VCP such that the insulating film INS extends in the vertical direction (e.g., the third direction D3), a fourth operation of forming the back gate BG in the internal hole of the insulating film INS such that the back gate BG extends in the vertical direction (e.g., the third direction D3), and a fifth operation of forming the conductive pad PAD that fills a space surrounded by the portion of the side wall of the data storage pattern DSP and the upper surface of the vertical channel pattern VCP.

The materials forming the data storage pattern DSP, the vertical channel pattern VCP, the back gate BG, and the conductive pad PAD have been described with reference to FIGS. 3 and 5, and thus a detailed description thereof will be omitted.

In the first operation of forming the data storage pattern DSP such that the data storage pattern DSP extends, the second operation of forming the vertical channel pattern VCP such that the vertical channel pattern VCP extends, and the third operation of forming the insulating film INS, the data storage pattern DSP, the vertical channel pattern VCP, and the insulating film INS may be formed by a chemical vapor deposition method or an atomic layer deposition method.

The manufacturing system may perform the fifth operation of forming the conductive pad PAD, which is subdivided into a (5-1)^{th} operation of recessing the upper portion of the vertical channel pattern VCP and a (5-2)^{th} operation of filling the recessed area with a doped semiconductor material or conductive material.

When each of the vertical channel structures VS includes the vertical semiconductor pattern VSP instead of the back gate BG, operation S960 may include a first operation of forming the data storage pattern DSP such that the data storage pattern DSP extends in the vertical direction (e.g., the third direction D3), to cover the inner side walls of the channel holes CH and the etched side wall of the buffer layer BU, a second operation of forming the vertical channel pattern VCP that covers a portion of a side wall of the data storage pattern DSP such that the vertical channel pattern VCP extends in the vertical direction (e.g., the third direction D3), a third operation of forming the vertical semiconductor pattern VSP that fills a space surrounded by the vertical channel pattern VCP, and a fourth operation of forming the conductive pad PAD that fills a space surrounded by the portion of the side wall of the data storage pattern DSP, the upper surface of the vertical channel pattern VCP, and the upper surface of the vertical semiconductor pattern VSP.

In more detail, the second operation of forming the vertical channel pattern VCP such that the vertical channel pattern VCP extends may include a (2-1)^{th} operation of the first part VCP1 that covers the lower side wall of the data storage pattern DSP and is in contact with the substrate SUB, and a (2-2)^{th} operation of forming the second part VCP2 that covers the upper side wall of the data storage pattern DSP on the first part VCP1.

The materials forming the data storage pattern DSP, the vertical channel pattern VCP, the vertical semiconductor pattern VSP, and the conductive pad PAD have been described with reference to FIGS. 3 and 5, and thus a detailed description thereof will be omitted.

In the first operation of forming the data storage pattern DSP such that the data storage pattern DSP extends, the second operation of forming the vertical channel pattern VCP such that the vertical channel pattern VCP extends, and the third operation of forming the vertical semiconductor pattern VSP, the data storage pattern DSP, the vertical channel pattern VCP, and the vertical semiconductor pattern VSP may be formed by a chemical vapor deposition method or an atomic layer deposition method.

The manufacturing system may perform the fourth operation of forming the conductive pad PAD, which is subdivided into a (4-1)^{th} operation of recessing the upper portion of the vertical channel pattern VCP and the upper portion of the vertical semiconductor pattern VSP and a (4-2)^{th} operation of filling the recessed area with a doped semiconductor material or conductive material.

Further, although not described as a separate operation, in addition to operations S910 to S960, the manufacturing system may further perform an operation of forming the separation trench TR, an operation of performing the WL Replacement process through the separation trench TR (which may be omitted when the WL Replacement process is performed through the channel holes CH), an operation of forming the common source area CSR inside the substrate SUB exposed through the separation trench TR, an operation of forming the insulating spacer SP that covers the side wall of the separation trench TR and the common source plug CSP that fills the interior space of the separation trench TR surrounded by the insulating spacer SP, an operation of forming the capping insulating film CAP on the vertical channel structures VS and the common source plug CSP, an operation of forming the bit line contact plug BLPG electrically connected to the conductive pad PAD through the capping insulating film CAP, and an operation of forming the bit line BL electrically connected to the bit line contact plug BLPG on the capping insulating film CAP such that the bit line BL extends in the second direction D2.

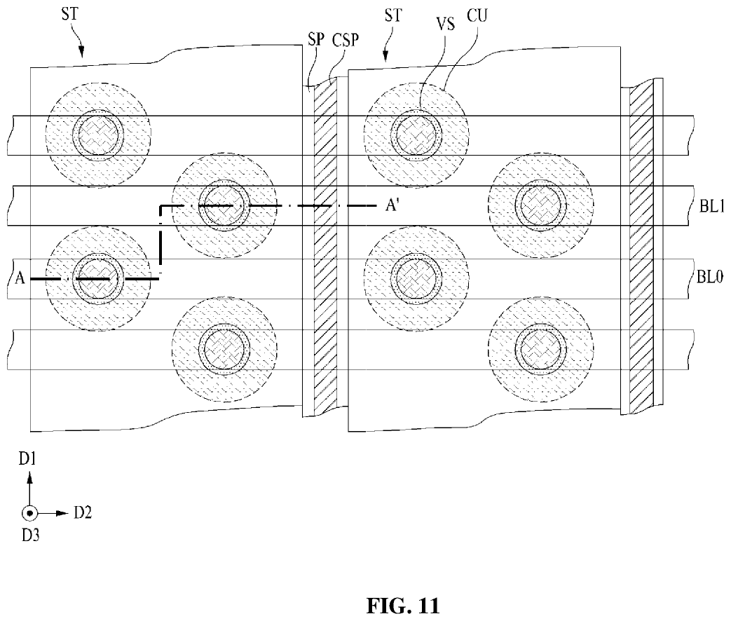

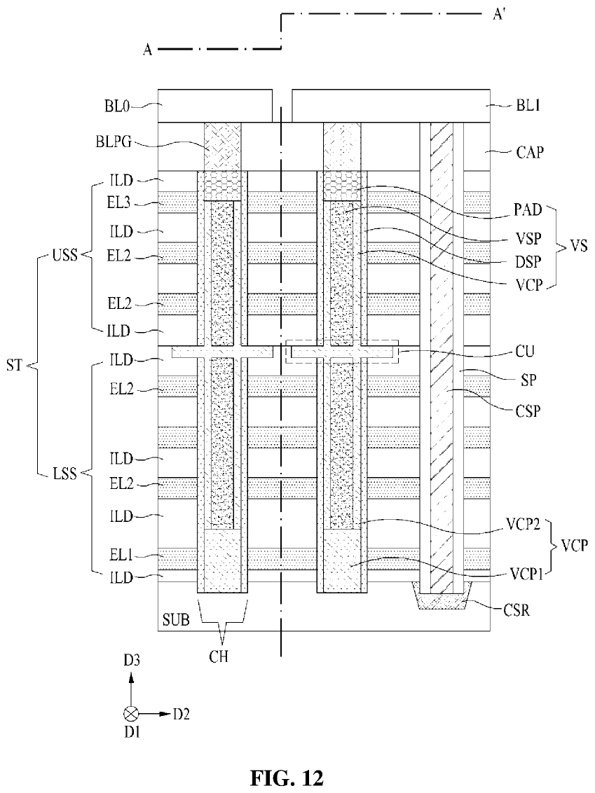

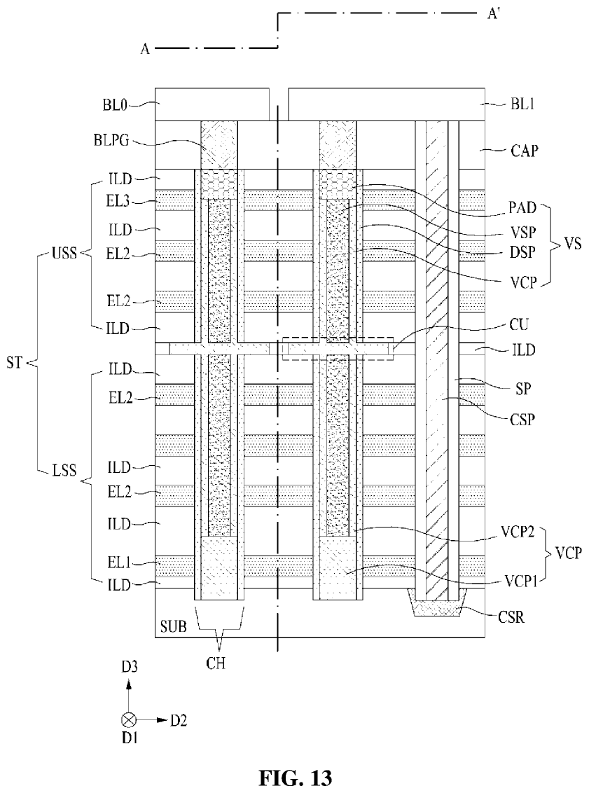

FIG. 11 is a plan view illustrating the structure of the three-dimensional flash memory according to the embodiment. FIG. 12 is a cross-sectional view illustrating the structure of the three-dimensional flash memory according to the embodiment and corresponds to the cross section along line A-A′ of FIG. 11, and FIG. 13 is a cross-sectional view for describing another implementation example of connection parts included in the three-dimensional flash memory illustrated in FIG. 12 and corresponds to a cross section along line A-A of FIG. 11.

Referring to FIGS. 11 and 13, the substrate SUB may be a semiconductor substrate such as a silicon substrate, a silicon-germanium substrate, a germanium substrate, or a single crystal epitaxial layer grown on a monocrystalline silicon substrate. The substrate SUB may be doped with first conductivity-type impurities (e.g., P-type impurities).

The laminated structures ST may be arranged on the substrate SUB. The laminated structures ST may be two-dimensionally arranged in the second direction D2 while extending in the first direction D1. Further, the laminated structures ST may be spaced apart from each other in the second direction D2.

Each of the laminated structures ST may include the gate electrodes EL1, EL2, and EL3 alternately laminated in the vertical direction perpendicular to the upper surface of the substrate SUB (e.g., in the third direction D3), and the interlayer insulating films ILD. The laminated structures ST may have substantially flat upper surfaces. That is, the upper surfaces of the laminated structures ST may be parallel to the upper surface of the substrate SUB. Hereinafter, the vertical direction means the third direction D3 or a direction opposite to the third direction D3.

Returning to FIG. 1, each of the gate electrodes EL1, EL2, and EL3 may be one of the erasure control line ECL, the ground selection lines GSL0, GSL1, and GSL2, the word lines WL0 to WLn and DWL, the first string selection lines SSL1-1, SSL1-2, and SSL1-3, and the second string selection lines SSL2-1, SSL2-2, and SSL2-3 that are sequentially laminated on the substrate SUB.

Each of the gate electrodes EL1, EL2, and EL3 may have substantially the same thickness in the third direction D3 while extending in the first direction D1. Hereinafter, the thickness means a thickness in the third direction D3. Each of the gate electrodes EL1, EL2, and EL3 may be formed of a conductive material. For example, each of the gate electrodes EL1, EL2, and EL3 may include at least one selected from a doped semiconductor (e.g., a doped silicon or the like), a metal (e.g., W (tungsten), Cu (copper), Al (aluminum), Ti (titanium), Ta (tantalum), Mo (molybdenum), Ru (ruthenium), Au (gold), or the like), a conductive metal nitride (e.g., a titanium nitride, a tantalum nitride, or the like) or the like. Each of the gate electrodes EL1, EL2, and EL3 may include at least one of all metal materials that may be formed by ALD in addition to the metal material described above.

In more detail, the gate electrodes EL1, EL2, and EL3 may include the lowermost first gate electrode EL1, the uppermost third gate electrode EL3, and the plurality of second gate electrodes EL2 between the first gate electrode EL1 and the third gate electrode EL3. Although each of the first gate electrode EL1 and the third gate electrode EL3 is illustrated and described in a singular number, this is exemplary, and the present disclosure is not limited thereto. As needed, the plurality of first gate electrodes EL1 and the plurality of third gate electrodes EL3 may also be provided. The first gate electrode EL1 may correspond to one of the ground selection lines GSL0, GSL1, and GSL2 illustrated in FIG. 1. The second gate electrode EL2 may correspond to any one of the word lines WL0 to WLn and DWL illustrated in FIG. 1. The third gate electrode EL3 may correspond to any one of the first string selection lines SSL1-1, SSL1-2, and SSL1-3 or any one of the second string selection lines SSL2-1, SSL2-2, and SSL2-3 illustrated in FIG. 1.

Although not illustrated, an end of each of the laminated structures ST may have a stepwise structure in the first direction D1. In more detail, the lengths of the gate electrodes EL1, EL2, and EL3 of the laminated structures ST in the first direction D1 may decrease as a distance from the substrate SUB increases. The third gate electrode EL3 may have the smallest length in the first direction D1 and the largest distance from the substrate SUB in the third direction D3. The first gate electrode EL1 may have the largest length in the first direction D1 and the smallest distance from the substrate SUB in the third direction D3. Due to the stepwise structure, the thickness of each of the laminated structures ST may decrease as the distance from the outermost one of the vertical channel structures VS, which will be described below, increases, and the side walls of the gate electrodes EL1, EL2, and EL3 may be spaced apart from each other at regular intervals in the first direction D1 when viewed from a plane.

The interlayer insulating films ILD may have different thicknesses. As an example, the lowermost one and the uppermost one of the interlayer insulating films ILD may have a thickness that is smaller than those of the other interlayer insulating films ILD. However, this is exemplary, and the present disclosure is not limited thereto. The interlayer insulating films ILD may be set to have different thickness or the same thickness according to characteristics of a semiconductor device. The interlayer insulating films ILD may be formed of an insulating material to insulate the gate electrodes EL1, EL2, and EL3 from each other. As an example, the interlayer insulating films ILD may be formed of a silicon oxide.

A plurality of channel holes CH passing through portions of the laminated structures ST and the substrate SUB may be provided. The vertical channel structures VS may be provided in the channel holes CH. The vertical channel structures VS, which are the plurality of cell strings CSTR illustrated in FIG. 1, may extend in the third direction D3 while being connected to the substrate SUB. A state in which the vertical channel structures VS are connected to the substrate SUB may mean that the portion of each of the vertical channel structures VS is buried inside the substrate SUB, but the present disclosure is not restricted or limited thereto. For example, the vertical channel structures VS may be formed such that the lower surfaces of the vertical channel structures VS are in contact with the upper surface of the substrate SUB. When the portion of each of the vertical channel structures VS is buried inside the substrate SUB, the lower surfaces of the vertical channel structures VS may be positioned to be lower in level than the upper surface of the substrate SUB.

A plurality of columns of the vertical channel structures VS passing through any one of the laminated structures ST may be provided. For example, as illustrated in FIG. 11, the columns of two vertical channel structures VS may penetrate one of the laminated structures ST. However, the present disclosure is not restricted or limited thereto. For example, columns of three or more vertical channel structures VS may penetrate one of the laminated structures ST. In a pair of adjacent columns, the vertical channel structures VS corresponding to one column may be shifted in the first direction D1 from the vertical channel structures VS corresponding to the other column adjacent thereto. When viewed from a plane, the vertical channel structures VS may be arranged in a zigzag shape in the first direction D1. However, the present disclosure is not restricted or limited thereto, and the vertical channel structures VS may form an array in which the vertical channel structures VS are arranged side by side in rows and columns.

Each of the vertical channel structures VS may extend from the substrate SUB in the third direction D3. In the drawing, each of the vertical channel structures VS is illustrated as having a column shape having the same width at an upper end and a lower end thereof, but the present disclosure is not restricted or limited thereto, and each of the vertical channel structures VS may have a shape of which widths in the first direction D1 and the second direction D2 increase toward the third direction D3. This is caused due to the limitation that when the channel holes CH are etched, the widths in the first direction D1 and the second direction D2 decrease as it goes in an opposite direction to the third direction D3. The upper surface of each of the vertical channel structures VS may have a circular shape, an oval shape, a quadrangular shape, or a bar shape.

Each of the vertical channel structures VS may include the data storage pattern DSP, the vertical channel pattern VCP, the vertical semiconductor pattern VSP, and the conductive pad PAD. In each of the vertical channel structures VS, the lower end of the data storage pattern DSP may have the shape of an opened pipe or a macaroni, and the lower end of the vertical channel pattern VCP may have the shape of a closed pipe or a macaroni. The vertical semiconductor pattern VSP may fill the space surrounded by the vertical channel pattern VCP and the conductive pad PAD.

While covering the inner side wall of each of the channel holes CH, the data storage pattern DSP may be in contact with the vertical channel pattern VCP inwardly and may be in contact with the side walls of the gate electrodes EL1, EL2, and EL3 outwardly. As such, the areas of the data storage pattern DSP, which correspond to the second gate electrodes EL2, may constitute the memory cells, in which the memory operation (e.g., the program operation, the read operation, or the erase operation) is performed by the voltages applied through the second gate electrodes EL2, together with the areas of the vertical channel pattern VCP, which correspond to the second gate electrodes EL2. The memory cells correspond to the memory cell transistors MCT illustrated in FIG. 1. That is, the data storage pattern DSP may trap the charges or holes by the voltages applied through the second gate electrodes EL2 or may maintain the state of the charges (e.g., the polarization state of the charges) by the voltages applied through the second gate electrodes EL2, and thus, the data storage pattern DSP may serve as data storage in the three-dimensional flash memory. For example, the ONO layer or the ferroelectric layer may be used as the data storage pattern DSP. The data storage pattern DSP may indicate the binary data value or the multi-bit (multi-level) data value through the change in the amount of trapped charges or holes or may indicate the binary data value or the multi-bit (multi-level) data value through the state change of the charges.

The vertical channel pattern VCP may cover the inner side wall of the data storage pattern DSP. The vertical channel pattern VCP may include the first part VCP1 and the second part VCP2 on the first part VCP1.

The first part VCP1 of the vertical channel pattern VCP may be provided under each of the channel holes CH and may be in contact with the substrate SUB. The first part VCP1 of the vertical channel pattern VCP may be used to block, suppress, or minimize a leakage current in each of the vertical channel structures VS and/or to form an epitaxial pattern. A thickness of the first part VCP1 of the vertical channel pattern VCP may be greater than, for example, a thickness of the first gate electrode EL1. The side wall of the first part VCP1 of the vertical channel pattern VCP may be surrounded by the data storage pattern DSP. The upper surface of the first part VCP1 of the vertical channel pattern VCP may be positioned at a higher level than that of the upper surface of the first gate electrode EL1. In more detail, the upper surface of the first part VCP1 of the vertical channel pattern VCP may be positioned between the upper surface of the first gate electrode EL1 and the lower surface of the lowermost one of the second gate electrodes EL2. The lower surface of the first part VCP1 of the vertical channel pattern VCP may be positioned at a lower level than an uppermost surface of the substrate SUB (i.e., the lower surface of the lowermost one of the interlayer insulating films ILD). The portion of the first part VCP1 of the vertical channel pattern VCP may overlap the first gate electrode EL1 in the horizontal direction. Hereinafter, the horizontal direction refers to a predetermined direction extending on a plane parallel to the first direction D1 and the second direction D2.

The second part VCP2 of the vertical channel pattern VCP may extend from the upper surface of the first part VCP1 in the third direction D3. The second part VCP2 of the vertical channel pattern VCP may be provided between the data storage pattern DSP and the vertical semiconductor pattern VSP and may correspond to the second gate electrodes EL2. Accordingly, as described above, the second part VCP2 of the vertical channel pattern VCP may constitute the memory cells together with the areas of the data storage pattern DSP, which correspond to the second gate electrodes EL2.

The upper surface of the second part VCP2 of the vertical channel pattern VCP may be substantially coplanar with the upper surface of the vertical semiconductor pattern VSP. The upper surface of the second part VCP2 of the vertical channel pattern VCP may be positioned at a level higher than the upper surface of the uppermost one of the second gate electrodes EL2. In more detail, the upper surface of the second part VCP2 of the vertical channel pattern VCP may be positioned between the upper surface and the lower surface of the third gate electrode EL3.

The vertical channel pattern VCP, which is a component transferring charges or holes to the data storage pattern DSP, may be formed of monocrystalline silicon or polysilicon such that the channel is formed or boosted by the voltage applied thereto. However, the present disclosure is not restricted or limited thereto. For example, the vertical channel pattern VCP may be formed of an oxide semiconductor material capable of blocking, suppressing, or minimizing a leakage current. For example, the vertical channel pattern VCP may be formed of an oxide semiconductor material including at least one of In, Zn, and Ga having excellent leakage current characteristics, or a group 4 semiconductor material. The vertical channel pattern VCP may be formed of, for example, a ZnOx-based material including AZO, ZTO, IZO, ITO, IGZO, or Ag—ZnO. Thus, the vertical channel pattern VCP may block, suppress, or minimize a leakage current to the gate electrodes EL1, EL2, and EL3 or the substrate SUB, may improve transistor characteristics (e.g., the threshold voltage distribution and the program/read operation speed) of at least one of the gate electrodes EL1, EL2, and EL3, and as a result, may improve electrical characteristics of the three-dimensional flash memory.

The vertical semiconductor pattern VSP may be surrounded by the second part VCP2 of the vertical channel pattern VCP. The upper surface of the vertical semiconductor pattern VSP may be in contact with the conductive pad PAD, and the lower surface of the vertical semiconductor pattern VSP may be in contact with the first part VCP1 of the vertical channel pattern VCP. The vertical semiconductor pattern VSP may be spaced apart from the substrate SUB in the third direction D3. In other words, the vertical semiconductor pattern VSP may be electrically floated from the substrate SUB.

The vertical semiconductor pattern VSP may be formed of a material that helps diffusion of charges or holes in the vertical channel pattern VCP. In more detail, the vertical semiconductor pattern VSP may be formed of a material having excellent charge and hole mobility. For example, the vertical semiconductor pattern VSP may be formed of a semiconductor material doped with impurities, an intrinsic semiconductor material not doped with impurities, or a polycrystalline semiconductor material. For a more detailed example, the vertical semiconductor pattern VSP may be formed of a polysilicon doped with first conductivity-type impurities (e.g., P-type impurities), which is like the substrate SUB. That is, the vertical semiconductor pattern VSP may improve the electrical characteristics of the three-dimensional flash memory to increase the memory operation speed.

Returning to FIG. 1, the vertical channel structures VS may correspond to the channels of the erasure control transistor ECT, the first and second string selection transistors SST1 and SST2, the ground selection transistor GST, and the memory cell transistors MCT.

The conductive pad PAD may be provided on the upper surface of the second part VCP2 of the vertical channel pattern VCP and on the upper surface of the vertical semiconductor pattern VSP. The conductive pad PAD may be connected to the upper portion of the vertical channel pattern VCP and the upper portion of the vertical semiconductor pattern VSP. The side wall of the conductive pad PAD may be surrounded by the data storage pattern DSP. The upper surface of the conductive pad PAD may be substantially coplanar with the upper surface of each of the laminated structures ST (i.e., the upper surface of the uppermost one of the interlayer insulating films ILD). The lower surface of the conductive pad PAD may be positioned at a lower level than that of an upper surface of the third gate electrode EL3. In more detail, the lower surface of the conductive pad PAD may be positioned between the upper surface and the lower surface of the third gate electrode EL3. That is, at least a portion of the conductive pad PAD may overlap the third gate electrode EL3 in the horizontal direction.

The conductive pad PAD may be formed of a semiconductor doped with impurities or a conductive material. For example, the conductive pad PAD may be formed of a semiconductor material doped with impurities different from those of the vertical semiconductor pattern VSP (in more detail, second conductivity-type (e.g., N-type) impurities different from the first conductivity-type (e.g., P-type) impurities).

The conductive pad PAD may reduce contact resistance between the bit line BL, which will be described below, and the vertical channel pattern VCP (or the vertical semiconductor pattern VSP).

Hereinafter, it has been described that the vertical channel structures VS have a structure including the conductive pad PAD, but the present disclosure is not restricted or limited thereto, and the vertical channel structures VS may have a structure in which the conductive pad PAD is omitted. In this case, as the conductive pad PAD is omitted from the vertical channel structures VS, each of the vertical channel pattern VCP and the vertical semiconductor pattern VSP may extend in the third direction D3 so that the upper surface of each of the vertical channel pattern VCP and the vertical semiconductor pattern VSP are substantially coplanar with the upper surface of each of the laminated structures ST (i.e., the upper surface of the uppermost one of the interlayer insulating films ILD). Further, in this case, the bit line contact plug BLPG, which will be described below, may be in direct contact with and electrically connected to the vertical channel pattern VCP instead of being indirectly electrically connected to the vertical channel pattern VCP through the conductive pad PAD.

Further, it has been described that the vertical channel structures VS include the vertical semiconductor pattern VSP, but the present disclosure is not restricted or limited thereto, and the vertical semiconductor pattern VSP may be omitted.

Further, it has been described that the vertical channel pattern VCP has a structure including the first part VCP1 and the second part VCP2, but the present disclosure is not restricted or limited thereto, and the vertical channel pattern VCP may have a structure in which the first part VCP1 is excluded. For example, the vertical channel pattern VCP may be provided between the vertical semiconductor pattern VSP that is formed to extend to the substrate SUB and the data storage pattern DSP and may be formed to extend to the substrate SUB to be in contact with the substrate SUB. In this case, the lower surface of the vertical channel pattern VCP may be positioned at a lower level than that of the uppermost surface of the substrate SUB (the lower surface of the lowermost one of the interlayer insulating films ILD), and the upper surface of the vertical channel pattern VCP may be substantially coplanar with the upper surface of the vertical semiconductor pattern VSP.

The separation trench TR extending in the first direction D1 may be provided between the adjacent laminated structures ST. The common source area CSR may be provided inside the substrate SUB exposed by the separation trench TR. The common source area CSR may extend in the first direction D1 within the substrate SUB. The common source area CSR may be formed of a semiconductor material doped with second conductivity-type impurities (e.g., N-type impurities). The common source area CSR may correspond to the common source line CSL of FIG. 1.

The common source plug CSP may be provided inside the separation trench TR. The common source plug CSP may be connected to the common source area CSR. The upper surface of the common source plug CSP may be substantially coplanar with the upper surface of each of the laminated structures ST (i.e., the upper surface of the uppermost one of the interlayer insulating films ILD). The common source plug CSP may have a plate shape extending in the first direction D1 and the third direction D3. In this case, the common source plug CSP may have a shape of which a width in the second direction D2 increases toward the third direction D3.

The insulation spacers SP may be interposed between the common source plug CSP and the laminated structures ST. The insulation spacers SP may be provided between the adjacent laminated structures ST to face each other. For example, the insulation spacers SP may be formed of a silicon oxide, a silicon nitride, a silicon oxy nitride, or a low-k material having a low dielectric constant.

The capping insulating film CAP may be provided on the laminated structures ST, the vertical channel structures VS, and the common source plug CSP. The capping insulating film CAP may cover the upper surface of the uppermost one of the interlayer insulating films ILD, the upper surface of the conductive pad PAD, and the upper surface of the common source plug CSP. The capping insulating film CAP may be formed of an insulating material different from that of the interlayer insulating films ILD. The bit line contact plug BLPG electrically connected to the conductive pad PAD may be provided inside the capping insulating film CAP. The bit line contact plug BLPG may have a shape of which widths in the first direction D1 and the second direction D2 increase toward the third direction D3.

The bit line BL may be provided on the capping insulating film CAP and the bit line contact plug BLPG. The bit line BL corresponds to any one of the plurality of bit lines BL0, BL1, and BL2 illustrated in FIG. 1, and may be formed of a conductive material to extend in the second direction D2. The conductive material constituting the bit line BL may be the same material as the conductive material forming each of the gate electrodes EL1, EL2, and EL3.

The bit line BL may be electrically connected to the vertical channel structures VS through the bit line contact plug BLPG. Here, the fact that the bit line BL is connected to the vertical channel structures VS my mean that the bit line BL is connected to the vertical channel patterns VCP included in the vertical channel structures VS.

The three-dimensional flash memory having such a structure may perform the program operation, the read operation, and the erasure operation based on the voltage applied to each of the cell strings CSTR, the voltage applied to the string selection line SSL, the voltage applied to each of the word lines WL0 to WLn, the voltage applied to the ground selection line GSL, and the voltage applied to the common source line CSL. For example, the three-dimensional flash memory may perform the program operation by forming a channel in the vertical channel pattern VCP and transferring charges or holes to the data storage pattern DSP of the target memory cell, based on the voltage applied to each of the cell strings CSTR, the voltage applied to the string selection line SSL, the voltage applied to each of the word lines WL0 to WLn, the voltage applied to the ground selection line GSL, and the voltage applied to the common source line CSL.

Further, the three-dimensional flash memory according to an embodiment is not restricted or limited to the above structure, and according to an implementation example, the three-dimensional flash memory may be implemented in various structures under a condition that the vertical channel pattern VCP, the data storage pattern DSP, the gate electrodes EL1, EL2, and EL3, the bit line BL, and the common source line CSL are included.

As the three-dimensional flash memory having such a structure is manufactured through the stack laminating process, each of the laminated structures ST may include the upper stack structure USS and the lower stack structure LSS. The lower stack structure LSS may be disposed on the substrate SUB and include the gate electrodes (EL1 and a portion of EL2) and the interlayer insulating films ILD that are vertically and alternately laminated. The upper stack structure USS may be laminated on the lower stack structure LSS and include the gate electrodes (a portion of EL2 and EL3) and the interlayer insulating films ILD that are vertically and alternately laminated.

When the lower stack structure LSS and the upper stack structure USS are laminated, the vertical channel structures VS included in the lower stack structure LSS and the vertical channel structures VS included in the upper stack structure USS may be misaligned. For example, when the vertical channel patterns VCP of the lower stack structure LSS and the vertical channel patterns VCP of the upper stack structure USS are misaligned, channel current characteristics may be degraded. Thus, each of the laminated structures ST of the three-dimensional flash memory may include the connection parts CU that connect the vertical channel patterns VCP of the stack structures USS and LSS to each other while being arranged between the upper stack structure USS and the lower stack structure LSS. These connection parts CU may be formed in a pillar shape having a closed interior so that the vertical semiconductor pattern VSP included in the upper stack structure USS and the vertical semiconductor pattern VSP included in the lower stack structure LSS are separated from each other. According to the manufacturing process, the connection parts CU may be formed in a recessed type in which the connection parts CU are recessed in the uppermost interlayer insulating film ILD included in the lower stack structure LSS as illustrated in FIG. 12 or in a protrusion type in which the connection parts CU are positioned on the uppermost interlayer insulating film ILD included in the lower stack structure LSS as illustrated in FIG. 13. When the connection parts CU are formed in the protrusion type, the connection parts CU may be accommodated by additional interlayer insulating films ILD that are not included in the upper and lower stack structures USS and LSS.

In particular, the connection parts CU may have shapes protruding from the vertical channel patterns VCP in the horizontal direction. In more detail, the connection parts CU may have sizes in which the vertical channel patterns VCP are accommodated on a plane and thus may have shapes protruding from the vertical channel patterns VCP in the horizontal direction, respectively. Further, the connection parts CU may be formed at positions, in which the vertical channel patterns VCP are accommodated, to connect the vertical channel patterns VCP of the upper and lower stack structures USS and LSS to each other.

Further, the connection parts CU may be formed of the same material as that of the vertical channel patterns VCP to connect the vertical channel patterns VCP of the upper and lower stack structures USS and LSS. For example, the connection parts CU may be formed of single crystalline silicon or polysilicon constituting the vertical channel patterns VCP. However, the present disclosure is not restricted or limited thereto, and each of the connection parts CU may be formed of various materials capable of connecting the vertical channel patterns VCP of the upper and lower stack structures USS and LSS to each other.

As described above, the three-dimensional flash memory includes the connection parts CU, to connect the vertical channel patterns VCP of the stack structures USS and LSS to each other so as to solve a problem of degrading the channel current characteristics.

It has been described above that the three-dimensional flash memory is manufactured through the stack laminating process, and thus includes the upper stack structure USS and the lower stack structure LSS. However, the number of stack structures laminated in the stack laminating process is adjusted, and thus the three-dimensional flash memory may include three or more stack structures (e.g., the upper stack structure USS, the middle stack structure MSS, and the lower stack structure LSS). In this case, the groups of the connection parts CU, which are arranged in the horizontal direction (the first direction D1 and the second direction D2), are spaced apart from each other in the third direction D3, and the connection parts CU may be arranged at connection portions of the stack structures. A plurality of buffer layers BU may be provided to surround the groups of the connection parts CU spaced apart from each other in the third direction D3, and may be spaced apart from each other in the third direction D3.

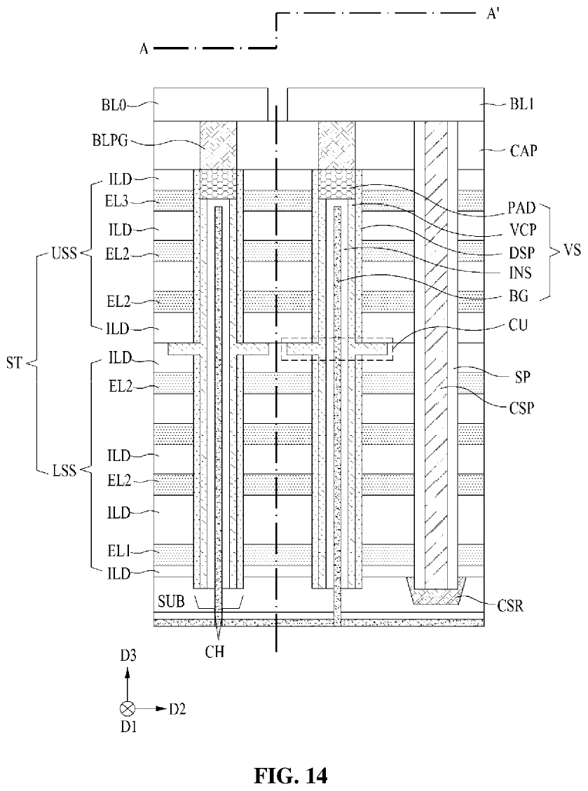

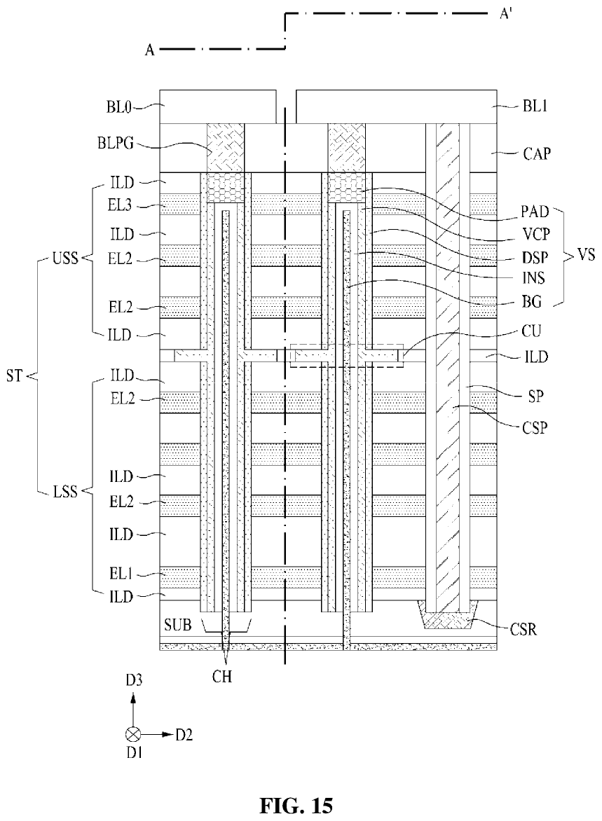

FIG. 14 is a cross-sectional view illustrating the structure of the three-dimensional flash memory according to another embodiment and corresponds to the cross section along line A-A′ of FIG. 11, and FIG. 15 is a cross-sectional view for describing another implementation example of connection parts included in the three-dimensional flash memory illustrated in FIG. 14 and corresponds to the cross section along line A-A′ of FIG. 11.

Referring to FIGS. 14 and 15, the substrate SUB may be a semiconductor substrate such as a silicon substrate, a silicon-germanium substrate, a germanium substrate, or a single crystal epitaxial layer grown on a monocrystalline silicon substrate. The substrate SUB may be doped with first conductivity-type impurities (e.g., P-type impurities).

The laminated structures ST may be arranged on the substrate SUB. The laminated structures ST may be two-dimensionally arranged in the second direction D2 while extending in the first direction D1. Further, the laminated structures ST may be spaced apart from each other in the second direction D2.

Each of the laminated structures ST may include the gate electrodes EL1, EL2, and EL3 alternately laminated in the vertical direction perpendicular to the upper surface of the substrate SUB (e.g., in the third direction D3), and the interlayer insulating films ILD. The laminated structures ST may have substantially flat upper surfaces. That is, the upper surfaces of the laminated structures ST may be parallel to the upper surface of the substrate SUB. Hereinafter, the vertical direction means the third direction D3 or a direction opposite to the third direction D3.

Returning to FIG. 1, each of the gate electrodes EL1, EL2, and EL3 may be one of the erasure control line ECL, the ground selection lines GSL0, GSL1, and GSL2, the word lines WL0 to WLn and DWL, the first string selection lines SSL1-1, SSL1-2, and SSL1-3, and the second string selection lines SSL2-1, SSL2-2, and SSL2-3 that are sequentially laminated on the substrate SUB.

Each of the gate electrodes EL1, EL2, and EL3 may have substantially the same thickness in the third direction D3 while extending in the first direction D1. Hereinafter, the thickness means a thickness in the third direction D3. Each of the gate electrodes EL1, EL2, and EL3 may be formed of a conductive material. For example, each of the gate electrodes EL1, EL2, and EL3 may include at least one selected from a doped semiconductor (e.g., a doped silicon or the like), a metal (e.g., W (tungsten), Cu (copper), Al (aluminum), Ti (titanium), Ta (tantalum), Mo (molybdenum), Ru (ruthenium), Au (gold), or the like), a conductive metal nitride (e.g., a titanium nitride, a tantalum nitride, or the like) or the like. Each of the gate electrodes EL1, EL2, and EL3 may include at least one of all metal materials that may be formed by ALD in addition to the metal material described above.

In more detail, the gate electrodes EL1, EL2, and EL3 may include the lowermost first gate electrode EL1, the uppermost third gate electrode EL3, and the plurality of second gate electrodes EL2 between the first gate electrode EL1 and the third gate electrode EL3. Although each of the first gate electrode EL1 and the third gate electrode EL3 is illustrated and described in a singular number, this is exemplary, and the present disclosure is not limited thereto. As needed, the plurality of first gate electrodes EL1 and the plurality of third gate electrodes EL3 may also be provided. The first gate electrode EL1 may correspond to one of the ground selection lines GSL0, GSL1, and GSL2 illustrated in FIG. 1. The second gate electrode EL2 may correspond to any one of the word lines WL0 to WLn and DWL illustrated in FIG. 1. The third gate electrode EL3 may correspond to any one of the first string selection lines SSL1-1, SSL1-2, and SSL1-3 or any one of the second string selection lines SSL2-1, SSL2-2, and SSL2-3 illustrated in FIG. 1.

Although not illustrated, an end of each of the laminated structures ST may have a stepwise structure in the first direction D1. In more detail, the lengths of the gate electrodes EL1, EL2, and EL3 of the laminated structures ST in the first direction D1 may decrease as a distance from the substrate SUB increases. The third gate electrode EL3 may have the smallest length in the first direction D1 and the largest distance from the substrate SUB in the third direction D3. The first gate electrode EL1 may have the largest length in the first direction D1 and the smallest distance from the substrate SUB in the third direction D3. Due to the stepwise structure, the thickness of each of the laminated structures ST may decrease as the distance from the outermost one of the vertical channel structures VS, which will be described below, increases, and the side walls of the gate electrodes EL1, EL2, and EL3 may be spaced apart from each other at regular intervals in the first direction D1 when viewed from a plane.

The interlayer insulating films ILD may have different thicknesses. As an example, the lowermost one and the uppermost one of the interlayer insulating films ILD may have a thickness that is smaller than those of the other interlayer insulating films ILD. However, this is exemplary, and the present disclosure is not limited thereto. The interlayer insulating films ILD may be set to have different thickness or the same thickness according to characteristics of a semiconductor device. The interlayer insulating films ILD may be formed of an insulating material to insulate the gate electrodes EL1, EL2, and EL3 from each other. As an example, the interlayer insulating films ILD may be formed of a silicon oxide.

A plurality of channel holes CH passing through portions of the laminated structures ST and the substrate SUB may be provided. The vertical channel structures VS may be provided in the channel holes CH. The vertical channel structures VS, which are the plurality of cell strings CSTR illustrated in FIG. 1, may extend in the third direction D3 while being connected to the substrate SUB. A state in which the vertical channel structures VS are connected to the substrate SUB may mean that the portion of each of the vertical channel structures VS is buried inside the substrate SUB, but the present disclosure is not restricted or limited thereto. For example, the vertical channel structures VS may be formed such that the lower surfaces of the vertical channel structures VS are in contact with the upper surface of the substrate SUB. When the portion of each of the vertical channel structures VS is buried inside the substrate SUB, the lower surfaces of the vertical channel structures VS may be positioned to be lower in level than the upper surface of the substrate SUB.

A plurality of columns of the vertical channel structures VS passing through any one of the laminated structures ST may be provided. For example, as illustrated in FIG. 11, the columns of two vertical channel structures VS may penetrate one of the laminated structures ST. However, the present disclosure is not restricted or limited thereto. For example, columns of three or more vertical channel structures VS may penetrate one of the laminated structures ST. In a pair of adjacent columns, the vertical channel structures VS corresponding to one row may be shifted in the first direction D1 from the vertical channel structures VS corresponding to the other column adjacent thereto. When viewed from a plane, the vertical channel structures VS may be arranged in a zigzag shape in the first direction D1. However, the present disclosure is not restricted or limited thereto, and the vertical channel structures VS may form an array in which the vertical channel structures VS are arranged side by side in rows and columns.

Each of the vertical channel structures VS may be formed to extend from the substrate SUB in the third direction D3. In the drawing, each of the vertical channel structures VS is illustrated as having a column shape having the same width at an upper end and a lower end thereof, but the present disclosure is not restricted or limited thereto, and each of the vertical channel structures VS may have a shape of which widths in the first direction D1 and the second direction D2 increase toward the third direction D3. This is caused due to the limitation that when the channel holes CH are etched, the widths in the first direction D1 and the second direction D2 decrease as it goes in an opposite direction to the third direction D3. The upper surface of each of the vertical channel structures VS may have a circular shape, an oval shape, a quadrangular shape, or a bar shape.

Each of the vertical channel structures VS may include the data storage pattern DSP, the vertical channel pattern VCP, the back gate BG, and the conductive pad PAD. In each of the vertical channel structures VS, the lower end of the data storage pattern DSP may have the shape of an opened pipe or a macaroni, and the lower end of the vertical channel pattern VCP may have the shape of a closed pipe or a macaroni. The back gate BG may be formed to apply a voltage to the vertical channel pattern VCP, with at least a portion thereof surrounded by the vertical channel pattern VCP. Hereinafter, the fact that the back gate BG is included in the vertical channel pattern VCP may mean a state in which at least a portion of the back gate BG is surrounded by the vertical channel pattern VCP as described above.

While covering the inner side wall of each of the channel holes CH, the data storage pattern DSP may be in contact with the vertical channel pattern VCP inwardly and may be in contact with the side walls of the gate electrodes EL1, EL2, and EL3 outwardly. As such, the areas of the data storage pattern DSP, which correspond to the second gate electrodes EL2, may constitute the memory cells, in which the memory operation (e.g., the program operation, the read operation, or the erase operation) is performed by the voltages applied through the second gate electrodes EL2, together with the areas of the vertical channel pattern VCP, which correspond to the second gate electrodes EL2. The memory cells correspond to the memory cell transistors MCT illustrated in FIG. 1. That is, the data storage pattern DSP may trap the charges or holes by the voltages applied through the second gate electrodes EL2 or may maintain the state of the charges (e.g., the polarization state of the charges) by the voltages applied through the second gate electrodes EL2, and thus, the data storage pattern DSP may serve as data storage in the three-dimensional flash memory. For example, the ONO layer or the ferroelectric layer may be used as the data storage pattern DSP. The data storage pattern DSP may indicate the binary data value or the multi-bit (multi-level) data value through the change in the amount of trapped charges or holes or may indicate the binary data value or the multi-bit (multi-level) data value through the state change of the charges.

The vertical channel pattern VCP may cover the inner side wall of the data storage pattern DSP and may extend in the third direction D3. The vertical channel pattern VCP may be provided between the data storage pattern DSP and the back gate BG and may correspond to the second gate electrodes EL2. As such, as described above, the vertical channel pattern VCP may constitute the memory cells together with the areas of the data storage pattern DSP, which correspond to the second gate electrodes EL2.

The upper surface of the vertical channel pattern VCP may be positioned to be higher in level than the upper surface of the uppermost one of the second gate electrodes EL2. In more detail, the upper surface of the vertical channel pattern VCP may be positioned between the upper surface and the lower surface of the third gate electrode EL3.

The vertical channel pattern VCP, which is a component transferring charges or holes to the data storage pattern DSP, may be formed of monocrystalline silicon or polysilicon such that the channel is formed or boosted by the voltage applied thereto. However, the present disclosure is not restricted or limited thereto. For example, the vertical channel pattern VCP may be formed of an oxide semiconductor material capable of blocking, suppressing, or minimizing a leakage current. For example, the vertical channel pattern VCP may be formed of an oxide semiconductor material including at least one of In, Zn, and Ga having excellent leakage current characteristics, or a group 4 semiconductor material. The vertical channel pattern VCP may be formed of, for example, a ZnOx-based material including AZO, ZTO, IZO, ITO, IGZO, or Ag—ZnO. Thus, the vertical channel pattern VCP may block, suppress, or minimize a leakage current to the gate electrodes EL1, EL2, and EL3 or the substrate SUB, may improve transistor characteristics (e.g., the threshold voltage distribution and the program/read operation speed) of at least one of the gate electrodes EL1, EL2, and EL3, and as a result, may improve electrical characteristics of the three-dimensional flash memory.

The back gate BG may be in contact with the vertical channel pattern VCP, with at least a portion thereof surrounded by the vertical channel pattern VCP, and may be formed to apply a voltage to the vertical channel pattern VCP for the memory operation. To this end, the back gate BG may be formed of a conductive material including at least one selected from the group of doped semiconductor (e.g., doped silicon, etc.), metal (e.g., tungsten (W), copper (Cu), aluminum (Al), titanium (Ti), tantalum (Ta), molybdenum (Mo), ruthenium (Ru), gold (Au), etc.), or conductive metal nitride (e.g., titanium nitride, tantalum nitride, etc.). The back gate BG may include at least one of all metal materials capable of being formed by ALD, in addition to the above metal materials.

In this case, the back gate BG may be formed to extend in the third direction D3 in the vertical channel pattern VCP from a level corresponding to the first gate electrode EL1 to a level corresponding to the second gate electrode EL2. That is, the upper surface of the back gate BG may be positioned to be higher in level than the upper surface of the uppermost one of the second gate electrodes EL2. However, the present disclosure is not restricted or limited thereto. For example, the back gate BG may be formed to extend in the third direction D3 in the vertical channel pattern VCP to the level corresponding to the third gate electrode EL3.

The lower substrate in contact with the lower portion of the back gate BG is omitted in the drawing, but depending on an implementation example, the lower substrate in contact with the lower surface of the back gate BG may be included. Further, depending on an implementation example, the back gate BG may be formed from the interior of the substrate SUB or may be formed from the upper portion of the substrate SUB.

The back gate BG may be included in the vertical channel pattern VCP of each of the cell strings CSTR, and all the back gates BG respectively included in the vertical channel patterns VCP of the cell strings CSTR may be electrically connected on a plane that the first direction D1 and the second direction D2 form. That is, the back gate BG may be connected in common to the cell strings CSTR. In this case, the back gates BG of the cell strings CSTR may be collectively controlled such that the same voltage is applied to all the back gates BG.

However, the present disclosure is not restricted or limited thereto. For example, the back gates BG respectively included in the vertical channel patterns VCP of the cell strings CSTR may be electrically connected to each other in the first direction D1 of FIG. 1. In this case, the back gates BG of the cell strings CSTR arranged in the second direction D2 may be electrically controlled independently of each other such that different voltages are applied to the back gates BG, and the back gates BG of the cell strings CSTR arranged in the first direction D1 of FIG. 1 may be collectively controlled such that the same voltage is applied to the back gates BG.

Further, the back gates BG respectively included in the vertical channel patterns VCP of the cell strings CSTR may be electrically connected to each other in the second direction D2 of FIG. 1. In this case, the back gates BG of the cell strings CSTR arranged in the first direction D1 may be electrically controlled independently of each other such that different voltages are applied to the back gates BG, and the back gates BG of the cell strings CSTR arranged in the second direction D2 of FIG. 1 may be collectively controlled such that the same voltage is applied to the back gates BG.

The insulating film INS may be disposed between the back gate BG and the vertical channel pattern VCP, and thus, the back gate BG may be prevented from being in direct contact with the vertical channel pattern VCP. Like the interlayer insulating films ILD, the insulating film ILD may be formed of an insulating material such as a silicon oxide.

A structure in which the back gate BG is formed in the internal hole of the vertical channel pattern VCP and is formed in a state of being closely surrounded by the vertical channel pattern VCP is described above, but the present disclosure is not restricted or limited thereto. For example, a structure in which only at least a portion of the back gate BG may be surrounded by the vertical channel pattern VCP may be formed. For example, a structure in which the back gate BG and the insulating film INS are included in at least a portion of the vertical channel pattern VCP or a structure in which the back gate BG and the insulating film INS penetrate the vertical channel pattern VCP may be implemented.

Returning to FIG. 1, the vertical channel structures VS may correspond to the channels of the erasure control transistor ECT, the first and second string selection transistors SST1 and SST2, the ground selection transistor GST, and the memory cell transistors MCT.

The conductive pad PAD may be provided on the upper surface of the vertical channel pattern VCP. The conductive pad PAD may be connected to the upper portion of the vertical channel pattern VCP. The side wall of the conductive pad PAD may be surrounded by the data storage pattern DSP. The upper surface of the conductive pad PAD may be substantially coplanar with the upper surface of each of the laminated structures ST (i.e., the upper surface of the uppermost one of the interlayer insulating films ILD). The lower surface of the conductive pad PAD may be positioned at a lower level than that of the upper surface of the third gate electrode EL3. In more detail, the lower surface of the conductive pad PAD may be positioned between the upper surface and the lower surface of the third gate electrode EL3. That is, at least a portion of the conductive pad PAD may overlap the third gate electrode EL3 in the horizontal direction.

The conductive pad PAD may be formed of a semiconductor doped with impurities or a conductive material. For example, the conductive pad PAD may be formed of a semiconductor material doped with impurities different from that of the substrate SUB (in detail, a semiconductor material doped with impurities of the second conductive type (e.g., N-type) different from the first conductive type (e.g., P-type)).

The conductive pad PAD may reduce a contact resistance between the bit line BL, which will be described below, and the vertical channel pattern VCP.

The separation trench TR extending in the first direction D1 may be provided between the adjacent laminated structures ST. The common source area CSR may be provided inside the substrate SUB exposed by the separation trench TR. The common source area CSR may extend in the first direction D1 within the substrate SUB. The common source area CSR may be formed of a semiconductor material doped with second conductivity-type impurities (e.g., N-type impurities). The common source area CSR may correspond to the common source line CSL of FIG. 1.

The common source plug CSP may be provided inside the separation trench TR. The common source plug CSP may be connected to the common source area CSR. The upper surface of the common source plug CSP may be substantially coplanar with the upper surface of each of the laminated structures ST (i.e., the upper surface of the uppermost one of the interlayer insulating films ILD). The common source plug CSP may have a plate shape extending in the first direction D1 and the third direction D3. In this case, the common source plug CSP may have a shape of which a width in the second direction D2 increases toward the third direction D3.

The insulation spacers SP may be interposed between the common source plug CSP and the laminated structures ST. The insulation spacers SP may be provided between the adjacent laminated structures ST to face each other. For example, the insulation spacers SP may be formed of a silicon oxide, a silicon nitride, a silicon oxy nitride, or a low-k material having a low dielectric constant.

The capping insulating film CAP may be provided on the laminated structures ST, the vertical channel structures VS, and the common source plug CSP. The capping insulating film CAP may cover the upper surface of the uppermost one of the interlayer insulating films ILD, the upper surface of the conductive pad PAD, and the upper surface of the common source plug CSP. The capping insulating film CAP may be formed of an insulating material different from that of the interlayer insulating films ILD. The bit line contact plug BLPG electrically connected to the conductive pad PAD may be provided inside the capping insulating film CAP. The bit line contact plug BLPG may have a shape of which widths in the first direction D1 and the second direction D2 increase toward the third direction D3.

The bit line BL may be provided on the capping insulating film CAP and the bit line contact plug BLPG. The bit line BL corresponds to any one of the plurality of bit lines BL0, BL1, and BL2 illustrated in FIG. 1, and may be formed of a conductive material to extend in the second direction D2. The conductive material constituting the bit line BL may be the same material as the conductive material forming each of the gate electrodes EL1, EL2, and EL3.

The bit line BL may be electrically connected to the vertical channel structures VS through the bit line contact plug BLPG. Here, the fact that the bit line BL is connected to the vertical channel structures VS my mean that the bit line BL is connected to the vertical channel patterns VCP included in the vertical channel structures VS.

The three-dimensional flash memory with the above structure may perform the program operation, the read operation, and the erase operation based on the voltage applied to each of the cell strings CSTR, the voltage applied to the string selection line SSL, the voltage applied to each of the word lines WL0 to WLn, the voltage applied to the ground selection line GSL, the voltage applied to the common source line CSL, and a voltage applied to the back gate BG. For example, based on the voltage applied to each of the cell strings CSTR, the voltage applied to the string selection line SSL, the voltage applied to each of the word lines WL0 to WLn, the voltage applied to the ground selection line GSL, the voltage applied to the common source line CSL, and the voltage applied to the back gate BG, the three-dimensional flash memory may form a channel in the vertical channel pattern VCP such that charges or holes are transferred to the data storage pattern DSP of a target memory cell. This may mean that the three-dimensional flash memory performs the program operation.

Further, the three-dimensional flash memory according to another embodiment is not restricted or limited to the above structure, and according to the implementation example, the three-dimensional flash memory may be implemented in various structures under the condition that the vertical channel pattern VCP, the data storage pattern DSP, the back gate BG, the gate electrodes EL1, EL2, and EL3, the bit line BL, and the common source line CSL are included.

As the three-dimensional flash memory having such a structure is manufactured through the stack laminating process, each of the laminated structures ST may include the upper stack structure USS and the lower stack structure LSS. The lower stack structure LSS may be disposed on the substrate SUB and include the gate electrodes (EL1 and a portion of EL2) and the interlayer insulating films ILD that are vertically and alternately laminated. The upper stack structure USS may be laminated on the lower stack structure LSS and include the gate electrodes (a portion of EL2 and EL3) and the interlayer insulating films ILD that are vertically and alternately laminated.

When the lower stack structure LSS and the upper stack structure USS are laminated, the vertical channel structures VS included in the lower stack structure LSS and the vertical channel structures VS included in the upper stack structure USS may be misaligned. For example, when the vertical channel patterns VCP of the lower stack structure LSS and the vertical channel patterns VCP of the upper stack structure USS are misaligned, channel current characteristics may be degraded. Thus, each of the laminated structures ST of the three-dimensional flash memory may include the connection parts CU that connect the vertical channel patterns VCP of the stack structures USS and LSS to each other while being arranged between the upper stack structure USS and the lower stack structure LSS. These connection parts CU may be formed in a tube shape including the internal hole formed to extend in the vertical direction (the third direction D3), and according to the manufacturing process, the connection parts CU may be formed in a recessed type in which the connection parts CU are recessed in the uppermost interlayer insulating film ILD included in the lower stack structure LSS as illustrated in FIG. 14 or a protrusion type in which the connection parts CU are positioned on the uppermost interlayer insulating film ILD included in the lower stack structure LSS. When the connection parts CU are formed in the protrusion type, the connection parts CU may be accommodated by additional interlayer insulating films ILD that are not included in the upper and lower stack structures USS and LSS. As the connection parts CU are formed in a tube shape, the back gate BG and the insulating film INS may be formed to extend from the lower stack structure LSS to the upper stack structure USS through internal holes of the connection parts CU.

In particular, the connection parts CU may have shapes protruding from the vertical channel patterns VCP in the horizontal direction. In more detail, the connection parts CU may have sizes in which the vertical channel patterns VCP are accommodated on a plane and thus may have shapes protruding from the vertical channel patterns VCP in the horizontal direction, respectively. Further, the connection parts CU may be formed at positions, in which the vertical channel patterns VCP are accommodated, to connect the vertical channel patterns VCP of the upper and lower stack structures USS and LSS to each other.

Further, the connection parts CU may be formed of the same material as that of the vertical channel patterns VCP to connect the vertical channel patterns VCP of the upper and lower stack structures USS and LSS. For example, the connection parts CU may be formed of single crystalline silicon or polysilicon constituting the vertical channel patterns VCP. However, the present disclosure is not restricted or limited thereto, and each of the connection parts CU may be formed of various materials capable of connecting the vertical channel patterns VCP of the upper and lower stack structures USS and LSS to each other.

As described above, the three-dimensional flash memory includes the connection parts CU, to connect the vertical channel patterns VCP of the stack structures USS and LSS to each other so as to solve a problem of degrading the channel current characteristics.

It has been described above that the three-dimensional flash memory is manufactured through the stack laminating process, and thus includes the upper stack structure USS and the lower stack structure LSS. However, the number of stack structures laminated in the stack laminating process is adjusted, and thus the three-dimensional flash memory may include three or more stack structures (e.g., the upper stack structure USS, the middle stack structure MSS, and the lower stack structure LSS). In this case, the groups of the connection parts CU, which are arranged in the horizontal direction (the first direction D1 and the second direction D2), are spaced apart from each other in the third direction D3, and the connection parts CU may be arranged at connection portions of the stack structures. A plurality of buffer layers BU may be provided to surround the groups of the connection parts CU spaced apart from each other in the third direction D3, and may be spaced apart from each other in the third direction D3.

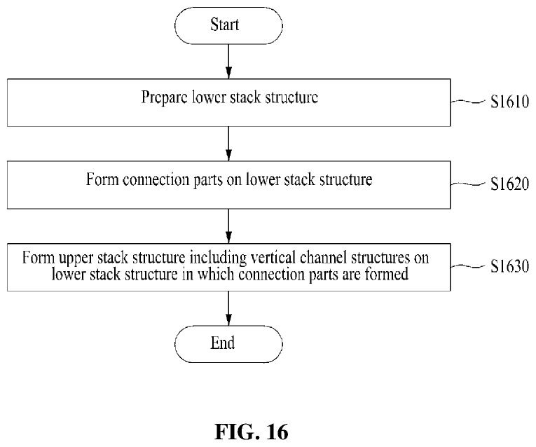

FIG. 16 is a flowchart illustrating a method of manufacturing the three-dimensional flash memory illustrated in FIGS. 12 and 13, and FIGS. 17A to 17E are cross-sectional views illustrating the three-dimensional flash memory to describe the method illustrated in FIG. 16.

Referring to FIG. 16, the method of manufacturing a three-dimensional flash memory according to the embodiment, which is intended to manufacture the three-dimensional flash memory described with reference to FIGS. 12 and 13 and is based on the assumption that the method is performed by an automated and mechanized manufacturing system, may include operation S1610 of preparing the lower stack structure LSS including the interlayer insulating films ILD and the gate electrodes (EL1 and a portion of EL2) formed to extend in the horizontal direction and alternately laminated in the vertical direction and the vertical channel structures VS passing through the interlayer insulating films ILD and the gate electrodes (EL1 and a portion of EL2) in the vertical direction, operation S1620 of forming the connection parts CU on the lower stack structure LSS based on the positions of the vertical channel structures VS of the lower stack structure LSS, and operation S1630 of forming the upper stack structure USS including the interlayer insulating films ILD and the gate electrodes (a portion of EL2 and EL3) formed to extend in the horizontal direction and alternately laminated in the vertical direction and the vertical channel structures VS passing through the interlayer insulating films ILD and the gate electrodes (a portion of EL2 and EL3) in the vertical direction, on the lower stack structure LSS in which the connection parts CU are formed.

In particular, in operation S1620, the connection parts CU having shapes protruding from the vertical channel patterns VCP of the lower stack structure LSS in the horizontal direction may be formed. According to the manufacturing process, the connection parts CU may be formed in a recessed type in which the connection parts CU are recessed in the uppermost interlayer insulating film ILD included in the lower stack structure LSS as illustrated in FIG. 12 or a protrusion type in which the connection parts CU are positioned on the uppermost interlayer insulating film ILD included in the lower stack structure LSS as illustrated in FIG. 13.

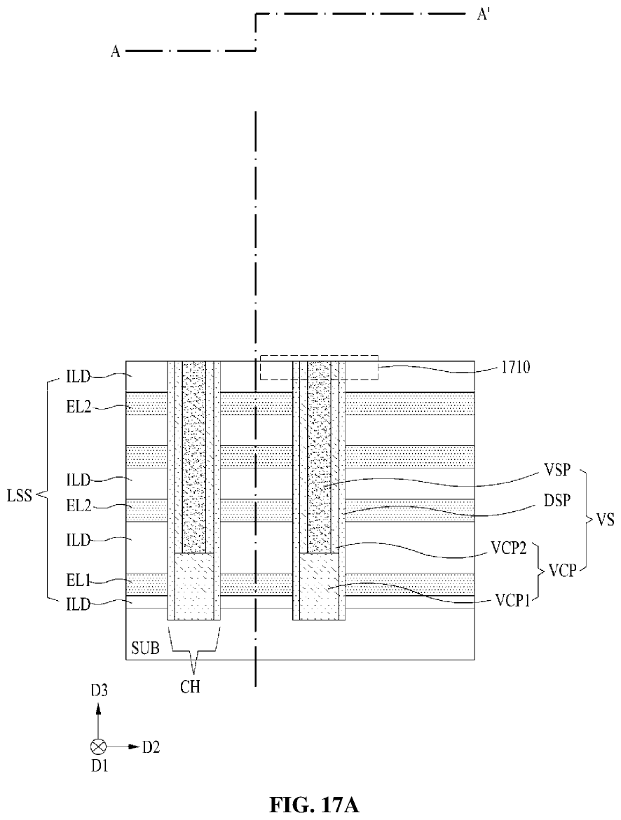

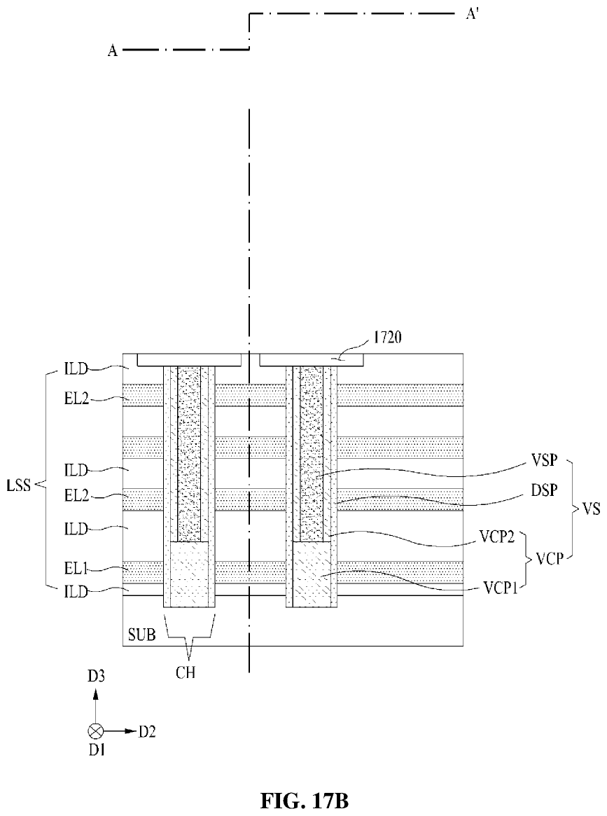

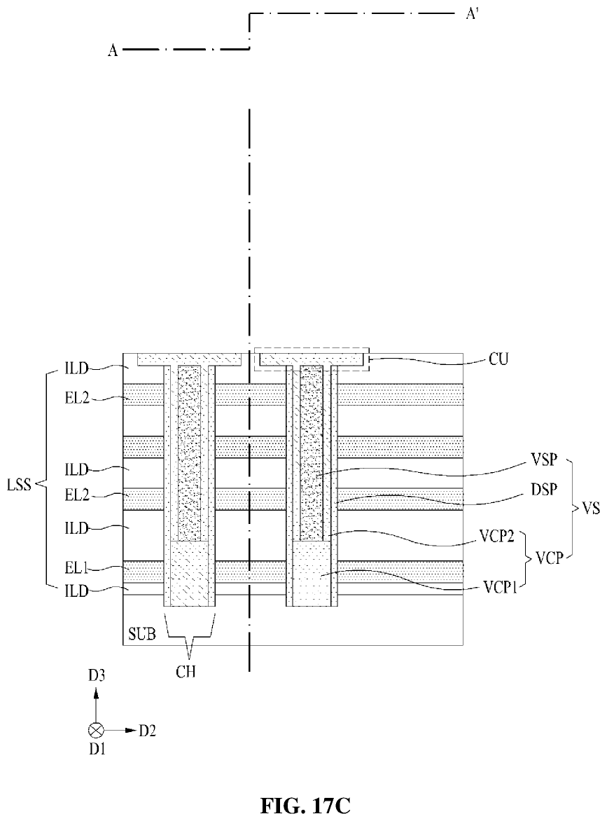

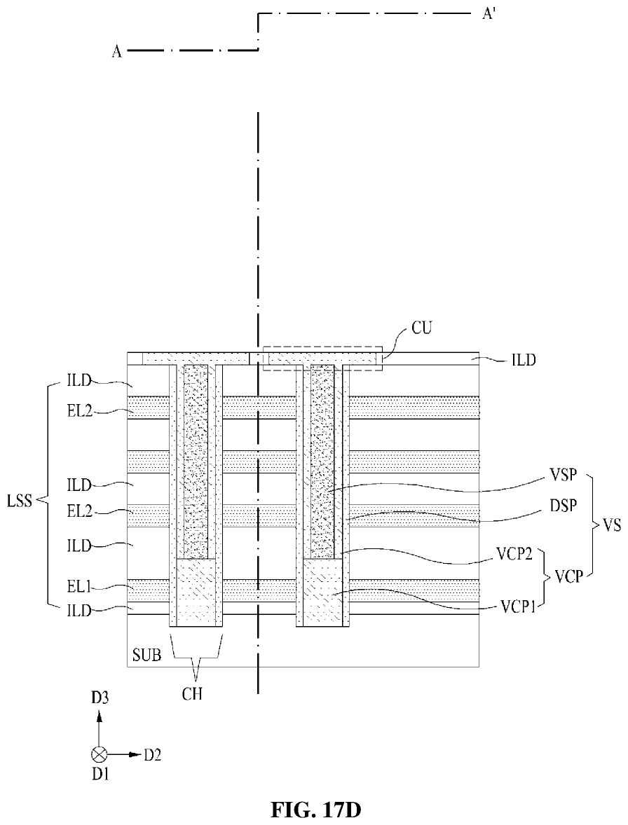

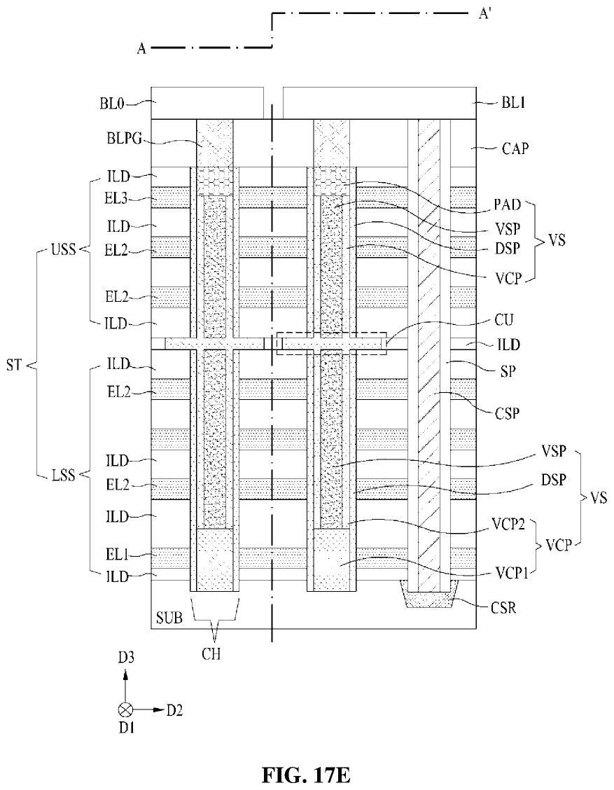

Hereinafter, operations S1610 to S1630 of FIG. 16 will be described in detail with reference to FIGS. 17A to 17E.

Referring to FIG. 17A, in operation S1610, the manufacturing system may prepare the lower stack structure LSS including the interlayer insulating films ILD and the gate electrodes (EL1 and a portion of EL2) formed in and extending from the substrate SUB in the horizontal direction (e.g., the first direction D1 and the second direction D2) and alternately laminated in the vertical direction (e.g., the third direction D3) and the vertical channel structures VS passing through the interlayer insulating films ILD and the gate electrodes (EL1 and a portion of EL2) in the vertical direction. Here, the vertical channel structures VS may have the structures described in FIGS. 12 and 13 and include portions of the data storage pattern DSP, the vertical channel pattern VCP, and the vertical semiconductor pattern VSP as illustrated in the drawings.

Although not described and illustrated in separate operations and drawings, before operation S1610 of preparing the lower stack structure LSS, the manufacturing system may perform an operation of forming the channel holes CH in the structure in which the interlayer insulating films ILD and the sacrificial layers SAC are alternately laminated in the vertical direction, selectively removing the sacrificial layers SAC through the channel holes CH, and forming the gate electrodes (EL1 and a portion of EL2) on the gate areas GR that are the spaces from which the sacrificial layers SAC are removed and an operation of forming vertical channel structures VS in the channel holes CH such that the vertical channel structures VS extend in the vertical direction. That is, the manufacturing system performs the WL Replacement process and the vertical channel structure forming process before operation S1610, and thus may prepare the lower stack structure LSS including the interlayer insulating film ILD, the gate electrodes (EL1 and a portion of EL2), and the vertical channel structures VS in operation S1610. Here, the sacrificial layers SAC may be selectively removed through the separation trench TR as well as the channel holes CH. In this case, an operation of forming the separation trench TR may be previously performed before operation S1610.

Further, it has been described above that the WL Replacement process is performed before operation S1610, and thus the lower stack structure LSS in which the gate electrodes (EL1 and a portion of EL2) are formed is prepared. However, the present disclosure is not restricted or limited thereto, and the lower stack structure LSS in which the gate electrodes (EL1 and a portion of EL2) are formed may be prepared through the gate first process.

Referring to FIGS. 17B to 17D, in operation S1620, the manufacturing system may form the connection parts CU on the lower stack structure LSS based on the positions of the vertical channel structures VS in the lower stack structure LSS. In this case, the manufacturing system may form the connection parts CU on the vertical channel patterns VCP included in the lower stack structure LSS using the same material (e.g., single-crystalline silicon or polysilicon) as a material constituting the vertical channel patterns VCP, to connect the vertical channel patterns VCP included in the lower stack structure LSS and the vertical channel patterns VCP included in the upper stack structure USS to be formed in operation S1630, which will be described below to each other.

For example, the manufacturing system may etch an upper portion of the lower stack structure LSS (an upper portion of the lower stack structure LSS, corresponding to the vertical channel structures VS) as illustrated in FIG. 17B and then may form the connection parts CU on remaining spaces 1720 after the etching as illustrated in FIG. 17C. The connection parts CU formed in this way may be provided in a recessed type in which the connection parts CU are recessed in the uppermost interlayer insulating film ILD included in the lower stack structure LSS as illustrated in FIG. 12.

As another example, the manufacturing system may form the connection parts CU at upper portions of the lower stack structure LSS (upper portions of the lower stack structure LSS corresponding to the vertical channel structures VS) as illustrated in FIG. 17D and thus may form the connection parts CU in a protrusion type in which the connection parts CU are positioned on the uppermost interlayer insulating film ILD included in the lower stack structure LSS as illustrated in FIG. 13. In this case, the manufacturing system may form an additional interlayer insulating film ILD that accommodates the connection parts CU.

It will be described with reference to the following drawings that the three-dimensional flash memory having a structure including the connection parts CU formed in a protrusion type is manufactured.

Referring to FIG. 17E, in operation S1630, the manufacturing system may form, on the lower stack structure LSS in which the connection parts CU are formed, the upper stack structure USS including the interlayer insulating films ILD and the gate electrodes (a portion of EL2 and EL3) formed to extend in the horizontal direction and alternately laminated in the vertical direction and the vertical channel structures VS passing through the interlayer insulating films ILD and the gate electrodes (a portion of EL2 and EL3) in the vertical direction. Here, the vertical channel structures VS may include, as a structure described in FIGS. 14 and 15, remaining portions of the data storage pattern DSP, the vertical channel pattern VCP, and the vertical semiconductor pattern VSP (remaining portions of the data storage pattern DSP, the vertical channel pattern VCP, and the vertical semiconductor pattern VSP illustrated in FIGS. 14 and 15, except for portions of the data storage pattern DSP, the vertical channel pattern VCP, and the vertical semiconductor pattern VSP included in the lower stack structure LSS) as illustrated in the drawings.

Although not described and illustrated in separate operations and drawings, before operation S1630 of preparing the upper stack structure USS, the manufacturing system may perform an operation of forming the channel holes CH in the structure in which the interlayer insulating films ILD and the sacrificial layers SAC are alternately laminated in the vertical direction, selectively removing the sacrificial layers SAC through the channel holes CH, and forming the gate electrodes (a portion of EL2 and EL3) on the gate areas GR that are the spaces from which the sacrificial layers SAC are removed and an operation of forming vertical channel structures VS in the channel holes CH such that the vertical channel structures VS extend in the vertical direction. That is, the manufacturing system may perform the WL Replacement process and the vertical channel structure forming process between operation S1620 and operation S1630 and thus form the upper stack structure USS including the interlayer insulating films ILD and the gate electrodes (a portion of EL2 and EL3) and the vertical channel structures VS in operation S1630. Here, the sacrificial layers SAC may be selectively removed through the separation trench TR as well as the channel holes CH. In this case, an operation of forming the separation trench TR may be previously performed between operation S1620 and operation S1630.

Further, it has been described above that the WL Replacement process is performed before operation S1630, and thus the upper stack structure USS in which the gate electrodes (a portion of EL2 and EL3) are formed is prepared. However, the present disclosure is not restricted or limited thereto, and the upper stack structure USS in which the gate electrodes (a portion of EL2 and EL3) are formed may be formed through the gate first process.

Although not described as a separate operation, in addition to operations S1610 to S1630, the manufacturing system may further perform an operation of forming the separation trench TR, an operation of performing the WL Replacement process through the separation trench TR (which may be omitted when the WL Replacement process is performed through the channel holes CH), an operation of forming the common source area CSR inside the substrate SUB exposed through the separation trench TR, an operation of forming the insulating spacer SP that covers the side wall of the separation trench TR and the common source plug CSP that fills the interior space of the separation trench TR surrounded by the insulating spacer SP, an operation of forming the capping insulating film CAP on the vertical channel structures VS and the common source plug CSP, an operation of forming the bit line contact plug BLPG electrically connected to the conductive pad PAD through the capping insulating film CAP, and an operation of forming the bit line BL electrically connected to the bit line contact plug BLPG on the capping insulating film CAP such that the bit line BL extends in the second direction D2.

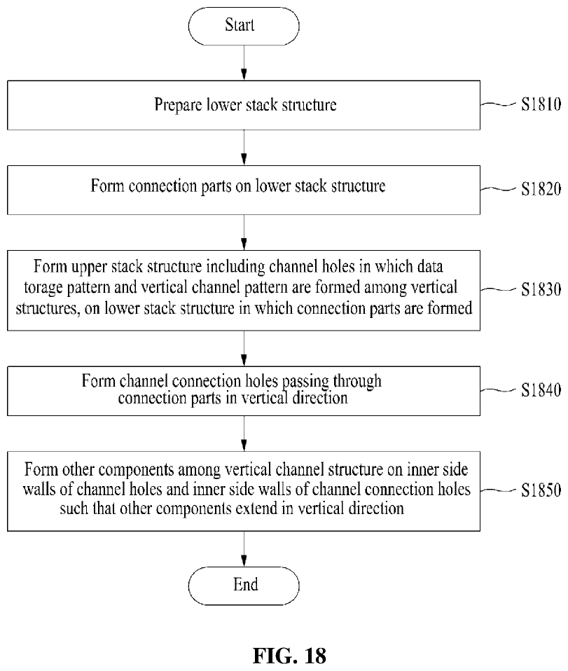

FIG. 18 is a flowchart illustrating a method of manufacturing the three-dimensional flash memory having a structure illustrated in FIGS. 14 and 15, and FIGS. 19A to 19G are cross-sectional views illustrating the three-dimensional flash memory to describe the method illustrated in FIG. 18.

Referring to FIG. 18, the method of manufacturing a three-dimensional flash memory according to the embodiment, which is intended to manufacture the three-dimensional flash memory described with reference to FIGS. 14 and 15 and is based on the assumption that the method is performed by an automated and mechanized manufacturing system, may include operation S1810 of preparing the lower stack structure LSS including the interlayer insulating films ILD and the gate electrodes (EL1 and a portion of EL2) formed to extend in the horizontal direction and alternately laminated in the vertical direction and the vertical channel structures VS passing through the interlayer insulating films ILD and the gate electrodes (EL1 and a portion of EL2) in the vertical direction, operation S1820 of forming the connection parts CU on the lower stack structure LSS based on the positions of the vertical channel structures VS of the lower stack structure LSS, operation S1830 of forming the upper stack structure USS including the interlayer insulating films ILD and the gate electrodes (a portion of EL2 and EL3) formed to extend in the horizontal direction and alternately laminated in the vertical direction and the channel holes CH passing through the interlayer insulating films ILD and the gate electrodes (a portion of EL2 and EL3) in the vertical direction, the data storage pattern DSP and the vertical channel pattern VCP among components of the vertical channel structures VS being formed on and extending from the inner side walls of the channel holes CH, on the lower stack structure LSS in which the connection parts CU are formed, operation S1840 of forming the channel connection holes CCH through the connection parts CU in the horizontal direction based on the positions of the channel holes CH, and operation S1850 of forming at least one remaining component except for the data storage pattern DSP and the vertical channel pattern VCP among the vertical channel structures VS on the inner walls of the channel holes CH and the inner walls of the channel connection holes CCH such that the at least one remaining component extends in the vertical direction.

In particular, in operation S1820, the connection parts CU having shapes protruding from the vertical channel patterns VCP of the lower stack structure LSS in the horizontal direction may be formed. According to the manufacturing process, the connection parts CU may be formed in a recessed type in which the connection parts CU are recessed in the uppermost interlayer insulating film ILD included in the lower stack structure LSS as illustrated in FIG. 14 or a protrusion type in which the connection parts CU are positioned on the uppermost interlayer insulating film ILD included in the lower stack structure LSS as illustrated in FIG. 15.

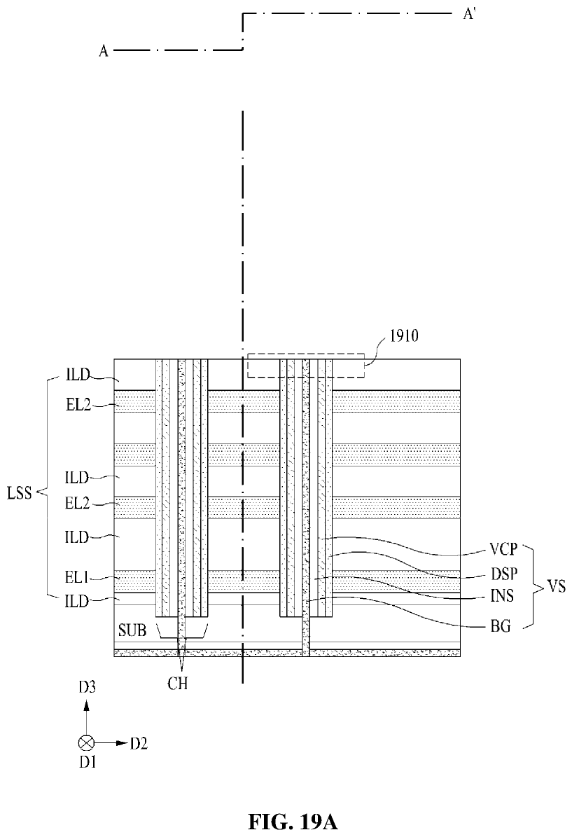

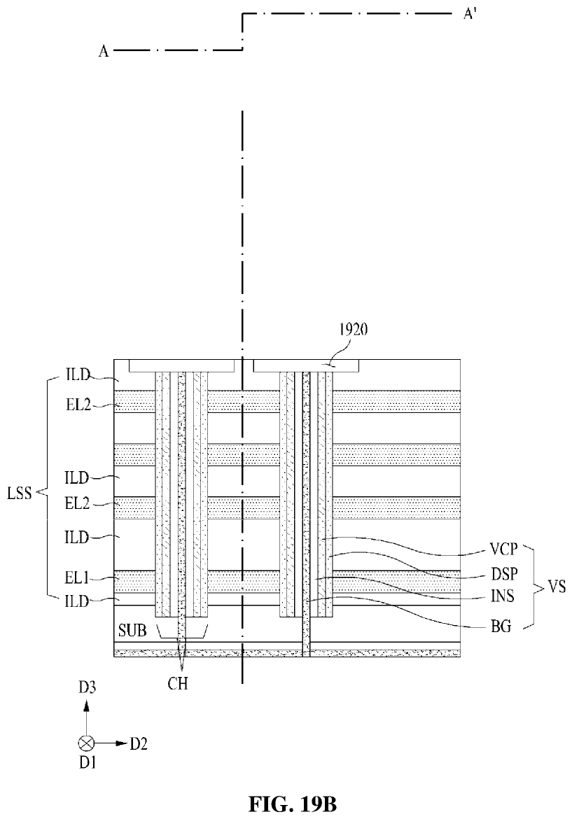

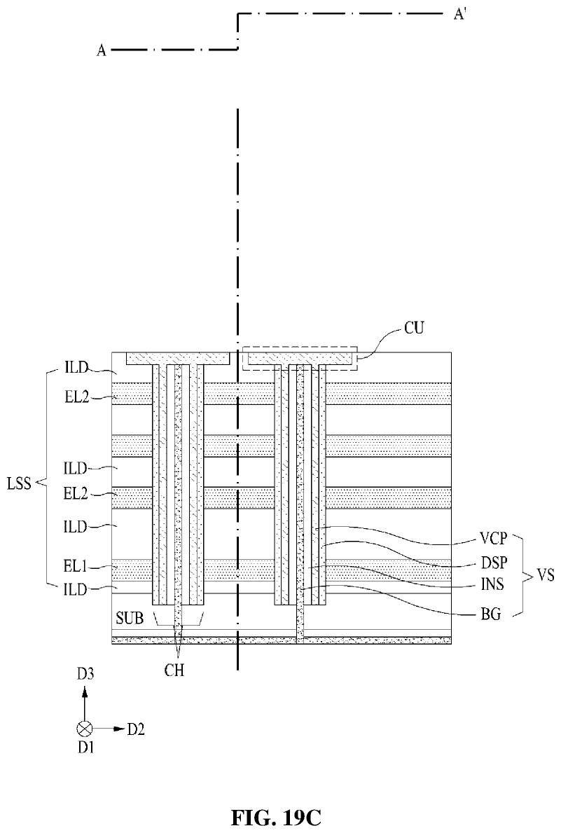

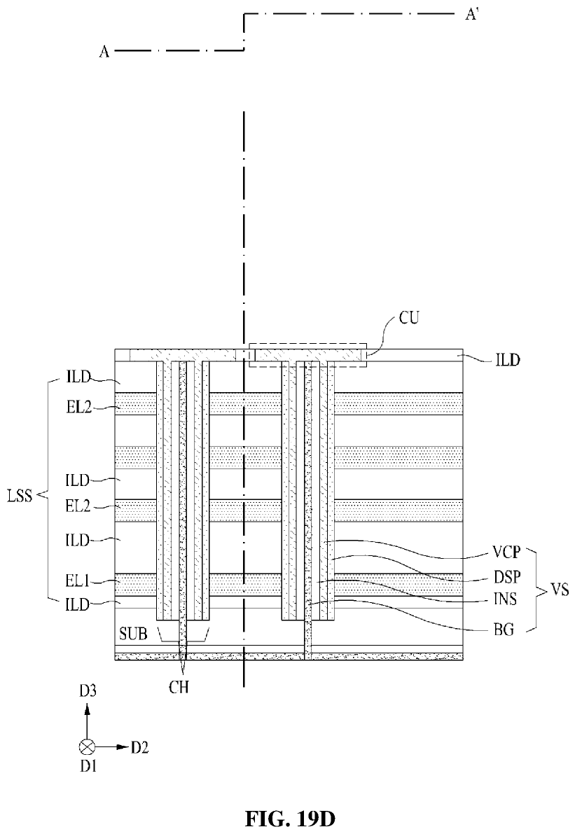

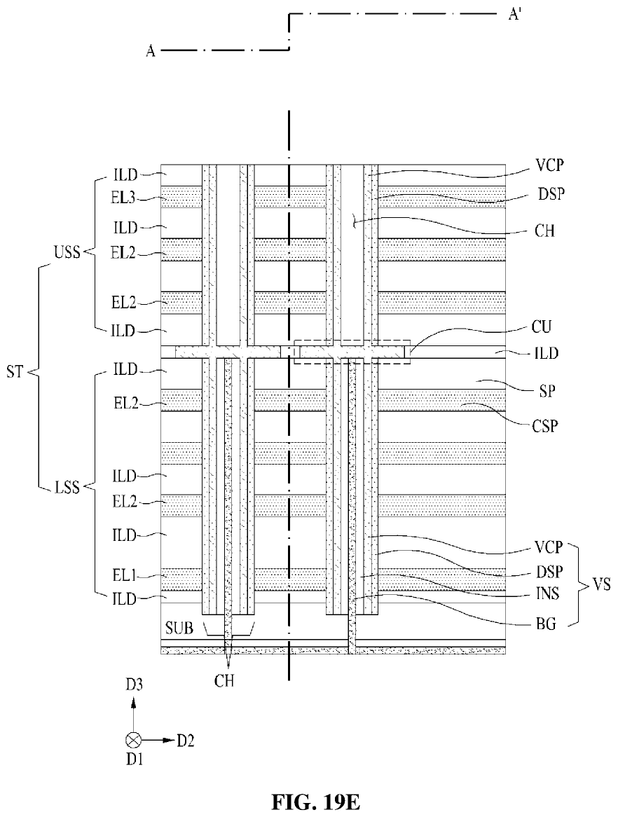

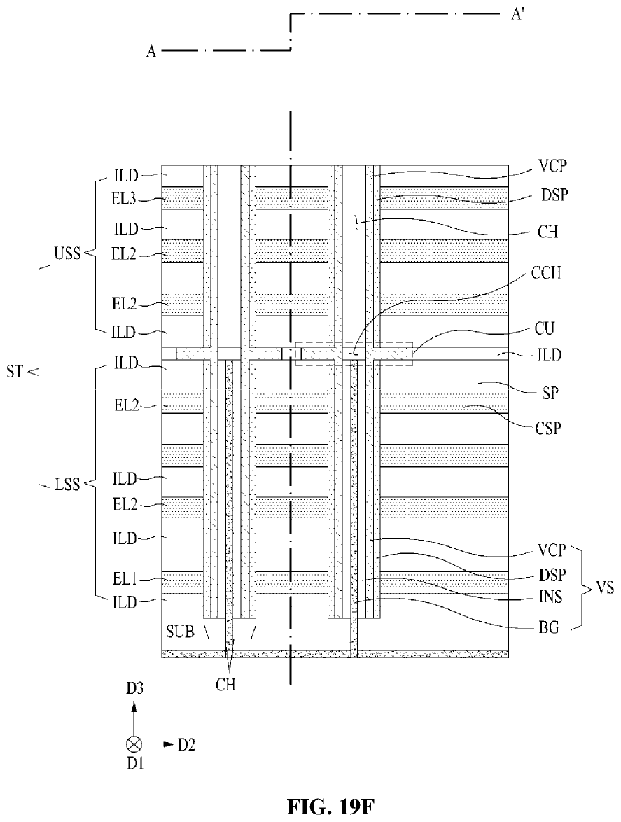

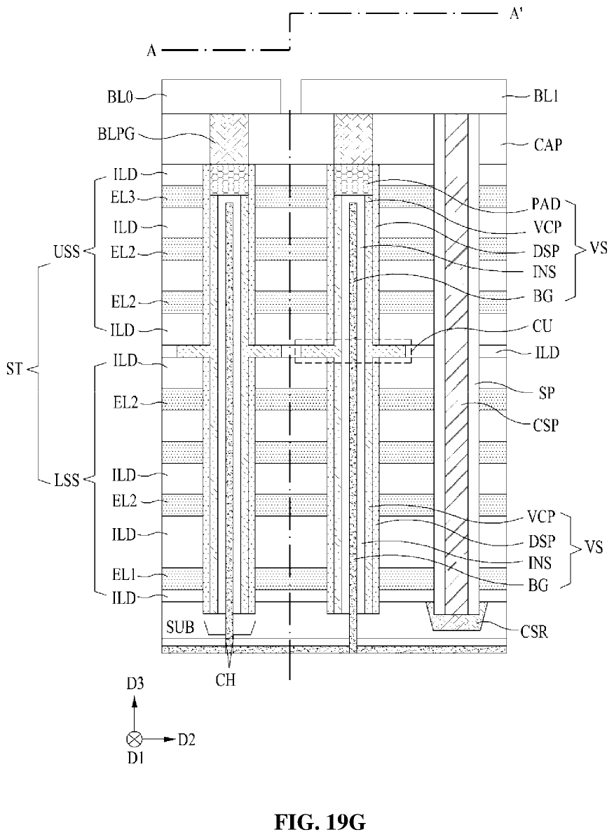

Hereinafter, operations S1810 to S1850 of FIG. 18 will be described in detail with reference to FIGS. 19A to 19G.

Referring to FIG. 19A, in operation S1810, the manufacturing system may prepare the lower stack structure LSS including the interlayer insulating films ILD and the gate electrodes (EL1 and a portion of EL2) formed in and extending from the substrate SUB in the horizontal direction (e.g., the first direction D1 and the second direction D2) and alternately laminated in the vertical direction (e.g., the third direction D3) and the vertical channel structures VS passing through the interlayer insulating films ILD and the gate electrodes (EL1 and a portion of EL2) in the vertical direction. Here, the vertical channel structures VS may have the structures described in FIGS. 14 and 15 and include portions of the data storage pattern DSP, the vertical channel pattern VCP, the insulating film INS, and the back gate BG as illustrated in the drawings.

Although not described and illustrated in separate operations and drawings, before operation S1810 of preparing the lower stack structure LSS, the manufacturing system may perform an operation of forming the channel holes CH in the structure in which the interlayer insulating films ILD and the sacrificial layers SAC are alternately laminated in the vertical direction, selectively removing the sacrificial layers SAC through the channel holes CH, and forming the gate electrodes (EL1 and a portion of EL2) on the gate areas GR that are the spaces from which the sacrificial layers SAC are removed and an operation of forming vertical channel structures VS in the channel holes CH such that the vertical channel structures VS extend in the vertical direction. That is, the manufacturing system performs the WL Replacement process and the vertical channel structure forming process before operation S1810, and thus may prepare the lower stack structure LSS including the interlayer insulating film ILD, the gate electrodes (EL1 and a portion of EL2), and the vertical channel structures VS in operation S1810. Here, the sacrificial layers SAC may be selectively removed through the separation trench TR as well as the channel holes CH. In this case, an operation of forming the separation trench TR may be previously performed before operation S1810.

Further, it has been described above that the WL Replacement process is performed before operation S1810, and thus, the lower stack structure LSS in which the gate electrodes (EL1 and a portion of EL2) are formed is prepared. However, the present disclosure is not restricted or limited thereto, and the lower stack structure LSS in which the gate electrodes (EL1 and a portion of EL2) are formed may be prepared through the gate first process.

Referring to FIGS. 19B to 19D, in operation S1820, the manufacturing system may form the connection parts CU on the lower stack structure LSS based on the positions of the vertical channel structures VS in the lower stack structure LSS. In this case, the manufacturing system may form the connection parts CU on the vertical channel patterns VCP included in the lower stack structure LSS using the same material (e.g., single-crystalline silicon or polysilicon) as a material constituting the vertical channel patterns VCP, to connect the vertical channel patterns VCP included in the lower stack structure LSS and the vertical channel patterns VCP included in the upper stack structure USS to each other.

For example, the manufacturing system may etch an upper portion of the lower stack structure LSS (an upper portion of the lower stack structure LSS, corresponding to the vertical channel structures VS) as illustrated in FIG. 19B and then may form the connection parts CU on remaining spaces 1920 after the etching as illustrated in FIG. 19C. The connection parts CU formed in this way may be provided in a recessed type in which the connection parts CU are recessed in the uppermost interlayer insulating film ILD included in the lower stack structure LSS as illustrated in FIG. 14.

As another example, the manufacturing system may form the connection parts CU at upper portions of the lower stack structure LSS (upper portions of the lower stack structure LSS corresponding to the vertical channel structures VS) as illustrated in FIG. 19D and thus may form the connection parts CU in a protrusion type in which the connection parts CU are positioned on the uppermost interlayer insulating film ILD included in the lower stack structure LSS as illustrated in FIG. 15. In this case, the manufacturing system may form an additional interlayer insulating film ILD that accommodates the connection parts CU.

It will be described with reference to the following drawings that the three-dimensional flash memory having a structure including the connection parts CU formed in a protrusion type is manufactured.

Referring to FIG. 19E, in operation S1830, the manufacturing system may form the upper stack structure USS including the interlayer insulating films ILD and the gate electrodes (a portion of EL2 and EL3) formed to extend in the horizontal direction (e.g., the first direction D1 and the second direction D2) and alternately laminated in the vertical direction (e.g., the third direction D3) and the channel holes CH passing through the interlayer insulating films ILD and the gate electrodes (a portion of EL2 and EL3) in the vertical direction, the data storage pattern DSP and the vertical channel pattern VCP among components of the vertical channel structures VS being formed on and extending from the inner side walls of the channel holes CH, on the lower stack structure LSS in which the connection parts CU are formed.

In this case, the upper stack structure USS in which some components (e.g., the data storage pattern DSP and the vertical channel pattern VCP) of the vertical channel structures VS are formed may be formed in each of the channel holes CH. This is to connect the vertical channel patterns VCP of the upper and lower stack structures USS and LSS to each other by the connection parts CU.

Although not described and illustrated in separate operations and drawings, before operation S1830 of preparing the upper stack structure USS, the manufacturing system may perform an operation of forming the channel holes CH in the structure in which the interlayer insulating films ILD and the sacrificial layers SAC are alternately laminated in the vertical direction, selectively removing the sacrificial layers SAC through the channel holes CH, and forming the gate electrodes (a portion of EL2 and EL3) on the gate areas GR that are the spaces from which the sacrificial layers SAC are removed and an operation of forming the data storage pattern DSP and the vertical channel pattern VCP among the vertical channel structures VS. That is, the manufacturing system may perform the WL Replacement process and the data storage pattern DSP/vertical channel pattern VCP forming process between operation S1820 and operation S1830 and thus may form the upper stack structure USS including the interlayer insulating films ILD and the gate electrodes (a portion of EL2 and EL3) and the channel holes CH, the channel holes CH being formed in the data storage pattern DSP and the vertical channel pattern VCP, in operation S1830. Here, the sacrificial layers SAC may be selectively removed through the separation trench TR as well as the channel holes CH. In this case, an operation of forming the separation trench TR may be previously performed between operation S1820 and operation S1830.

Further, it has been described above that the WL Replacement process is performed before operation S1830, and thus the upper stack structure USS in which the gate electrodes (a portion of EL2 and EL3) are formed is prepared. However, the present disclosure is not restricted or limited thereto, and the upper stack structure USS in which the gate electrodes (a portion of EL2 and EL3) are formed may be formed through the gate first process.

Referring to FIG. 19F, in operation S1840, the manufacturing system may form the channel connection holes CCH passing through the connection parts CU in the vertical direction based on the positions of the channel holes CH. In more detail, the manufacturing system may form the channel connection holes CCH based on the positions of the channel holes CH of the upper stack structure USS and the positions of the vertical channel structures VS of the lower stack structure LSS such that the vertical channel structures VS included in the lower stack structure LSS and the channel holes CH included in the upper stack structure USS are connected to each other through the channel connection holes CCH.

In operation S1840 of forming the channel connection holes CCH, an anisotropic etching method using a mask pattern as an etch mask may be used. However, this is merely an example, and various etching processes may be used in operation S1840.

Referring to FIG. 19G, in operation S1850, the manufacturing system may form at least one remaining component except for the data storage pattern DSP and the vertical channel pattern VCP among the vertical channel structures VS, on the inner side walls of the channel holes CH and the inner side walls of the channel connection holes CCH, such that the remaining component extends in the vertical direction.

As described above, when the upper stack structure USS in which some components (e.g., the data storage pattern DSP and the vertical channel pattern VCP) among the components of the vertical channel structures VS are formed in the channel holes CH is formed in operation S1830, the other components (e.g., the insulating film INS and the back gate BG) among the components of the vertical channel structures VS may be formed in operation S1850.

Here, the vertical channel structures VS may include, as a structure described in FIGS. 14 and 15, remaining portions of the data storage pattern DSP, the vertical channel pattern VCP, the insulating film INS, and the back gate BG (remaining portions of the data storage pattern DSP, the vertical channel pattern VCP, the insulating film INS, and the back gate BG illustrated in FIGS. 14 and 15 except for portions of the data storage pattern DSP, the vertical channel pattern VCP, the insulating film INS, and the back gate BG included in the lower stack structure LSS) as illustrated in the drawings.

Further, although not described as a separate operation, in addition to operations S1810 to S1850, the manufacturing system may further perform an operation of forming the separation trench TR, an operation of performing the WL Replacement process through the separation trench TR (which may be omitted when the WL Replacement process is performed through the channel holes CH), an operation of forming the common source area CSR inside the substrate SUB exposed through the separation trench TR, an operation of forming the insulating spacer SP that covers the side wall of the separation trench TR and the common source plug CSP that fills the interior space of the separation trench TR surrounded by the insulating spacer SP, an operation of forming the capping insulating film CAP on the vertical channel structures VS and the common source plug CSP, an operation of forming the bit line contact plug BLPG electrically connected to the conductive pad PAD through the capping insulating film CAP, and an operation of forming the bit line BL electrically connected to the bit line contact plug BLPG on the capping insulating film CAP such that the bit line BL extends in the second direction D2.

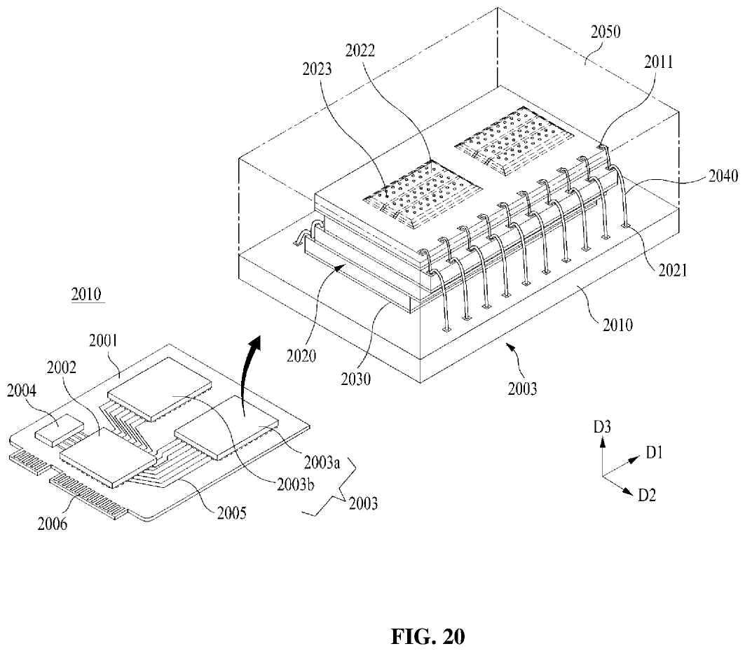

FIG. 20 is a schematic perspective view illustrating an electronic system including the three-dimensional flash memory according to embodiments.

Referring to FIG. 20, an electronic system 2000 including the three-dimensional flash memory according to embodiments may include a main board 2001, and a controller 2002, one or more semiconductor packages 2003, and a DRAM 2004 that are mounted on the main board 2001.

The semiconductor packages 2003 and the DRAM 2004 may be connected to the controller 2002 by wiring patterns 2005 provided in the main board 2001.

The main board 2001 may include a connector 2006 including a plurality of pins that are connected to an external host. The number and arrangement of a plurality of pins of the connector 2006 may change depending on a communication interface between the electronic system 2000 and the external host.

For example, the electronic system 2000 may communicate with the external host through any one of interfaces such as USB (Universal Serial Bus), PCIE-Express (Peripheral Component Interconnect Express), SATA (Serial Advanced Technology Attachment), and M-Phy for UFS (Universal Flash Storage). The electronic system 2000 may operate, for example, based on a power supplied from the external host through the connector 2006. The electronic system 2000 may further include a power management integrated circuit (PMIC) that distributes the power supplied from the external host into the controller 2002 and the semiconductor packages 2003.

The controller 2002 may record data at the semiconductor packages 2003 or may read data from the semiconductor packages 2003 and may make an operation speed of the electronic system 2000 better.

The DRAM 2004 may be a buffer memory for alleviating a speed difference between the semiconductor packages 2003 that is a data storage space and the external host. The DRAM 2004 included in the electronic system 2000 may operate as a kind of cache memory and may provide a space for temporarily storing data in a control operation associated with the semiconductor packages 2003. When the DRAM 2004 is included in the electronic system 2000, the controller 2002 may further include a DRAM controller for controlling the DRAM 2004, in addition to a NAND controller for controlling the semiconductor packages 2003.

The semiconductor package 2003 may include first and second semiconductor packages 2003a and 2003b that are spaced apart from each other. Each of the first and second semiconductor packages 2003a and 2003b may be a semiconductor package including a plurality of semiconductor chips 2020. Each of the first and second semiconductor packages 2003a and 2003b may include a package board 2010, the semiconductor chips 2020 on the package board 2010, adhesive layers 2030 respectively disposed on lower surfaces of the semiconductor chips 2020, connection structures 2040 electrically connecting the semiconductor chips 2020 and the package board 2010, and a molding layer 2050 covering the semiconductor chips 2020 and the connection structures 2040 on the package board 2010.

The package board 2010 may be a printed circuit board including package upper pads 2011. Each of the semiconductor chips 2020 may include input/output pads 2021. Each of the semiconductor chips 2020 may include the three-dimensional flash memory described above with reference to FIGS. 3 to 6 or the three-dimensional flash memory described above with reference to FIGS. 12 to 15. In more detail, each of the semiconductor chips 2020 may include gate laminate structures 2022 and memory channel structures 2023. The gate laminate structures 2022 may correspond to the laminated structures ST described above, and the memory channel structures 2023 may correspond to the vertical channel structures VS described above.

The connection structures 2040 may be, for example, bonding wires electrically connecting the input/output pads 2021 and the package upper pads 2011. Thus, in each of the first and second semiconductor packages 2003a and 2003b, the semiconductor chips 2020 may be electrically connected to each other through a bonding wire method, and may be electrically connected to the package upper pads 2011 of the package board 2010. According to embodiments, in each of the first and second semiconductor packages 2003a and 2003b, the semiconductor chips 2020 may be connected to each other by a through silicon via instead of the connection structures 2040 using a bonding wire method.

Unlike the illustration, the controller 2002 and the semiconductor chips 2020 may be included in one package. The controller 2002 and the semiconductor chips 2020 may be mounted on a separate interposer board different from the main board 2001, and the controller 2002 and the semiconductor chips 2020 may be connected to each other by wires formed in the interposer board.

As described above, although the embodiments have been described with reference to the limited embodiments and the limited drawings, various modifications and changes may be made based on the above description by those skilled in the art. For example, even though the described technologies are performed in an order different from the described method, and/or the described components such as a system, a structure, a device, and a circuit are coupled or combined in a form different from the described method or are replaced or substituted by other components or equivalents, appropriate results may be achieved.

Therefore, other implementations, other embodiments, and those equivalent to the appended claims also belong to the scope of the appended claims.

1. A three-dimensional flash memory comprising:
stack structures each including interlayer insulating films and gate electrodes formed to extend in a horizontal direction and alternately laminated in a vertical direction and vertical channel structures passing through the interlayer insulating films and the gate electrodes and formed to extend in the vertical direction, each of the vertical channel structures including a data storage pattern formed to extend in the vertical direction and a vertical channel pattern configured to cover an inner side wall of the data storage pattern and formed to extend in the vertical direction, and the stack structures being laminated in the vertical direction; and
a buffer layer including connection parts arranged between the stack structures and configured to connect the vertical channel patterns of the stack structures to each other,
wherein the connection parts protrude from the vertical channel patterns in the horizontal direction and have curved edges, respectively.

2. The three-dimensional flash memory of claim 1, wherein each of the connection parts is formed on a side wall on which a portion of the buffer layer in the horizontal direction is wet-etched and thus has a curved edge.

3. The three-dimensional flash memory of claim 2, wherein the buffer layer is formed of a material on which the wet etching is performed.

4. The three-dimensional flash memory of claim 3, wherein the material forming the buffer layer includes at least one material among a silicon oxide and a metal oxide.

5. The three-dimensional flash memory of claim 1, wherein each of the connection parts is formed on a side wall on which a portion of the buffer layer in the horizontal direction is etched as the buffer layer includes a plurality of layers, which have different etching ratios and are laminated in the vertical direction and has a curved shape.

6. The three-dimensional flash memory of claim 5, wherein a layer positioned in a center of the plurality of layers in the vertical direction has a higher etching ratio than those of layers positioned at edges of the plurality of layers in the vertical direction.

7-8. (canceled)

9. A three-dimensional flash memory comprising:
stack structures each including interlayer insulating films and gate electrodes formed to extend in a horizontal direction and alternately laminated in a vertical direction and vertical channel structures passing through the interlayer insulating films and the gate electrodes and formed to extend in the vertical direction, each of the vertical channel structures including a data storage pattern formed to extend in the vertical direction and a vertical channel pattern configured to cover an inner side wall of the data storage pattern and formed to extend in the vertical direction, and the stack structures being laminated in the vertical direction; and
connection parts arranged between the stack structures and protruding from the vertical channel patterns in the horizontal direction to connect the vertical channel patterns of the stack structures to each other.

10. The three-dimensional flash memory of claim 9, wherein each of the connection parts is formed in a pillar shape having a closed interior such that when each of the vertical channel patterns includes a back gate formed to extend in the vertical direction while at least a portion thereof is surrounded by the vertical channel pattern, the back gate is formed in a tube shape including an internal hole formed to extend in the vertical direction or when each of the vertical channel patterns includes a vertical semiconductor pattern, the vertical semiconductor pattern included in an upper stack structure and the vertical semiconductor pattern included in a lower stack structure among the stack structures are separated by the connection parts.

11-13. (canceled)
